(19) United States
(12) Patent Application Publication
(10) Pub. No.: US 2024/0002998 A1
(43) Pub. Date: Jan. 4, 2024

(54) SPUTTERING TARGET AND METHOD FOR FORMING SPUTTERING TARGET

(71) Applicant: SEMICONDUCTOR ENERGY LABORATORY CO., LTD., Atsugi-shi (JP)

(72) Inventors: Shunpei YAMAZAKI, Tokyo (JP); Yuichi SATO, Isehara (JP); Fumito ISAKA, Zama (JP); Toshikazu OHNO, Atsugi (JP)

(21) Appl. No.: 18/213,683

(22) Filed: Jun. 23, 2023

(30) Foreign Application Priority Data
Jun. 29, 2022 (JP) 2022-105047

(51) Int. Cl. C23C 14/34

(52) U.S. Cl. CPC C23C 14/3414

(57) ABSTRACT

A novel sputtering target is provided. The sputtering target includes a first region and a second region. The first region contains a first metal oxide containing an element M1 (the element M1 is one or more elements selected from Al, Ga, Si, Mg, Zr, and B). The second region contains a second metal oxide containing indium and zinc. The first region and the second region are separated from each other. Each of the first region and the second region is a crystal grain. A crystal grain boundary is observed between the first region and the second region. The diameter of each of the first region and the second region is greater than or equal to 5 nm and less than or equal to 10 μm.

### BACKGROUND OF THE INVENTION

### 1. Field of the Invention

The present invention relates to an object, a method, or a manufacturing method. The present invention relates to a process, a machine, manufacture, or a composition of matter. In particular, one embodiment of the present invention relates to a metal oxide, a method for forming the metal oxide, a sputtering target, or a method for forming the sputtering target. One embodiment of the present invention relates to a semiconductor device, a display device, a liquid crystal display device, a light-emitting device, a power storage device, a memory device, a method for driving them, or a method for manufacturing them.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. An imaging device, a display device, a liquid crystal display device, a light-emitting device, an electro-optical device, a power generation device (including a thin film solar cell, an organic thin film solar cell, and the like), and an electronic device may each include a semiconductor device.

### 2. Description of the Related Art

As a semiconductor material that can be used in a transistor, an oxide has been attracting attention. For example, Patent Document 1 discloses a field-effect transistor including an amorphous oxide of any of an In—Zn—Ga—O-based oxide, an In—Zn—Ga—Mg—O-based oxide, an In—Zn—O-based oxide, an In—Sn—O-based oxide, an In—O-based oxide, an In—Ga—O-based oxide, and a Sn—In—Zn—O-based oxide.

### REFERENCE

### Patent Document

[Patent Document 1] Japanese Patent No. 5118810

### SUMMARY OF THE INVENTION

In Patent Document 1, an active layer of a transistor is formed using an amorphous oxide of any of an In—Zn—Ga—O-based oxide, an In—Zn—Ga—Mg—O-based oxide, an In—Zn—O-based oxide, an In—Sn—O-based oxide, an In—O-based oxide, an In—Ga—O-based oxide, and a Sn—In—Zn—O-based oxide. In other words, the active layer of the transistor includes one of the amorphous oxides. The transistor whose active layer includes one of the amorphous oxides has a problem of a low on-state current, which is one of electrical characteristics of the transistor. Alternatively, the transistor whose active layer includes one of the amorphous oxides has a problem of poor reliability.

In view of the above problems, an object of one embodiment of the present invention is to provide a novel metal oxide. Another object is to provide a novel sputtering target. Another object is to provide a method for forming a novel sputtering target. Another object is to give excellent electrical characteristics to a semiconductor device. Another object is to provide a highly reliable semiconductor device. Another object is to provide a semiconductor device with a novel structure. Another object is to provide a display device with a novel structure.

Note that the description of these objects does not disturb the existence of other objects. In one embodiment of the present invention, there is no need to achieve all the objects. Other objects will be apparent from and can be derived from the description of the specification, the drawings, the claims, and the like.

One embodiment of the present invention is a sputtering target including a first region and a second region. The first region contains a first metal oxide containing an element M1 (the element M1 is one or more elements selected from Al, Ga, Si, Mg, Zr, and B). The second region contains a second metal oxide containing indium and an element M2 (the element M2 is one or more elements selected from Zn, Ti, Ge, Sn, V, Ni, Mo, W, and Ta). The first region and the second region are separated from each other. At least one of the first region and the second region is a crystal grain. A crystal grain boundary is observed between the first region and the second region. A diameter of each of the first region and the second region is greater than or equal to 5 nm and less than or equal to 10 μm.

In the above sputtering target, the first metal oxide preferably contains indium and zinc in addition to the element M1.

In the above sputtering target, it is preferable that the element M1 be Ga and the element M2 be Sn.

One embodiment of the present invention is a sputtering target including a first region and a second region. The first region contains a first metal oxide containing an element M1 (the element M1 is one or more elements selected from Al, Ga, Si, Mg, Zr, and B). The second region contains a second metal oxide containing indium and zinc. The first region and the second region are separated from each other. Each of the first region and the second region is a crystal grain. A crystal grain boundary is observed between the first region and the second region. A diameter of each of the first region and the second region is greater than or equal to 5 nm and less than or equal to 10 μm.

In the above sputtering target, the first metal oxide preferably contains indium and zinc in addition to the element M1.

In the above sputtering target, the element M1 is preferably Ga.

In the above sputtering target, a crystal structure of the first region is preferably different from a crystal structure of the second region.

One embodiment of the present invention is a method for forming a sputtering target, including the steps of weighing a first indium oxide, an oxide of an element M1 (the element M1 is one or more elements selected from Al, Ga, Si, Mg, Zr, and B), and a first zinc oxide, which are raw materials of a first fired body, and a second indium oxide and a second zinc oxide, which are raw materials of a second fired body; forming a first mixture by mixing the first indium oxide, the oxide of the element M1, and the first zinc oxide; forming a first molded body by molding the first mixture with pressure; forming the first fired body by firing the first molded body; forming a first powder by pulverizing the first fired body; forming a second mixture by mixing the second indium oxide and the second zinc oxide; forming a second molded body by molding the second mixture with pressure; forming the second fired body by firing the second molded body; forming a second powder by pulverizing the second fired body; forming a third mixture by mixing the first powder and the second powder; and forming a third molded body by molding the third mixture with pressure. A step of firing the third molded body is not performed after the step of forming the third molded body.

One embodiment of the present invention is a method for forming a sputtering target, including the steps of weighing a first indium oxide, an oxide of an element M1 (the element M1 is one or more elements selected from Al, Ga, Si, Mg, Zr, and B), and a first zinc oxide, which are raw materials of a first fired body, and a second indium oxide and a second zinc oxide, which are raw materials of a second fired body; forming a first mixture by mixing the first indium oxide, the oxide of the element M1, and the first zinc oxide; forming a first molded body by molding the first mixture with pressure; forming the first fired body by firing the first molded body; forming a first powder by pulverizing the first fired body; forming a second mixture by mixing the second indium oxide and the second zinc oxide; forming a second molded body by molding the second mixture with pressure; forming the second fired body by firing the second molded body; forming a second powder by pulverizing the second fired body; forming a third mixture by mixing the first powder and the second powder; forming a third molded body by molding the third mixture with pressure; and forming a third fired body by firing the third molded body. A firing temperature of the third molded body is a temperature at which part of the first powder and part of the second powder are not combined with each other.

In the above method for forming a sputtering target, the firing temperature of the third molded body is preferably lower than firing temperatures of the first molded body and the second molded body.

Another embodiment of the present invention is a method for forming a sputtering target, including the steps of weighing a first indium oxide, an oxide of an element M1 (the element M1 is one or more elements selected from Al, Ga, Si, Mg, Zr, and B), and a zinc oxide, which are raw materials of a first fired body, and a second indium oxide and an oxide of an element M2 (the element M2 is one or more elements selected from Ti, Ge, Sn, V, Ni, Mo, W, and Ta), which are raw materials of a second fired body; forming a first mixture by mixing the first indium oxide, the oxide of the element M1, and the zinc oxide; forming a first molded body by molding the first mixture with pressure; forming the first fired body by firing the first molded body; forming a first powder by pulverizing the first fired body; forming a second mixture by mixing the second indium oxide and the oxide of the element M2; forming a second molded body by molding the second mixture with pressure; forming the second fired body by firing the second molded body; forming a second powder by pulverizing the second fired body; forming a third mixture by mixing the first powder and the second powder; and forming a third molded body by molding the third mixture with pressure. A step of firing the third molded body is not performed after the step of forming the third molded body.

Another embodiment of the present invention is a method for forming a sputtering target, including the steps of weighing a first indium oxide, an oxide of an element M1 (the element M1 is one or more elements selected from Al, Ga, Si, Mg, Zr, and B), and a zinc oxide, which are raw materials of a first fired body, and a second indium oxide and an oxide of an element M2 (the element M2 is one or more elements selected from Ti, Ge, Sn, V, Ni, Mo, W, and Ta), which are raw materials of a second fired body; forming a first mixture by mixing the first indium oxide, the oxide of the element M1, and the zinc oxide; forming a first molded body by molding the first mixture with pressure; forming the first fired body by firing the first molded body; forming a first powder by pulverizing the first fired body; forming a second mixture by mixing the second indium oxide and the oxide of the element M2; forming a second molded body by molding the second mixture with pressure; forming the second fired body by firing the second molded body; forming a second powder by pulverizing the second fired body; forming a third mixture by mixing the first powder and the second powder; forming a third molded body by molding the third mixture with pressure; and forming a third fired body by firing the third molded body. The third molded body is fired at a temperature at which part of the first powder and part of the second powder are not combined with each other.

In the above method for forming a sputtering target, the firing temperature of the third molded body is preferably lower than firing temperatures of the first molded body and the second molded body.

Another embodiment of the present invention is a method for forming a sputtering target, including the steps of weighing an indium oxide and a zinc oxide, which are raw materials of a first fired body, and an oxide of an element M1 (the element M1 is one or more elements selected from Al, Ga, Si, Mg, Zr, and B); forming a first mixture by mixing the indium oxide and the zinc oxide; forming a first molded body by molding the first mixture with pressure; forming the first fired body by firing the first molded body; forming a first powder by pulverizing the first fired body; forming a second mixture by mixing the oxide of the element M1 and the first powder; and forming a second molded body by molding the second mixture with pressure. A step of firing the second molded body is not performed after the step of forming the second molded body.

Another embodiment of the present invention is a method for forming a sputtering target, including the steps of weighing an oxide of an element M1 (the element M1 is one or more elements selected from Al, Ga, Si, Mg, Zr, and B) and an indium oxide and a zinc oxide, which are raw materials of a first fired body; forming a first mixture by mixing the indium oxide and the zinc oxide; forming a first molded body by molding the first mixture with pressure; forming the first fired body by firing the first molded body; forming a first powder by pulverizing the first fired body; forming a second mixture by mixing the oxide of the element M1 and the first powder; forming a second molded body by molding the second mixture with pressure; and forming a second fired body by firing the second molded body. The second molded body is fired at a temperature at which part of the oxide of the element M1 and part of the first powder are not combined with each other.

In the above method for forming a sputtering target, the firing temperature of the second molded body is preferably lower than the firing temperature of the first molded body.

According to one embodiment of the present invention, a novel metal oxide can be provided. A novel sputtering target can be provided. A method for forming a novel sputtering target can be provided. A semiconductor device with excellent electrical characteristics can be provided. A highly reliable semiconductor device can be provided. A semiconductor device with a novel structure can be provided. A display device with a novel structure can be provided.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

In the accompanying drawings:

FIGS. 1A to 1D are schematic views of a sputtering target;

FIG. 2 is a flowchart showing a method for forming a sputtering target;

FIG. 3 is a flowchart showing a method for forming a sputtering target;

FIG. 4 is a flowchart showing a method for forming a sputtering target;

FIGS. 5A and 5B are flowcharts showing methods for forming a sputtering target;

FIGS. 6A and 6B are flowcharts showing methods for forming a sputtering target;

FIG. 7 is a flowchart showing a method for forming a sputtering target;

FIGS. 8A and 8B each show an atomic ratio range of a metal oxide of one embodiment of the present invention;

FIG. 9 is a schematic view of a sputtering apparatus;

FIGS. 10A and 10B are schematic views showing deposition using a sputtering target;

FIG. 11 is a conceptual view illustrating a composition of a metal oxide;

FIG. 12A is a top view illustrating an example of a semiconductor device, FIGS. 12B and 12C are cross-sectional views illustrating examples of the semiconductor device, and FIG. 12D is a cross-sectional conceptual view;

FIGS. 13A and 13B are cross-sectional views illustrating examples of a semiconductor device;

FIGS. 14A and 14B are cross-sectional views illustrating examples of a semiconductor device;

FIGS. 15A and 15B are cross-sectional views illustrating an example of a semiconductor device;

FIG. 16A is a top view illustrating an example of a semiconductor device, and FIGS. 16B and 16C are cross-sectional views illustrating examples of the semiconductor device;

FIG. 17A is a top view illustrating an example of a semiconductor device, and FIG. 17B is a cross-sectional view illustrating an example of the semiconductor device;

FIG. 18 is a cross-sectional view illustrating an example of a semiconductor device;

FIG. 19 is a cross-sectional view illustrating an example of a semiconductor device;

FIG. 20A is a top view illustrating an example of a semiconductor device, and FIG. 20B is a cross-sectional view illustrating an example of the semiconductor device;

FIGS. 21A and 21B are cross-sectional views illustrating examples of a semiconductor device;

FIG. 22A is a block diagram illustrating a structure example of a memory device of one embodiment of the present invention, and FIG. 22B is a perspective view illustrating a structure example of the memory device of one embodiment of the present invention;

FIGS. 23A to 23I are circuit diagrams each illustrating a structure example of a memory device of one embodiment of the present invention;

FIG. 24 is a cross-sectional view illustrating an example of a memory device;

FIG. 25 is a cross-sectional view illustrating an example of a memory device;

FIG. 26 is a cross-sectional view illustrating an example of a memory device;

FIG. 27 illustrates a circuit configuration example of a memory cell;

FIGS. 28A and 28B illustrate examples of electronic components;

FIGS. 29A and 29B illustrate examples of electronic devices, and FIGS. 29C to 29E illustrate an example of a large computer;

FIG. 30 illustrates an example of space equipment; and

FIG. 31 illustrates an example of a storage system that can be used in a data center.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that in this specification and the like, ordinal numbers such as “first” and “second” are used for convenience and do not limit the number of components or the order of components (e.g., the order of steps or the stacking order of layers).

Furthermore, an ordinal number used for a component in a certain part in this specification is not the same as an ordinal number used for the component in another part in this specification or claims in some cases.

Note that the terms “film” and “layer” can be used interchangeably depending on the case or the circumstances. For example, the term “conductive layer” can be replaced with the term “conductive film”. For another example, the term “insulating film” can be replaced with the term “insulating layer”. The term “conductor” can be replaced with the term “conductive layer” or “conductive film” depending on the case or the circumstances. The term “insulator” can be replaced with the term “insulating layer” or “insulating film” depending on the case or the circumstances.

Examples of an opening include a groove and a slit. A region where the opening is formed may be referred to as an opening portion.

In the drawings used in embodiments, a sidewall of an insulator in an opening is substantially perpendicular to a substrate surface or a formation surface, but the sidewall may have a tapered shape.

In this specification and the like, a tapered shape refers to a shape such that at least part of a side surface of a component is inclined with respect to a substrate surface or a formation surface of the component. For example, a tapered shape preferably includes a region where the angle between the inclined side surface and the substrate surface or the formation surface of the component (hereinafter, such an angle is referred to as a taper angle in some cases) is less than 90°. Note that the side surface of the component and the substrate plane are not necessarily completely flat and may be substantially flat with a slight curvature or with slight unevenness.

In this specification and the like, the expression “level with” indicates a structure having the same level from a reference surface (e.g., a flat surface such as a substrate surface) in a cross-sectional view. For example, in a manufacturing process of the semiconductor device, planarization treatment (typically, chemical mechanical polishing (CMP) treatment) is performed, whereby the surface(s) of a single layer or a plurality of layers may be exposed. In this case, the surfaces on which the CMP treatment is performed are at the same level from a reference surface. However, a plurality of layers may be on different levels depending on a treatment apparatus, a treatment method, or a material of the treated surfaces, used for the CMP treatment. This case is also included in the scope of “level with” in this specification and the like. For example, the expression “level with” also includes the case where two layers (here, a first layer and a second layer) have different two levels with respect to a reference surface and the difference in the top-surface level between the first and second layers is less than or equal to 20 nm.

In this specification and the like, the expression “an end portion is aligned with another end portion” means that at least outlines of stacked layers partly overlap with each other in a top view. For example, the case of patterning or partly patterning an upper layer and a lower layer with the use of the same mask pattern is included. The expression “an end portion is aligned with another end portion” also includes the case where the outlines do not completely overlap with each other; for instance, the outline of the upper layer may be positioned inward or outward from the outline of the lower layer.

In general, it is difficult to clearly differentiate “completely aligned” from “substantially aligned”. Thus, in this specification and the like, the expression “aligned” includes both “completely aligned” and “substantially aligned”.

Note that “normally-on characteristics” in this specification and the like mean a state where a channel exists without voltage application to a gate and current flows through a transistor. Furthermore, “normally-off characteristics” mean a state where current does not flow through a transistor when no potential or a ground potential is applied to a gate.

In this specification and the like, the term “leakage current” sometimes expresses the same meaning as “off-state current”. In this specification and the like, the off-state current sometimes refers to current that flows between a source and a drain of a transistor in the off state, for example.

### Embodiment 1

In this embodiment, a metal oxide, a sputtering target for depositing the metal oxide, and a method for forming the sputtering target, which are embodiments of the present invention, will be described.

The metal oxide described in this embodiment preferably contains two or three elements selected from indium, an element M, and zinc. The element M is a metal element or metalloid element having a high bonding energy with oxygen. For example, the bonding energy of the metal element or metalloid element with oxygen is higher than that of indium. Specific examples of the element M include aluminum (Al), gallium (Ga), tin (Sn), yttrium, titanium (Ti), vanadium (V), chromium, manganese, iron, cobalt, nickel (Ni), zirconium (Zr), molybdenum (Mo), hafnium, tantalum (Ta), tungsten (W), lanthanum, cerium, neodymium, magnesium (Mg), calcium, strontium, barium, boron (B), silicon (Si), germanium (Ge), and antimony. The element M contained in the metal oxide is preferably one or more of the above elements, further preferably one or more selected from aluminum, gallium, tin, and yttrium, and still further preferably gallium. In this specification and the like, a metal element and a metalloid element may be collectively referred to as a “metal element” and a “metal element” in this specification and the like may refer to a metalloid element.

As the metal oxide described in this embodiment, for example, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (In—Ga—Sn oxide), a gallium zinc oxide (Ga—Zn oxide, also referred to as GZO), an aluminum zinc oxide (Al—Zn oxide), an indium aluminum zinc oxide (In—Al—Zn oxide, also referred to as IAZO), an indium tin zinc oxide (In—Sn—Zn oxide), an indium titanium zinc oxide (In—Ti—Zn oxide), an indium gallium zinc oxide (In—Ga—Zn oxide, also referred to as IGZO), an indium gallium tin zinc oxide (In—Ga—Sn—Zn oxide, also referred to as IGZTO), or an indium gallium aluminum zinc oxide (In—Ga—Al—Zn oxide, also referred to as IGAZO or IAGZO) can be used. Alternatively, an indium tin oxide containing silicon, a gallium tin oxide (Ga—Sn oxide), an aluminum tin oxide (Al—Sn oxide), or the like can be used.

Increasing the proportion of indium atoms to the sum of atoms of metal elements that are main components in the metal oxide can increase the field-effect mobility of a transistor. Note that a main component in a metal oxide refers to, for example, an element having a proportion of 1 atomic % or higher with respect to elements contained in the metal oxide.

Instead of indium or in addition to indium, the metal oxide can contain one or more kinds of metal elements whose period number in the periodic table is large. As the overlap between orbits of metal elements is larger, the metal oxide tends to have higher carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide can contain one or more kinds of non-metal elements. A transistor including the metal oxide containing a non-metal element can have high field-effect mobility in some cases. Examples of the non-metal element include carbon, nitrogen, phosphorus, sulfur, selenium, fluorine, chlorine, bromine, and hydrogen.

Increasing the proportion of zinc atoms to the sum of atoms of the metal elements that are the main components in the metal oxide enables the metal oxide to have high crystallinity, so that diffusion of impurities in the metal oxide can be inhibited. Consequently, a change in the electrical characteristics of the transistor can be reduced to improve the reliability of the transistor.

Increasing the proportion of the element M atoms to the sum of atoms of the metal elements that are the main components in the metal oxide can inhibit formation of oxygen vacancies in the metal oxide. Accordingly, generation of carriers due to oxygen vacancies is inhibited, which makes the off-state current of the transistor low.

Furthermore, a change in the electrical characteristics of the transistor can be reduced to improve the reliability of the transistor.

Specifically, it is possible to use, as the metal oxide, a metal oxide with an atomic ratio of In:M:Zn=1:1:1 or in the neighborhood thereof, a metal oxide with an atomic ratio of In:M:Zn=1:1:1.2 or in the neighborhood thereof, a metal oxide with an atomic ratio of In:M:Zn=1:1:2 or in the neighborhood thereof, a metal oxide with an atomic ratio of In:M:Zn=2:1:3 or in the neighborhood thereof, or a metal oxide with an atomic ratio of In:M:Zn=4:2:3 or in the neighborhood thereof. Note that the neighborhood of an atomic ratio includes ±30% of an intended atomic ratio. Gallium is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

As described above, the electrical characteristics and reliability of a transistor including a metal oxide depend on the composition of the metal oxide. Thus, changing the composition of a metal oxide in accordance with the electrical characteristics and reliability required for a transistor enables a semiconductor device to have both excellent electrical characteristics and high reliability.

The metal oxide described in this embodiment contains oxygen and two or more elements other than oxygen. Note that the two or more elements other than oxygen are preferably selected from indium (In), the elements that can be selected as the element M, and zinc (Zn). For example, the two or more elements other than oxygen are preferably selected from elements such as In, Al, Ga, Si, Mg, Zr, B, Ti, Ge, Sn, V, Ni, Mo, W, Ta, and Zn.

Here, a metal oxide containing oxygen and three elements other than oxygen is considered. Hereinafter, the three elements other than oxygen are sometimes denoted as an element M1, an element M2, and an element M3. At this time, the metal oxide contains oxygen and the elements M1, M2, and M3. The terms of the atomic ratios of the elements M1, M2, and M3 are sometimes denoted as [M1], [M2], and [M3], respectively.

The element M1 is selected from indium, the elements that can be selected as the element M, and zinc; the element M2 is selected from indium, the elements that can be selected as the element M, and zinc and is different from the element M1; and the element M3 is selected from indium, the elements that can be selected as the element M, and zinc and is different from the elements M1 and M2.

In the case where the metal oxide contains oxygen and two elements other than oxygen, the two elements other than oxygen are sometimes denoted as the elements M1 and M2. In the case where the metal oxide contains oxygen and four elements other than oxygen, the four elements other than oxygen are sometimes denoted as the elements M1, M2, and M3 and an element M4. In the case where the metal oxide contains oxygen and five or more elements other than oxygen, the five or more elements other than oxygen are sometimes denoted in a similar manner.

### <Sputtering Target>

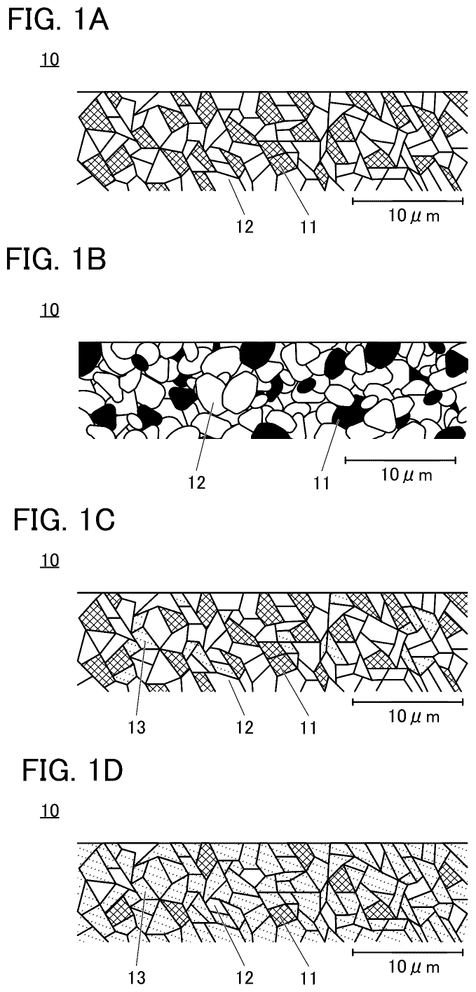

First, a sputtering target for depositing a metal oxide by a sputtering method will be described with reference to FIGS. 1A to 1D. FIGS. 1A to 1D are cross-sectional views of a sputtering target 10 for depositing a metal oxide by a sputtering method.

The sputtering target 10 is used for depositing a metal oxide by a sputtering method and thus contains an element contained in the metal oxide. For example, in the case where a metal oxide to be deposited using the sputtering target 10 contains the elements M1, M2, and M3, the sputtering target 10 contains the elements M1, M2, and M3.

The sputtering target 10 includes a first region 11 and a second region 12. The first region 11 and the second region 12 are separated from each other.

In this specification and the like, the expression “two regions are separated from each other” can be changed into the expression “two regions are apart from each other”. Note that being apart from each other means being physically distant from each other; however, in this specification and the like, two regions being proximate to each other, being adjacent to each other, or being in contact with each other is also regarded as being apart from each other.

It is preferable that the sputtering target 10 partly have a crystal structure. For example, the sputtering target 10 may partly have a polycrystalline structure. Note that the polycrystalline structure is formed of a plurality of fine single crystals (also referred to as crystal grains, crystallites, or microcrystals). FIG. 1A illustrates an example in which each of the first region 11 and the second region 12 is a crystal grain. In the case where each of the first region 11 and the second region 12 is a crystal grain, the first region 11 can be referred to as a first crystal grain and the second region 12 can be referred to as a second crystal grain. In the following description, the first crystal grain can be replaced with the first region 11 and the second crystal grain can be replaced with the second region 12.

In the case where each of the first region 11 and the second region 12 is a crystal grain, a crystal grain boundary is observed between the first region 11 and the second region 12 adjacent to each other. A crystal grain boundary is sometimes observed between the adjacent first regions 11 or between the adjacent second regions 12. The diameters of the first region 11 and the second region 12 (the diameters of the crystal grains) are each preferably greater than or equal to 3 nm or greater than or equal to 5 nm and less than or equal to 10 μm, less than or equal to 1 μm, less than or equal to 100 nm, or less than or equal to 10 nm. Note that the diameter of a crystal grain refers to the length of the longest straight line connecting two points on an outline of the crystal grain.

A crystal grain boundary refers to a region between crystal grains. A crystal grain boundary also refers to, for example, a portion where crystal grains adhere to each other, a portion where crystal orientation changes inside the sputtering target 10, i.e., a portion where alignment of atomic columns is discontinuous in a scanning transmission electron microscope (STEM) image or the like, a portion including a large number of crystal defects, a portion with a disordered crystal structure, or the like. A crystal defect refers to a defect that can be observed in a cross-sectional transmission electron microscope (TEM) image, a cross-sectional STEM image, or the like, i.e., a structure including another element between lattices, a cavity, or the like. A crystal grain boundary can be regarded as a plane defect.

In the case where the sputtering target 10 partly has a crystal structure and the first region 11 and the second region 12 each have a microcrystal, the diameter of the microcrystal is preferably greater than or equal to 0.5 nm and less than or equal to 3 nm, greater than or equal to 1 nm and less than or equal to 2 nm, or an approximate value thereof.

As illustrated in FIG. 1B, the first region 11 and the second region 12 may each be in a particulate form. In that case, the diameter of each of the first region 11 and the second region 12 is preferably less than 10 μm. Note that the term “particulate form” refers to a shape with an outline formed of only curved lines or both straight lines and curved lines in a cross-sectional view.

In the sputtering target 10, a combination of elements contained in the first region 11 preferably differs from a combination of elements contained in the second region 12. For example, it is preferable that at least one of the elements contained in the first region 11 not be contained in the second region 12. Furthermore, it is preferable that at least one of the elements contained in the second region 12 not be contained in the first region 11.

Note that the combination of the elements contained in the first region 11 may be the same as the combination of the elements contained in the second region 12. In that case, the first region 11 and the second region 12 preferably have different compositions.

The first crystal grain and the second crystal grain preferably have different crystal structures. In addition, the microcrystal of the first region 11 and the microcrystal of the second region 12 preferably have different crystal structures. For example, an In—Ga—Zn oxide has various crystal structures such as a bixbyite structure, a spinel structure, a wurtzite structure, a YbFe₂O₄ structure, and a Yb₂Fe₃O₇ structure depending on its composition. Thus, when the first region 11 and the second region 12 have different compositions, the first crystal grain and the second crystal grain sometimes have different crystal structures. Moreover, the microcrystal of the first region 11 and the microcrystal of the second region 12 sometimes have different crystal structures. That is, the sputtering target 10 having two or more kinds of crystal structures sometimes includes the first region 11 and the second region 12.

Note that the crystal structures of the sputtering target 10 can be evaluated with an X-ray diffraction (XRD) pattern obtained by an XRD method. For example, when structural analysis is performed with an XRD apparatus on the sputtering target 10 including the first region 11 and the second region 12 having different crystal structures, an XRD pattern derived from the first region 11 and an XRD pattern derived from the second region 12 are observed. In the case where the first or second crystal grain or the microcrystal of the first region 11 or the second region 12 is extremely small, the two XRD patterns are not observed in some cases.

The crystal structures of the sputtering target 10 can also be evaluated with a diffraction pattern obtained by a nanobeam electron diffraction (NBED) method (such a pattern is also referred to as a nanobeam electron diffraction pattern). For example, when NBED is performed on the sputtering target 10 including the first region 11 and the second region 12 having different crystal structures, a diffraction pattern derived from the crystal structure of the first crystal grain or the microcrystal of the first region 11 and a diffraction pattern derived from the crystal structure of the second crystal grain or the microcrystal of the second region 12 are observed to be different from each other.

As described above, the electrical characteristics and reliability of a transistor including a metal oxide depend on the composition of the metal oxide. Thus, setting the composition of a metal oxide in accordance with the electrical characteristics and reliability required for a transistor enables the transistor and a semiconductor device including the transistor to have both excellent electrical characteristics and high reliability. That is, when the ratio of the first region 11 to the second region 12 is made different or the compositions of the first region 11 and the second region 12 are made different in the sputtering target 10 depending on the electrical characteristics and reliability required for a transistor, for example, the transistor and a semiconductor device including the transistor can have both excellent electrical characteristics and high reliability.

In the above-described structure, the first region 11 includes a first metal oxide and the second region 12 includes a second metal oxide. In that case, two solid phases of the first metal oxide and the second metal oxide are present in the sputtering target 10. In this specification and the like, the first region 11 or the first crystal grain can sometimes be replaced with the first metal oxide, and the first metal oxide can sometimes be replaced with the first region 11 or the first crystal grain. Similarly, the second region 12 or the second crystal grain can sometimes be replaced with the second metal oxide, and the second metal oxide can sometimes be replaced with the second region 12 or the second crystal grain.

Here, the case where the sputtering target 10 is an oxide target containing the elements M1, M2, and M3 will be described.

The first region 11 preferably contains the element M1. The first region 11 may contain an oxide of the element M1. For example, the first region 11 contains the oxide of the element M1. In that case, the oxide of the element M1 can be regarded as the first metal oxide contained in the first region 11. That is, the first region 11 contains the first metal oxide containing the element M1.

The second region 12 preferably contains the element M2. The second region 12 may contain an oxide of the element M2. For example, the second region 12 contains the oxide of the element M2. In that case, the oxide of the element M2 can be regarded as the second metal oxide contained in the second region 12. That is, the second region 12 contains the second metal oxide containing the element M2.

The element M3 is contained in one or both of the first region 11 and the second region 12.

In the case where the element M3 is contained in the first region 11, for example, the first region 11 contains the elements M1 and M3. For example, the first region 11 contains an M1-M3 oxide. In that case, the M1-M3 oxide can be regarded as the first metal oxide contained in the first region 11. That is, the first region 11 contains the first metal oxide containing the elements M1 and M3. Note that the first region 11 may contain one or both of the oxide of the element M1 and the oxide of the element M3.

In the case where the element M3 is contained in the second region 12, for example, the second region 12 contains the elements M2 and M3. For example, the second region 12 contains an M2-M3 oxide. In that case, the M2-M3 oxide can be regarded as the second metal oxide contained in the second region 12. That is, the second region 12 contains the second metal oxide containing the elements M2 and M3. Note that the second region 12 may contain one or both of the oxide of the element M2 and the oxide of the element M3.

The first region 11 may contain the elements M2 and M3 in addition to the element M1. The first region 11 may contain an oxide of the elements M1, M2, and M3. For example, the first region 11 contains an M1-M2-M3 oxide. In that case, the M1-M2-M3 oxide can be regarded as the first metal oxide contained in the first region 11. That is, the first region 11 contains the first metal oxide containing the elements M1, M2, and M3. Note that the first region 11 may contain one or more of the oxide of the element M1, the oxide of the element M2, the oxide of the element M3, an M1-M2 oxide, the M1-M3 oxide, and the M2-M3 oxide.

The composition of the sputtering target 10 depends on the compositions of the first region 11 and the second region 12 and the ratio of the first region 11 to the second region 12. In the case where the first region 11 contains the oxide of the element M1, the second region 12 contains a metal oxide with an atomic ratio of [M2]: [M3]=1:2, and the molar ratio of the first region 11 to the second region 12 in the sputtering target 10 is 1:2, for example, the sputtering target 10 has an atomic ratio of [M2]: [M1]: [M3]=2:1:4 or in the neighborhood thereof.

The atomic ratio of the metal oxide deposited using the sputtering target 10 varies from the atomic ratio of metal elements contained in the sputtering target 10 in a range of ±40%.

As described above, the metal oxide may contain one or more non-metal elements. In the case where the metal oxide contains nitrogen, for example, one or both of the first region 11 and the second region 12 may contain nitrogen. In the case where the first region 11 contains the element M1 and nitrogen at this time, for example, the first region 11 contains at least one of an oxynitride of the element M1, a nitride oxide of the element M1, and a nitride of the element M1. The first region 11 may contain the oxide of the element M1.

Note that in this specification and the like, an oxynitride refers to a material that contains more oxygen than nitrogen, and a nitride oxide refers to a material that contains more nitrogen than oxygen.

The sputtering target 10 includes at least the first region 11 and the second region 12. As illustrated in FIG. 1C, for example, the sputtering target 10 may include a third region 13 in addition to the first region 11 and the second region 12. The third region 13 contains a third metal oxide formed by combining part of the first metal oxide and part of the second metal oxide. That is, the third metal oxide contains any of the elements contained in the first metal oxide and any of the elements contained in the second metal oxide. In that case, the third metal oxide has a composition different from those of the first metal oxide and the second metal oxide.

In the case where the third region 13 is a crystal grain, a crystal grain boundary is observed between the third region 13 and the first region 11 adjacent to each other and between the third region 13 and the second region 12 adjacent to each other. Note that the crystal structure of the third region 13 may be the same as that of either the first crystal grain or the second crystal grain, or may be different from those of the first crystal grain and the second crystal grain.

In the sputtering target 10 including the first region 11, the second region 12, and the third region 13, the first region 11 and the second region 12 may each be surrounded by a plurality of the third regions 13 as illustrated in FIG. 1D.

A metal oxide formed by combining the whole first metal oxide and part of the second metal oxide may be regarded as the first metal oxide contained in the first region 11 in the sputtering target 10. Moreover, a metal oxide formed by combining part of the first metal oxide and the whole second metal oxide may be regarded as the second metal oxide contained in the second region 12 in the sputtering target 10.

In the case where the element M1 is Ga, the element M2 is In, and the element M3 is Zn, for example, it is preferable that the first region 11 contain one or more of a gallium oxide, a Ga—Zn oxide, and an In—Ga—Zn oxide and the second region 12 contain one or both of an indium oxide and an In—Zn oxide. In the case where the sputtering target 10 includes the third region 13, the third region 13 contains an In—Ga—Zn oxide.

In the case where the element M1 is Al, the element M2 is In, and the element M3 is Zn, for example, it is preferable that the first region 11 contain one or more of an aluminum oxide, an Al—Zn oxide, and an In—Al—Zn oxide and the second region 12 contain one or both of an indium oxide and an In—Zn oxide.

In the case where the sputtering target 10 contains the elements M1, M2, M3, and M4, the element M4 is contained in one or both of the first region 11 and the second region 12.

In the case where one of the elements M2 and M4 is In and the other of the elements M2 and M4 is selected from elements such as Ti, Ge, Sn, V, Ni, Mo, W, and Ta, for example, the elements M2 and M4 are preferably contained in the second region 12. In that case, the first region 11 contains an oxide containing the element M1, and the second region 12 contains an oxide containing the elements M2 and M4. One or both of the elements M2 and M4 may be contained in the first region 11. The element M3 is contained in one or both of the first region 11 and the second region 12.

Specifically, in the case where the element M1 is Ga, one of the elements M2 and M4 is In, the element M3 is Zn, and the other of the elements M2 and M4 is Sn, for example, it is preferable that the first region 11 contain one or more of a gallium oxide, a Ga—Zn oxide, an In—Ga—Zn oxide, and a Ga—Sn—Zn oxide and the second region 12 contain one or both of an In—Sn oxide and an In—Sn—Zn oxide.

In the case where one of the elements M1 and M4 is Ga and the other of the elements M1 and M4 is selected from elements such as Al, Si, Mg, Zr, and B, for example, the elements M1 and M4 are preferably contained in the first region 11. In that case, the first region 11 contains an oxide containing the elements M1 and M4, and the second region 12 contains an oxide containing the element M2. The element M3 is contained in one or both of the first region 11 and the second region 12.

### <Method for Forming Sputtering Target>

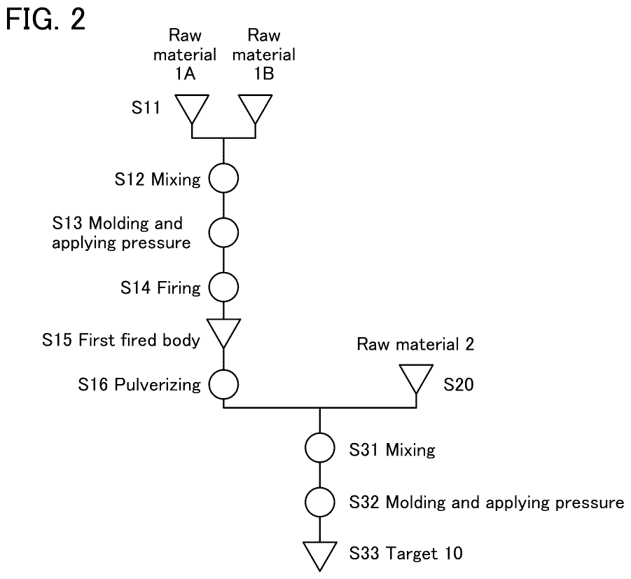

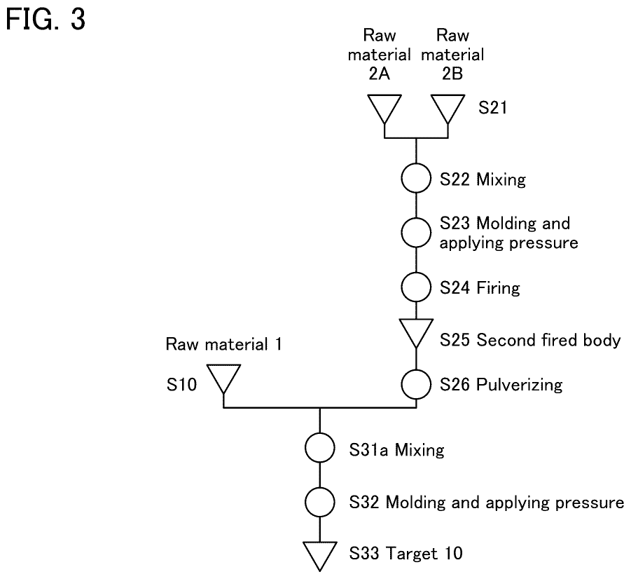

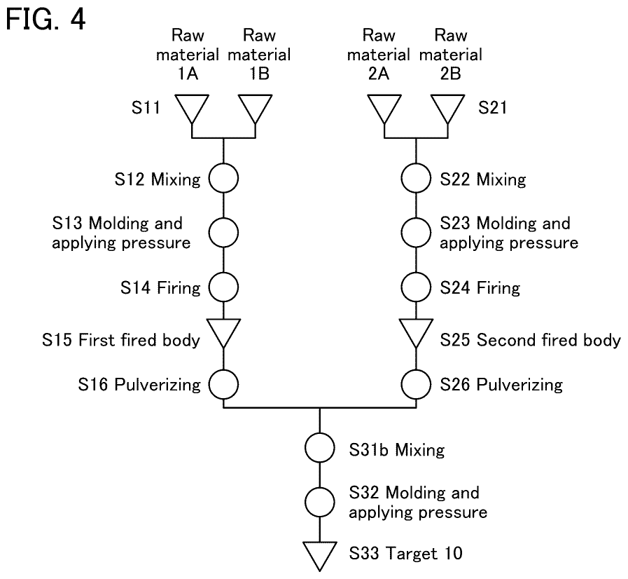

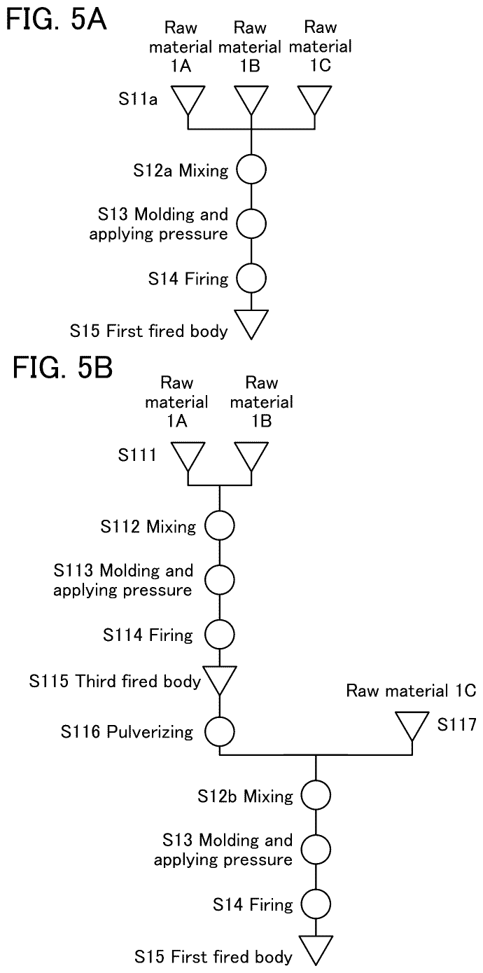

Next, methods for forming the sputtering target 10 will be described with reference to flowcharts in FIG. 2, FIG. 3, FIG. 4, FIGS. 5A and 5B, FIGS. 6A and 6B, and FIG. 7. The sputtering target 10 described here is formed using one or both of a fired body to be the first metal oxide and a fired body to be the second metal oxide. Hereinafter, the fired body to be the first metal oxide is referred to as a first fired body and the fired body to be the second metal oxide is referred to as a second fired body in some cases.

### [Formation Method Example 1]

First, an example of a method for forming the sputtering target 10 will be described with reference to the flowchart in FIG. 2. FIG. 2 shows the case of using the first fired body in the method for forming the sputtering target 10. In an example of the formation method described with reference to FIG. 2, the sputtering target 10 contains the elements M1, M2, and M3, the first metal oxide contains the elements M1 and M3, and the second metal oxide contains the element M2.

In Step S11, raw materials of the first fired body are prepared. FIG. 2 shows an example in which two kinds of powdery raw materials (a raw material 1A and a raw material 1B) are prepared as the raw materials of the first fired body. Since the first fired body contains the elements contained in the first metal oxide, a powdery oxide of the element M1 and a powdery oxide of the element M3 are used as the raw materials 1A and 1i, for example. In that case, Step S11 can be regarded as a step of weighing the oxide of the element M1 and the oxide of the element M3 that are the raw materials of the first fired body. Specifically, for example, in the case where the element M1 is Ga and the element M3 is Zn, a powdery gallium oxide and a powdery zinc oxide are used as the raw materials 1A and 1B.

With the use of raw materials with high purity, the sputtering target 10 with a low impurity concentration can be easily obtained in a later step. Specifically, the concentration of each alkali metal as an impurity can be lower than 10 ppm by weight, preferably lower than 5 ppm by weight, further preferably lower than 2 ppm by weight. The concentration of each alkaline earth metal as an impurity can be lower than 5 ppm by weight, preferably lower than 2 ppm by weight, further preferably lower than 1 ppm by weight. The concentration of each halogen as an impurity can be lower than 10 ppm by weight, preferably lower than 5 ppm by weight, further preferably lower than 2 ppm by weight. Note that these impurity concentrations are measured by secondary ion mass spectrometry (SIMS), glow discharge mass spectrometry (GDMS), inductively coupled plasma mass spectrometry (ICP-MS), or the like.

Although the oxides of elements are used in the above example, oxynitrides, nitride oxides, nitrides, or the like may be used.

Next, in Step S12, the weighed raw materials of the first fired body (the raw materials 1A and 1B in FIG. 2) are mixed to form a mixture. For example, the powdery oxide of the element M1 and the powdery oxide of the element M3 are mixed to form a mixture.

Next, in Step S13, the mixture is spread over a mold and molded. Pressure is applied to the mixture spread over the mold with a pressing machine or the like, whereby a molded body is formed. That is, Step S13 can be regarded as a step of forming a molded body by molding the mixture with pressure.

Next, the molded body is fired in Step S14. That is, Step S14 can be regarded as a step of forming a fired body by firing the molded body. A furnace (also referred to as a firing furnace or a sintering furnace) is used in the firing step. The firing step is performed in an atmosphere containing one or more of a noble gas, a nitrogen gas, and an oxygen gas.

The molded body is preferably fired at a temperature at which the elements M1 and M3 are combined with each other to form an oxide, e.g., at a temperature at which the elements M1 and M3 react with each other by heat and are transformed into a compound different from the raw materials. For example, the molded body is fired at higher than or equal to 400° C. and lower than or equal to 1700° C., preferably higher than or equal to 900° C. and lower than or equal to 1500° C. Specifically, the molded body is fired at approximately 1400° C.

Step S13 in which molding and pressure application are performed and Step S14 in which firing is performed are separately performed in the method shown in the flowchart of FIG. 2; however, the formation method described in this embodiment is not limited thereto. For example, pressure may be applied with a pressing machine while the mixture spread over the mold is fired.

Through the above steps, the first fired body can be obtained in Step S15. At this time, the first fired body is a fired body of the M1-M3 oxide. Specifically, for example, in the case where the element M1 is Ga and the element M3 is Zn, the first fired body is a fired body of a Ga—Zn oxide.

Then, in Step S16, the first fired body is pulverized to form a powder.

In Step S20, a raw material of the second metal oxide is prepared. FIG. 2 shows an example in which one kind of a powdery raw material (a raw material 2) is prepared as the raw material of the second metal oxide. For example, a powdery oxide of the element M2 is used as the raw material 2. In that case, Step S20 can be regarded as a step of weighing the oxide of the element M2 that is the raw material of the second metal oxide. Specifically, for example, in the case where the element M2 is In, a powdery indium oxide is used as the raw material 2. Although the oxide is used in the above example, an oxynitride, a nitride oxide, a nitride, or the like may be used.

Next, the powder of the first fired body formed in Step S16 and the raw material of the second metal oxide prepared in Step S20 are mixed in Step S31 to form a mixture.

Next, in Step S32, the mixture is spread over a mold and molded. Pressure is applied to the mixture spread over the mold with a pressing machine or the like, whereby a molded body is formed. That is, Step S32 can be regarded as a step of forming a molded body by molding the mixture with pressure.

When the formation of the molded body does not include high-temperature heat treatment such as firing but includes only pressure application as shown in the flowchart of FIG. 2, the combination of part of the powder of the first fired body and part of the raw material of the second metal oxide can be prevented. This enables the first metal oxide and the second metal oxide to be separated from each other in the sputtering target 10. That is, the sputtering target 10 in which the first region 11 and the second region 12 are separated from each other can be formed.

Furthermore, the use of the powder (the powder of the first fired body) formed by mixing the oxide of the element M1 and the oxide of the element M3 in Steps S12 to S16 can increase the amounts of the elements M1 and M3 contained in the first region 11.

Finishing treatment is performed on the molded body in Step S33, whereby the sputtering target 10 can be obtained. Specifically, the molded body is divided or ground to adjust the length, the width, and the thickness of the molded body. Abnormal discharge might occur when a surface of the molded body has minute unevenness; thus, polishing treatment is performed on the surface of the molded body. The polishing treatment is preferably performed by CMP.

In Step S31 in which the powder of the first fired body and the raw material of the second metal oxide are mixed, water and organic substances (a dispersing agent and a binder) may be further added to form slurry. When the powder and the raw material are mixed to form slurry, the diameters of the first region 11 and the second region 12 in the sputtering target 10 can be further reduced. In Step S12, the raw materials of the first fired body may be mixed to form slurry in a similar manner.

In the case where the powder of the first fired body and the raw material of the second metal oxide are mixed to form slurry, one or more suction ports are provided on a bottom of the mold over which the slurry is spread for molding in Step S32 and water or the like is sucked therethrough. Furthermore, a filter is provided on the bottom of the mold, through which the powder and the raw material do not pass but water and the organic substances pass. Specifically, a filter in which a porous resin film is attached over a woven fabric or a felt may be used, for example.

In Step S32, water and the like are sucked from the slurry with the filter provided on the bottom of the mold, so that water and the organic substances are removed from the slurry and the molded body is formed.

Note that water and the organic substances are left in the obtained molded body; thus, drying treatment and removal of the organic substances are performed. The drying treatment is preferably natural drying, in which case the molded body is less likely to be cracked.

In the case where the raw materials of the first fired body are mixed to form slurry in Step S12, a molded body is preferably formed in a manner similar to the above.

The sputtering target 10 is formed by pressure application to the mixture of the powder of the first fired body and the raw material of the second metal oxide in the above description. Specifically, the formation of the sputtering target 10 does not include a step of firing the molded body after the step of forming the molded body by pressure application to the mixture of the powder of the first fired body and the raw material of the second metal oxide. Note that this embodiment is not limited thereto. For example, the sputtering target 10 may be formed in the following manner: the molded body is formed by pressure application and then fired to form a fired body. A furnace is used for the firing step. The firing step is performed in an atmosphere containing one or more of a noble gas, a nitrogen gas, and an oxygen gas.

The molded body is preferably fired at a temperature at which the powder of the first fired body and the raw material of the second metal oxide are not combined with each other, i.e., at a temperature at which the M1-M3 oxide and the oxide of the element M2 are not combined with each other, e.g., at a temperature at which they do not react with each other by heat and are not transformed into a compound different from the raw materials. For example, the molded body is fired at a temperature lower than the firing temperature of the molded body in Step S14. For example, the molded body is preferably fired at higher than or equal to 200° C. and lower than 1000° C.

Alternatively, the molded body may be fired at a temperature at which at least one of the powder of the first fired body and the raw material of the second metal oxide remains after the firing step. For example, in the case where part of the powder of the first fired body remains after the firing step, the second region 12 includes a metal oxide formed by combining part of the first metal oxide and the whole second metal oxide. For another example, in the case where part of the raw material of the second metal oxide remains after the firing step, the first region 11 includes a metal oxide formed by combining the whole first metal oxide and part of the second metal oxide.

When a step of firing the molded body at a low temperature is performed, the third metal oxide containing the element in the second metal oxide and any of the elements in the first metal oxide is sometimes formed in part of the sputtering target 10. In that case, the third region 13 is formed.

The sputtering target 10 formed by firing the molded body at a low temperature can have higher strength.

In the case where slurry including the mixture is used as described above in forming the sputtering target 10, water and the organic substances slightly left in the molded body can be removed by firing.

The firing is not necessarily performed in the step different from Step S32 of molding and applying pressure. For example, pressure may be applied with a pressing machine while the mixture spread over the mold is fired at a low temperature.

### [Formation Method Example 2]

A method for forming the sputtering target 10, which is different from that shown in FIG. 2, will be described with reference to the flowchart in FIG. 3. FIG. 3 shows the case of using the second fired body in the method for forming the sputtering target 10. In an example of the formation method described with reference to FIG. 3, the sputtering target 10 contains the elements M1, M2, and M3, the first metal oxide contains the element M1, and the second metal oxide contains the elements M2 and M3.

The method for forming the sputtering target 10 shown in FIG. 3 is different from that shown in FIG. 2 mainly in that Steps S21 to S26 are performed instead of Step S20 and Step S10 is performed instead of Steps S11 to S16. Steps different from those in the formation method shown in FIG. 2 are mainly described below, and description of the same steps as those in the formation method shown in FIG. 2 is omitted.

In Step S10, a raw material of the first metal oxide is prepared. FIG. 3 shows an example in which one kind of a powdery raw material (a raw material 1) is prepared as the raw material of the first metal oxide. For example, the powdery oxide of the element M1 is used as the raw material 1. In that case, Step S10 can be regarded as a step of weighing the oxide of the element M1 that is the raw material of the first metal oxide. Specifically, for example, in the case where the element M1 is Ga, a powdery gallium oxide is used as the raw material 1.

In Step S21, raw materials of the second fired body are prepared. FIG. 3 shows an example in which two kinds of powdery raw materials (a raw material 2A and a raw material 2B) are prepared as the raw materials of the second fired body. Since the second fired body contains the elements contained in the second metal oxide, the powdery oxide of the element M2 and the powdery oxide of the element M3 are used as the raw materials 2A and 2B, for example. In that case, Step S21 can be regarded as a step of weighing the oxide of the element M2 and the oxide of the element M3 that are the raw materials of the second fired body. Specifically, for example, in the case where the element M2 is In and the element M3 is Zn, a powdery indium oxide and a powdery zinc oxide are used as the raw materials 2A and 2B.

In weighing the raw materials, for example, the powdery oxide of the element M2 and the powdery oxide of the element M3 are weighed such that the atomic ratio of the element M2 to the element M3 is [M2]: [M3]=1:1, 2:1, 4:1, or the like.

Although the oxides of elements are used in the above example, oxynitrides, nitride oxides, nitrides, or the like may be used.

Next, in Step S22, the weighed raw materials of the second fired body (the raw materials 2A and 2B in FIG. 3) are mixed to form a mixture. For example, the powdery oxide of the element M2 and the powdery oxide of the element M3 are mixed to form a mixture.

Next, the mixture is spread over a mold and molded in Step S23 in a manner similar to Step S13.

Then, the molded body is fired in Step S24 in a manner similar to Step S14.

The molded body is preferably fired at a temperature at which the elements M2 and M3 are combined with each other to form an oxide, e.g., at a temperature at which the elements M2 and M3 react with each other by heat and are transformed into a compound different from the raw materials. For example, the molded body is fired at higher than or equal to 400° C. and lower than or equal to 1700° C., preferably higher than or equal to 900° C. and lower than or equal to 1500° C. Specifically, the molded body is fired at approximately 1400° C.

Step S23 in which molding and pressure application are performed and Step S24 in which firing is performed are separately performed in the method shown in the flowchart of FIG. 3; however, the formation method described in this embodiment is not limited thereto. For example, pressure may be applied with a pressing machine while the mixture spread over the mold is fired.

Through the above steps, the second fired body can be obtained in Step S25. At this time, the second fired body is a fired body of the M2-M3 oxide. Specifically, for example, in the case where the element M2 is In and the element M3 is Zn, the second fired body is a fired body of an In—Zn oxide.

Then, in Step S26, the second fired body is pulverized to form a powder.

Next, the powder of the second fired body formed in Step S26 and the raw material of the first metal oxide prepared in Step S10 are mixed in Step S31a to form a mixture.

The steps after Step S32 can be performed in a manner similar to those in the flowchart in FIG. 2. In this manner, the sputtering target 10 in which the first region 11 and the second region 12 are separated from each other can be formed.

The use of the powder (the powder of the second fired body) formed by mixing the oxide of the element M2 and the oxide of the element M3 in Steps S22 to S26 can increase the amounts of the elements M2 and M3 contained in the second region 12.

As described for Step S31, in Step S31a in which the raw material of the first metal oxide and the powder of the second fired body are mixed, water and organic substances (a dispersing agent and a binder) may be further added to form slurry. In Step S22, the raw materials of the second fired body may be mixed to form slurry in a similar manner.

As described above, the sputtering target 10 may be formed in the following manner: the molded body is formed by pressure application and then fired at a low temperature to form a fired body. The molded body is preferably fired at a temperature at which the raw material of the first metal oxide and the powder of the second fired body are not combined with each other, i.e., at a temperature at which the oxide of the element M1 and the M2-M3 oxide are not combined with each other, e.g., at a temperature at which they do not react with each other by heat and are not transformed into a compound different from the raw materials. For example, the molded body is fired at a temperature lower than the firing temperature of the molded body in Step S24. For example, the molded body is preferably fired at higher than or equal to 200° C. and lower than 1000° C.

Alternatively, the molded body may be fired at a temperature at which at least one of the raw material of the first metal oxide and the powder of the second fired body remains after the firing step. For example, in the case where part of the raw material of the first metal oxide remains after the firing step, the second region 12 includes a metal oxide formed by combining part of the first metal oxide and the whole second metal oxide.

For another example, in the case where part of the powder of the second fired body remains after the firing step, the first region 11 includes a metal oxide formed by combining the whole first metal oxide and part of the second metal oxide.

When a step of firing the molded body at a low temperature is performed, the third metal oxide containing the element in the first metal oxide and any of the elements in the second metal oxide is sometimes formed in part of the sputtering target 10. In that case, the third region 13 is formed.

### [Formation Method Example 3]

A method for forming the sputtering target 10, which is different from those shown in FIG. 2 and FIG. 3, will be described with reference to the flowchart in FIG. 4. FIG. 4 shows the case of using the first fired body and the second fired body in the method for forming the sputtering target 10. In an example of the formation method described with reference to FIG. 4, the sputtering target 10 contains the elements M1, M2, and M3, the first metal oxide contains the elements M1 and M3, and the second metal oxide contains the elements M2 and M3.

The method for forming the sputtering target 10 shown in FIG. 4 is different from that shown in FIG. 2 mainly in that Steps S21 to S26 are performed instead of Step S20. In addition, the method for forming the sputtering target 10 shown in FIG. 4 is different from that shown in FIG. 3 mainly in that Steps S11 to S16 are performed instead of Step S10. That is, in the method for forming the sputtering target shown in FIG. 4, the first fired body and the second fired body are formed in parallel. Note that either of the sequence of Steps S11 to S16 and the sequence of Steps S21 to S26 may be performed first. Steps different from those in the formation methods shown in FIG. 2 and FIG. 3 are mainly described below, and description of the same steps as those in the formation methods shown in FIG. 2 and FIG. 3 is omitted.

In weighing the raw materials, the powdery oxide of the element M1, the powdery oxide of the element M2, and the powdery oxide of the element M3 are prepared, and a method similar to those in Step S11 in FIG. 2 and Step S21 in FIG. 3 is employed. Since the element M3 is contained in each of the first metal oxide and the second metal oxide, the oxide of the element M3 to be contained in the first fired body, which is referred to as a first oxide of the element M3, and the oxide of the element M3 to be contained in the second fired body, which is referred to as a second oxide of the element M3, are separately weighed.

Step S12 shown in FIG. 4 is performed using the powdery oxide of the element M1 and the powdery first oxide of the element M3 weighed in Step S11 shown in FIG. 4 in a manner similar to Step S12 in the above, whereby a mixture is formed. Step S22 shown in FIG. 4 is performed using the powdery oxide of the element M2 and the powdery second oxide of the element M3 weighed in Step S21 shown in FIG. 4 in a manner similar to Step S22 in the above, whereby a mixture is formed.

Refer to the above description for Steps S13 to S16 and Steps S23 to S26 shown in FIG. 4.

Next, the powder of the first fired body formed in Step S16 and the powder of the second fired body formed in Step S26 are mixed in Step S31b to form a mixture. The steps after Step S32 can be performed in a manner similar to those in the flowchart in FIG. 2.

The above is the description of the method for forming the sputtering target 10 shown in FIG. 4.

### [Example of Method for Forming First Fired Body]

FIG. 2 and FIG. 4 show the examples of the formation methods in which the first metal oxide contains the elements M1 and M3. Next, a method for forming the first fired body, in which the first metal oxide contains the elements M1, M2, and M3, will be described with reference to FIGS. 5A and 5B.

In Step S11a, the raw materials of the first fired body are prepared. In FIG. 5A, three kinds of powdery raw materials (the raw materials 1A and 1B and a raw material 1C) are prepared as the raw materials of the first fired body. Since the first fired body contains the elements contained in the first metal oxide, the powdery oxide of the element M1, the powdery oxide of the element M3, and the powdery oxide of the element M2 are used as the raw materials 1A, 1, and 1C, for example. In that case, Step S11a can be regarded as a step of weighing the oxide of the element M1, the oxide of the element M2, and the oxide of the element M3 that are the raw materials of the first fired body. Specifically, for example, in the case where the element M1 is Ga, the element M2 is In, and the element M3 is Zn, a powdery gallium oxide, a powdery zinc oxide, and a powdery indium oxide are used as the raw materials 1A, 1B, and 1C.

Since the element M2 is contained in each of the first metal oxide and the second metal oxide, the oxide of the element M2 to be contained in the first fired body and the oxide of the element M2 to be contained in the second fired body are separately weighed. The element M3 may also be contained in the second metal oxide. In that case, the oxide of the element M3 to be contained in the first fired body and the oxide of the element M3 to be contained in the second fired body are separately weighed.

Next, in Step S12a, the weighed raw materials of the first fired body (the raw materials 1A, 1i, and 1C in FIG. 5A) are mixed to form a mixture. For example, the powdery oxide of the element M1, the powdery oxide of the element M2, and the powdery oxide of the element M3 are mixed to form a mixture. The steps after Step S13 can be performed in a manner similar to those in the flowchart in FIG. 2.

Through the above steps, the first fired body containing the elements M1, M2, and M3 can be formed.

The method for forming the first fired body that is different from that in FIG. 5A will be described with reference to a flowchart of FIG. 5B. In the method for forming the first fired body in FIG. 5B, a third fired body formed using the raw materials 1A and 1B is used.

The method for forming the first fired body in FIG. 5B is different from that in FIG. 5A in that Steps S111 to S117 and S12b are performed instead of Steps S11a and S12a.

In Step S111, the raw materials of the third fired body are prepared. FIG. 5B shows an example in which two kinds of powdery raw materials (the raw materials 1A and 1B) are prepared as the raw materials of the third fired body. For example, the powdery oxide of the element M1 and the powdery oxide of the element M3 are used as the raw materials 1A and 1B. In that case, Step S111 can be regarded as a step of weighing the oxide of the element M1 and the oxide of the element M3 that are the raw materials of the third fired body.

Refer to the description of Steps S12 to S16 in FIG. 2 for Steps S112 to S116.

In Step S117, the raw material of the first fired body is prepared. FIG. 5B shows an example in which one kind of a powdery raw material (the raw material 1C) is prepared as one of the raw materials of the first fired body. The first fired body is formed using the powder of the third fired body and the raw material 1C. Since the third fired body contains the elements M1 and M3, the powdery oxide of the element M2 is used as the raw material 1C, for example. In that case, Step S117 can be regarded as a step of weighing the oxide of the element M2 that is one of the raw materials of the first fired body.

Next, the powder of the third fired body formed in Step S116 and one of the raw materials (the raw material 1C) of the first fired body prepared in Step S117 are mixed in Step S12b to form a mixture. The steps after Step S13 can be performed in a manner similar to those in the flowchart in FIG. 2.

Through the above steps, the first fired body containing the elements M1, M2, and M3 can be formed.

Although FIG. 5B shows the example in which the first fired body is formed using the raw material 1C and the powder of the third fired body containing the elements M1 and M3, the present invention is not limited thereto. The first fired body may be formed using the raw material 1B and the powder of the third fired body containing the elements M1 and M2 or may be formed using the raw material 1A and the powder of the third fired body containing the elements M2 and M3.

In the case where the first metal oxide contains the elements M1, M3, and M4, the element M2 in the description of [Example of method for forming first fired body] can be replaced with the element M4.

### [Example of Method for Forming Second Fired Body]

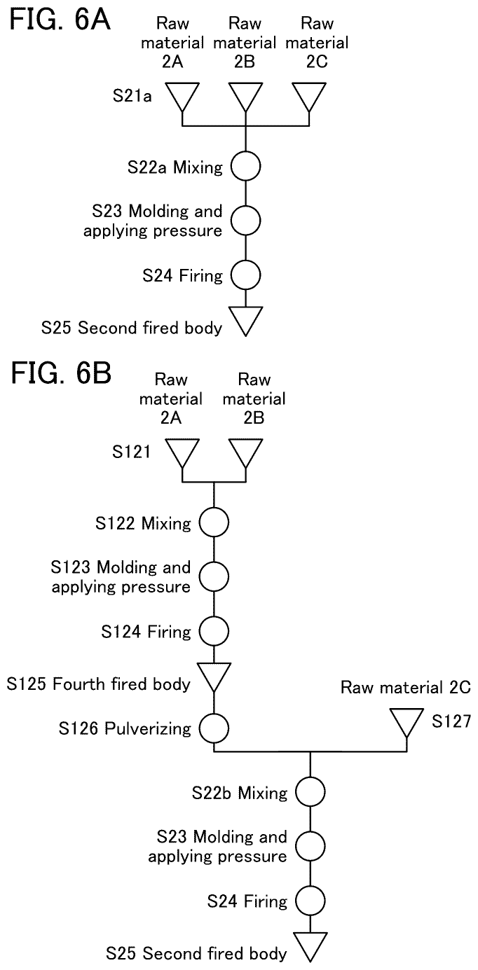

FIG. 3 and FIG. 4 show the examples of the formation methods in which the second metal oxide contains the elements M2 and M3. Next, a method for forming the second fired body, in which the second metal oxide contains the elements M2, M3, and M4, will be described with reference to FIGS. 6A and 6B.

In Step S21a, the raw materials of the second fired body are prepared. In FIG. 6A, three kinds of powdery raw materials (the raw materials 2A and 2B and a raw material 2C) are prepared as the raw materials of the second fired body. Since the second fired body contains the elements contained in the second metal oxide, the powdery oxide of the element M2, the powdery oxide of the element M3, and the powdery oxide of the element M4 are used as the raw materials 2A, 2B, and 2C, for example. In that case, Step S21a can be regarded as a step of weighing the oxide of the element M2, the oxide of the element M3, and the oxide of the element M4 that are the raw materials of the second fired body. Specifically, for example, in the case where the element M2 is In, the element M3 is Zn, and the element M4 is Sn, a powdery indium oxide, a powdery zinc oxide, and a powdery tin oxide are used as the raw materials 2A, 2B, and 2C.

The element M3 may also be contained in the first metal oxide. In that case, the oxide of the element M3 to be contained in the first fired body and the oxide of the element M3 to be contained in the second fired body are separately weighed.

Next, in Step S22a, the weighed raw materials of the second fired body (the raw materials 2A, 2B, and 2C in FIG. 6A) are mixed to form a mixture. For example, the powdery oxide of the element M2, the powdery oxide of the element M3, and the powdery oxide of the element M4 are mixed to form a mixture. The steps after Step S23 can be performed in a manner similar to those in the flowchart in FIG. 3.

Through the above steps, the second fired body containing the elements M2, M3, and M4 can be formed.

The method for forming the second fired body that is different from that in FIG. 6A will be described with reference to a flowchart of FIG. 6B. In the method for forming the second fired body in FIG. 6B, a fourth fired body formed using the raw materials 2A and 2B is used.

The method for forming the second fired body in FIG. 6B is different from that in FIG. 6A in that Steps S121 to S127 and S22b are performed instead of Steps S21a and S22a.

In Step S121, the raw materials of the fourth fired body are prepared. FIG. 6B shows an example in which two kinds of powdery raw materials (the raw materials 2A and 2B) are prepared as the raw materials of the fourth fired body. For example, the powdery oxide of the element M2 and the powdery oxide of the element M3 are used as the raw materials 2A and 2B. In that case, Step S121 can be regarded as a step of weighing the oxide of the element M2 and the oxide of the element M3 that are the raw materials of the fourth fired body.

Refer to the description of Steps S22 to S26 in FIG. 3 for Steps S122 to S126.

In Step S127, the raw material of the second fired body is prepared. FIG. 6B shows an example in which one kind of a powdery raw material (the raw material 2C) is prepared as one of the raw materials of the second fired body. The second fired body is formed using the powder of the fourth fired body and the raw material 2C. Since the fourth fired body contains the elements M2 and M3, the powdery oxide of the element M4 is used as the raw material 2C, for example. In that case, Step S127 can be regarded as a step of weighing the oxide of the element M4 that is one of the raw materials of the second fired body.

Next, the powder of the fourth fired body formed in Step S126 and one of the raw materials (the raw material 2C) of the second fired body prepared in Step S127 are mixed in Step S22b to form a mixture. The steps after Step S23 can be performed in a manner similar to those in the flowchart in FIG. 3.

Through the above steps, the second fired body containing the elements M2, M3, and M4 can be formed.

Although FIG. 6B shows the example in which the second fired body is formed using the raw material 2C and the powder of the fourth fired body containing the elements M2 and M3, the present invention is not limited thereto. The second fired body may be formed using the raw material 2B and the powder of the fourth fired body containing the elements M2 and M4 or may be formed using the raw material 2A and the powder of the fourth fired body containing the elements M3 and M4.

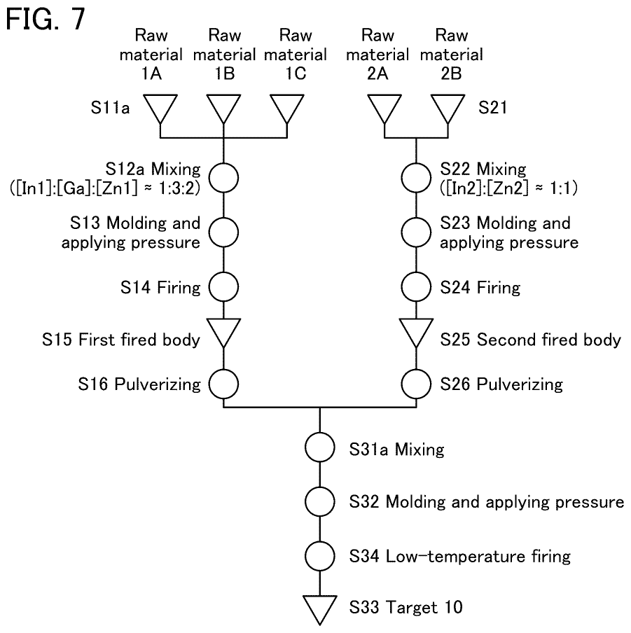

The sputtering target 10 containing the elements M2 and M3 in each of the first region 11 and the second region 12 can be formed by the formation method in which Steps S11a and S12a in FIG. 5A are performed instead of Steps S11 and S12 shown in the flowchart of FIG. 4. An example of forming the sputtering target 10 in which Ga, In, and Zn are respectively used as the elements M1, M2, and M3, the first region 11 has an atomic ratio of [In]: [Ga]: [Zn]=1:3:2, and the second region 12 has an atomic ratio of [In]: [Zn]=1:1 will be described below with reference to FIG. 7. Note that in the formation method described below, the kinds and the atomic ratio of elements are not limited to the above, and the sputtering target 10 is formed with appropriate kinds and an appropriate atomic ratio of elements by a similar method.

In weighing the raw materials, a powdery gallium oxide, a powdery indium oxide, and a powdery zinc oxide are prepared, and a method similar to that in Steps S11a and S21 is employed. In order that the first region 11 and the second region 12 can each contain indium and zinc, the indium oxide to be contained in the first fired body, which is referred to as a first indium oxide, and the indium oxide to be contained in the second fired body, which is referred to as a second indium oxide, are separately weighed. In addition, the zinc oxide to be contained in the first fired body, which is referred to as a first zinc oxide, and the zinc oxide to be contained in the second fired body, which is referred to as a second zinc oxide, are separately weighed.

Thus, for example, in the case where the sputtering target 10 having an atomic ratio of [In]: [Ga]: [Zn]=3:3:4 is formed, the powdery first indium oxide, the powdery second indium oxide, the powdery gallium oxide, the powdery first zinc oxide, and the powdery second zinc oxide are weighed such that the atomic ratio between first indium (hereinafter, sometimes referred to as In1), second indium (hereinafter, sometimes referred to as In2), gallium, first zinc (hereinafter, sometimes referred to as Zn1), and second zinc (hereinafter, sometimes referred to as Zn2) is [In1]: [In2]: [Ga]: [Zn1]: [Zn2]=1:2:3:2:2.

Next, Step S12a shown in FIG. 7 is performed using the powdery first indium oxide, the powdery gallium oxide, and the powdery first zinc oxide weighed in Step S11a shown in FIG. 7 in a manner similar to Step S12a in the above, whereby a mixture is formed. In Step S12a shown in FIG. 7, the powdery first indium oxide, the powdery gallium oxide, and the powdery first zinc oxide are mixed at an atomic ratio of [In1]: [Ga]: [Zn1]=1:3:2, whereby a mixture is formed.

The example in which the powdery first indium oxide, the powdery gallium oxide, and the powdery first zinc oxide are mixed at an atomic ratio of [In1]: [Ga]: [Zn1]=1:3:2 as the raw materials of the first fired body is described above; however, the formation method described in this embodiment is not limited to this example, and the amounts of the powdery first indium oxide, the powdery gallium oxide, and the powdery first zinc oxide to be mixed are determined as appropriate.

Refer to the description of Steps S13 to S16 in FIG. 2 for Steps S13 to S16. In the case where a molded body of the first indium oxide, the gallium oxide, and the first zinc oxide is fired in Step S14, the molded body is fired at higher than or equal to 400° C. and lower than or equal to 2500° C., preferably higher than or equal to 900° C. and lower than or equal to 1900° C.

Then, Step S22 shown in FIG. 7 is performed using the powdery second indium oxide and the powdery second zinc oxide weighed in Step S21 shown in FIG. 7 in a manner similar to Step S22 in the above, whereby a mixture is formed. In Step S22, the powdery second indium oxide and the powdery second zinc oxide are mixed at an atomic ratio of [In2]: [Zn2]=1:1, whereby a mixture is formed.

The example in which the powdery second indium oxide and the powdery second zinc oxide are mixed at an atomic ratio of [In2]: [Zn2]=1:1 as the raw materials of the second fired body is described above; however, the formation method described in this embodiment is not limited thereto, and the amounts of the powdery second indium oxide and the powdery second zinc oxide to be mixed are determined as appropriate.

As shown in FIG. 6A and the like, an element other than indium and zinc (e.g., the element M4) may be used as a raw material of the second fired body. In the case where Ti, W, Sn, or the like is used as the element, for example, a powdery titanium oxide, a powdery tungsten oxide, a powdery tin oxide, or the like is used.

Refer to the description of Steps S23 to S26 in FIG. 3 for Steps S23 to S26. In the case where a molded body of the second indium oxide and the second zinc oxide is fired in Step S24, the molded body is fired at higher than or equal to 400° C. and lower than or equal to 1700° C., preferably higher than or equal to 900° C. and lower than or equal to 1500° C. For example, the molded body is fired at approximately 1400° C.

Next, in a manner similar to Step S31a in the above, the powder of the first fired body formed in Step S16 and the powder of the second fired body formed in Step S26 are mixed in Step S31a in FIG. 7, whereby a mixture is formed.

Next, the mixture is spread over a mold and molded in Step S32 in FIG. 7 in a manner similar to Step S32 in the above.

Then, low-temperature firing is preferably performed in Step S34 in FIG. 7. A furnace is used for the firing. The firing is performed in an atmosphere containing one or more of a noble gas, a nitrogen gas, and an oxygen gas.

The molded body is preferably fired at a temperature at which the powder of the first fired body and the powder of the second fired body are not combined with each other, i.e., at a temperature at which the In—Ga—Zn oxide contained in the powder of the first fired body and the In—Zn oxide contained in the powder of the second fired body are not combined with each other, e.g., at a temperature at which they do not react with each other by heat and are not transformed into a compound different from the raw materials. For example, the molded body is fired at a temperature lower than the firing temperatures in Steps S14 and S24. For example, the molded body is fired at a temperature lower than the firing temperatures in Steps S14 and S24 by approximately 200° C. to 300° C. Specifically, the molded body is preferably fired at higher than or equal to 200° C. and lower than 1200° C.

The sputtering target 10 formed by firing the molded body at a low temperature can have higher strength.

The low-temperature firing in Step S34 is not necessarily performed in the step different from Step S32 of molding and applying pressure. For example, pressure may be applied with a pressing machine while the mixture spread over the mold is fired at a low temperature.

In the case where the sputtering target 10 has strength high enough at the end of Step S32, Step S34 is not necessarily performed and the process may proceed to Step S33.

Next, finishing treatment is performed on the molded body in Step S33 in FIG. 7 in a manner similar to Step S33 in the above, whereby the sputtering target 10 can be obtained.

As shown in the flowchart of FIG. 7, the sputtering target 10 is formed in the following manner: high-temperature heat treatment is not performed after the powder of the first fired body and the powder of the second fired body are separately formed by firing and pulverizing the first metal oxide and the second metal oxide. In this manner, the sputtering target 10 can be formed without combination of the first metal oxide and the second metal oxide. Thus, the first region 11 and the second region 12 can be separated from each other in the sputtering target 10.

Moreover, the powder of the first fired body is formed through Steps S12a to S16 in advance, so that the proportion of gallium in the first region 11 can be increased. In addition, the powder of the second fired body is formed through Steps S22 to S26 in advance, so that the proportions of indium and zinc in the second region 12 can be increased. In this manner, the first region 11 and the second region 12 in the sputtering target 10 can have different compositions.

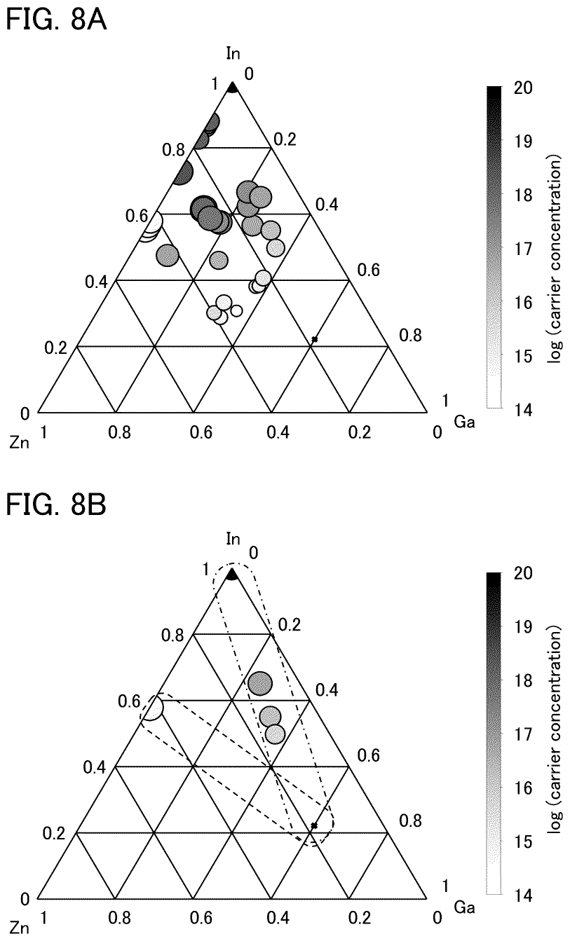

The example of the method for forming the sputtering target 10 for depositing the metal oxide containing In, Ga, and Zn is described above with reference to FIG. 7. Preferred ranges of the atomic ratio between indium, gallium, and zinc contained in the metal oxide of one embodiment of the present invention will be described below with reference to FIGS. 8A and 8B. The terms of the atomic ratios of indium, gallium, and zinc contained in the metal oxide are denoted by [In], [Ga], and [Zn], respectively. FIGS. 8A and 8B show ternary plots.

Note that the proportion of oxygen atoms is not shown in FIGS. 8A and 8B. A metal oxide to which a slight amount of an element other than In, Ga, and Zn is added may be shown in the plots of FIGS. 8A and 8B.

Circles in the plots of FIGS. 8A and 8B each show a composition, Hall mobility, and carrier concentration of a metal oxide. For example, the center of the circle represents a composition of a metal oxide, the diameter of the circle represents Hall mobility of a metal oxide, and the gradation of the circle represents a carrier concentration of a metal oxide. Specifically, the circle with a larger diameter represents a higher Hall mobility of a metal oxide, whereas the circle with a smaller diameter represents a lower Hall mobility of a metal oxide. In addition, the darker-colored (blacker) circle represents a higher carrier concentration of a metal oxide, whereas the lighter-colored (whiter) circle represents a lower carrier concentration of a metal oxide. FIG. 8B shows some of the circles in the plot of FIG. 8A.

The composition of a metal oxide can be evaluated by ICP-MS, for example. The Hall mobility and carrier concentration of a metal oxide can be evaluated by the Hall effect measurement, for example.

In FIGS. 8A and 8B, the circle with a larger diameter represents a metal oxide with higher mobility and the lighter-colored (whiter) circle represents a metal oxide with a lower carrier concentration. A lower carrier concentration of a metal oxide including a channel formation region can achieve a transistor having normally-off characteristics.

As shown in FIG. 8A, a metal oxide having a high indium content tends to be represented by the dark-colored (black) circle with a large diameter. That is, a transistor including such a metal oxide can have high mobility but might have normally-on characteristics. An indium content refers to the proportion of the number of indium atoms to the sum of the number of atoms of all metal elements contained in a metal oxide. The same can apply to a gallium content by replacing indium in the above description with gallium.

A metal oxide having a high gallium content tends to be represented by the light-colored (white) circle with a small diameter. That is, a higher gallium content results in a higher insulating property of a metal oxide. Thus, a transistor including such a metal oxide can have normally-off characteristics but might have low mobility.

As described above, a transistor including a first metal oxide having a high gallium content and a second metal oxide having a high indium content can have both high mobility and normally-off characteristics.

A region surrounded by a dotted line in FIG. 8B represents the range of the atomic ratio that the sputtering target 10 can have when the atomic ratio of the first fired body is [In]: [Ga]: [Zn]=1:3:2 and the atomic ratio of the second fired body is [In]: [Ga]: [Zn]=1:0:1.

For example, when the molar ratio of the powder of the first fired body having an atomic ratio of [In1]: [Ga]: [Zn1]=1:3:2 to the powder of the second fired body having an atomic ratio of [In2]: [Zn2]=1:1 is set to 1:2, the sputtering target 10 having an atomic ratio of [In]: [Ga]: [Zn]=3:3:4 can be formed.

The atomic ratio of the sputtering target 10 is not limited to the above, and the sputtering target 10 can have a given atomic ratio by appropriately setting the molar ratio of the powder of the first fired body to the powder of the second fired body. For example, adjustment of the molar ratio of the powder of the first fired body having an atomic ratio of [In1]: [Ga]: [Zn1]=1:3:2 to the powder of the second fired body having an atomic ratio of [In2]: [Zn2]=1:1 allows the atomic ratio of the sputtering target 10 to fall within the range from [In]: [Ga]: [Zn]=1:3:2 to 1:0:1. In this manner, the use of the first fired body and the second fired body with different atomic ratios and the adjustment of the ratio of the first fired body to the second fired body can expand the range of the atomic ratio of the sputtering target 10.

A region surrounded by a dashed-dotted line in FIG. 8B represents the range of the atomic ratio that the sputtering target 10 can have when the atomic ratio of the first fired body is [In]: [Ga]: [Zn]=1:3:2 and the second fired body is an indium oxide to which Sn is added. Note that a slight amount of Sn is added to the indium oxide; thus, the indium oxide may be plotted at an atomic ratio of [In]: [Ga]: [Zn]=1:0:0. Alternatively, since Sn is an element that can serve as a carrier supply source as described later, [In] in FIG. 8B can be regarded as the sum of the numbers of In atoms and Sn atoms; hence, the indium oxide to which Sn is added may be plotted at an atomic ratio of [In]: [Ga]: [Zn]=1:0:0.

For example, adjustment of the molar ratio of the powder of the first fired body having an atomic ratio of [In1]: [Ga]: [Zn]=1:3:2 to the powder of the second fired body containing the indium oxide to which Sn is added allows the atomic ratio of the sputtering target 10 to fall within the range from [In]: [Ga]: [Zn]=1:3:2 to 1:0:0.

### <Sputtering Apparatus>

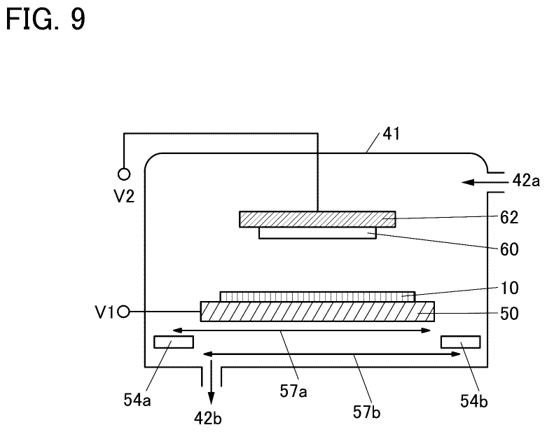

A sputtering apparatus in which the sputtering target 10 can be used will be described with reference to FIG. 9. FIG. 9 is a cross-sectional view illustrating a deposition chamber 41 of a sputtering apparatus.

The deposition chamber 41 illustrated in FIG. 9 includes a substrate holder 62, the sputtering target 10, a backing plate 50, and a magnet unit. One or more magnet units can be provided. The magnet unit can be fixed or have an oscillation mechanism. Note that the sputtering target 10 is placed over and fixed to the backing plate 50. When a substrate 60 is transferred into the deposition chamber 41, the substrate 60 is placed in contact with the substrate holder 62. The deposition chamber 41 includes an inlet 42a for supplying gas (also referred to as deposition gas) and an outlet 42b. A deposition gas is supplied to the deposition chamber 41 through the inlet 42a and exhausted through the outlet 42b.

FIG. 9 illustrates an example in which a magnet unit 54a and a magnet unit 54b are provided. The magnet units 54a and 54b are placed under the sputtering target 10 with the backing plate 50 therebetween. The magnet units 54a and 54b each have an oscillation mechanism: the magnet unit 54a has an oscillation range 57a and the magnet unit 54b has an oscillation range 57b. When the magnet units 54a and 54b are oscillated in the range where the sputtering target 10 is placed, a uniform film can be formed. For example, the magnet unit 54a or the magnet unit 54b may be oscillated with a beat (also referred to as rhythm, pulse, frequency, period, cycle, or the like) of greater than or equal to 0.1 Hz and less than or equal to 1 kHz.

The magnetic field that the sputtering target 10 receives is determined by voltage V2 applied to the substrate holder 62 and voltage V1 applied to the backing plate 50. The magnetic field that the sputtering target 10 receives changes in accordance with oscillation of the magnet units. A region with an intense magnetic field is a high-density plasma region; thus, sputtering of the sputtering target 10 easily occurs in the vicinity of the region. In the case where the sputtering target 10 contains a plurality of elements, the intensity of the magnetic field applied from the magnet unit 54a to the sputtering target 10 can be made different from the intensity of the magnetic field applied from the magnet unit 54b to the sputtering target 10. Elements based on the magnetic field intensity are deposited on the substrate 60.

FIG. 9 illustrates an example in which a parallel-plate sputtering apparatus is used; however, a method for depositing a metal oxide of this embodiment is not limited thereto. For example, a metal oxide may be deposited using a facing-target sputtering apparatus.

A sputtering method, which enables low-temperature deposition, can increase the productivity of a semiconductor device or the like including a metal oxide.

### <Step of Depositing Metal Oxide on Substrate>

Next, a step of depositing the metal oxide on the substrate using the sputtering target 10 will be described.

In a step of depositing a metal oxide on a substrate, for example, in the deposition chamber 41 illustrated in FIG. 9, an argon gas, a nitrogen gas, or an oxygen gas is ionized to be separated into cations and electrons, and plasma is created. Then, the cations in the plasma are accelerated toward the sputtering target 10 by the potential applied to the backing plate 50. Sputtered particles are generated when the cations collide with the sputtering target 10, and the sputtered particles are deposited on the substrate 60.

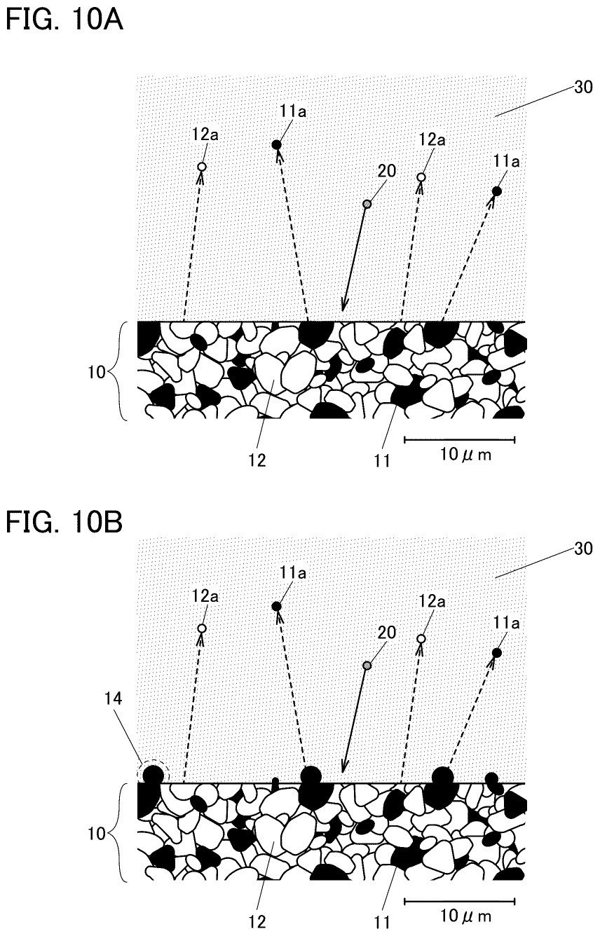

FIG. 10A is a schematic view of the vicinity of the sputtering target 10 during deposition of a metal oxide. FIG. 10A illustrates the sputtering target 10, plasma 30, a cation 20, first sputtered particles 11a, and second sputtered particles 12a.

In FIG. 10A, an argon gas, an oxygen gas, or a nitrogen gas is ionized and separated into the cation 20 and an electron (not illustrated), and the plasma 30 is created. After that, the cation 20 in the plasma 30 is accelerated toward the sputtering target 10. The cation 20 collides with the sputtering target 10, whereby the first sputtered particles 11a and the second sputtered particles 12a are generated and ejected from the sputtering target 10. Since the first sputtered particles 11a are ejected from the first region 11, a cluster including a large amount of the element M1 is formed in some cases. Since the second sputtered particles 12a are ejected from the second region 12, a cluster including a large amount of the element M2 is formed in some cases.

The first sputtered particles 11a ejected from the first region 11 and the second sputtered particles 12a ejected from the second region 12 are individually deposited over the substrate. A region including the first sputtered particles 11a and a region including the second sputtered particles 12a are unevenly formed over the substrate.

In the case where gallium is used as the element M1, a precipitation portion 14 is formed on the top surface of the sputtering target 10 in some cases as illustrated in FIG. 10B. The precipitation portion 14 is formed mainly of gallium contained in the first region 11, and has a spherical form or a granular form due to surface tension in some cases. The atomic ratio of gallium contained in the precipitation portion 14 is thus higher than the atomic ratio of gallium contained in the first region 11 in some cases. The content of gallium contained in the precipitation portion 14 is higher than the content of gallium contained in the first region 11 in some cases. Furthermore, zinc, a zinc oxide, or the like is formed to cover the surface of the precipitation portion 14 in some cases.

When the cation 20 typified by an argon ion or the like collides with the first region 11 exposed on the top surface of the sputtering target 10, oxygen is released from the first region 11, and elemental gallium, elemental zinc, or the like is formed on the surface of the sputtering target 10. Since elemental gallium has a melting point of as low as approximately 30° C., the formed elemental gallium is melted due to heat generated by sputtering. Melted gallium aggregates owing to surface tension to form the spherical or granular precipitation portion 14.

The solid-solution range of zinc with respect to gallium in the vicinity of the melting point of elemental gallium is approximately 1 atomic %. Because of this, zinc rarely exists inside the precipitation portion 14, and zinc, a zinc oxide, or the like is formed to cover the surface of the precipitation portion 14 in some cases.

The first sputtered particles 11a ejected from the precipitation portion 14 contain a larger amount of gallium than the first sputtered particles 11a ejected from the first region 11 in many cases. Accordingly, the amount of gallium contained in a region including the first sputtered particles 11a, which is formed on the substrate by sputtering, sometimes increases.

The above is the description of the step of depositing the metal oxide on the substrate using the sputtering target 10.

Next, a metal oxide deposited using the sputtering target 10 will be described. The metal oxide deposited using the sputtering target 10 includes a plurality of components.

The metal oxide deposited using the sputtering target 10 includes a first component and a second component. The first component contains an oxide containing the elements of the first region 11 in the sputtering target 10, and the second component contains an oxide containing the elements of the second region 12 in the sputtering target 10.

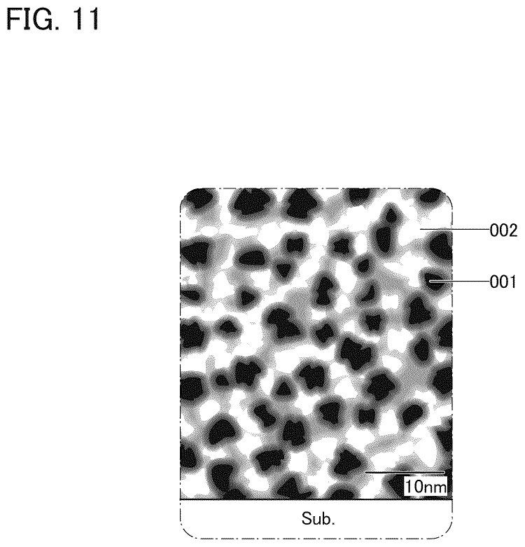

A composition in which the metal oxide contains the elements Ma and Mb is described here with reference to FIG. 11.

### <Composition of Metal Oxide>

FIG. 11 is a conceptual view of a metal oxide having a cloud-aligned composite (CAC) composition in one embodiment of the present invention. In this specification, a metal oxide of one embodiment of the present invention having a semiconductor function is defined as a cloud-aligned composite oxide semiconductor (CAC-OS).

The metal oxide described in this embodiment preferably contains an element Ma and an element Mb respectively contribute to an insulating property and conductivity of the metal oxide. Note that contribution to the insulating property or conductivity of the metal oxide is relative, and the degree of contribution of each element depends on the combination of elements contained in the metal oxide. Thus, the element Ma can be regarded as an element that makes larger contribution to the insulating property of the metal oxide than the element Mb. The element Mb can be regarded as an element that makes larger contribution to the conductivity of the metal oxide than the element Ma.

Examples of the element Ma include Al, Ga, Si, Mg, Zr, and B. It is preferable that one or more of the above elements be used as the element Ma. Examples of the element Mb include In, Zn, Ti, Ge, Sn, V, Ni, Mo, W, and Ta. It is preferable that one or more of the above elements be used as the element Mb.

In that case, the element Ma and the element Mb correspond to the element M1 and the element M2, respectively, in the sputtering target 10.

As the element M3 in the sputtering target 10, it is preferable to use one of the elements that can be selected as the element Mb, and it is particularly preferable to use Zn. In the case where Zn is selected as one of the elements M1 and M2 in the sputtering target 10, one of the elements that can be selected as the element Ma or the element Mb is used as the element M3.

One of the elements that can be selected as the element Ma or the element Mb is used as the element M4 in the sputtering target 10.

For example, in the CAC-OS, as illustrated in FIG. 11, elements contained in the metal oxide are unevenly distributed, and regions 001 mainly containing an element and regions 002 mainly containing another element are formed. The regions 001 and 002 are mixed to form a mosaic pattern. In other words, the CAC-OS has a composition in which elements contained in a metal oxide are unevenly distributed. Materials including unevenly distributed elements each have a size greater than or equal to 0.5 nm and less than or equal to 10 nm, preferably greater than or equal to 1 nm and less than or equal to 2 nm, or a similar size. Note that in the following description of a metal oxide, a state in which one or more metal elements are unevenly distributed and regions containing the metal element(s) are mixed is referred to as a mosaic pattern or a patch-like pattern. The regions each have a size greater than or equal to 0.5 nm and less than or equal to 10 nm, preferably greater than or equal to 1 nm and less than or equal to 2 nm, or a similar size.

An Ma-Mb oxide with a CAC composition has a composition in which materials are separated into an oxide containing the element Ma and an oxide containing the element Mb to form a mosaic pattern and the oxide containing the element Ma and forming the mosaic pattern and the oxide containing the element Mb and forming the mosaic pattern are distributed in the film (such a composition is hereinafter also referred to as a cloud-like composition).

For example, an In—Ga—Zn oxide with a CAC composition has a composition in which materials are separated into a gallium oxide and an indium oxide or an In—Zn oxide to form a mosaic pattern and the gallium oxide forming the mosaic pattern and the indium oxide or In—Zn oxide forming the mosaic pattern are distributed in the film (such a composition is hereinafter also referred to as a cloud-like composition).

In other words, the metal oxide of one embodiment of the present invention includes at least two oxides or components selected from a gallium oxide, an indium oxide, a zinc oxide, an In—Ga oxide, a Ga—Zn oxide, an In—Zn oxide, and an In—Ga—Zn oxide. It is particularly preferable that the at least two oxides be selected from each of a group of oxides containing Ga and a group of oxides containing In.

In the case where the element Ma is Ga and the element Mb is In, Sn, and Zn, for example, the metal oxide of one embodiment of the present invention includes at least two oxides selected from a gallium oxide, an indium oxide, a tin oxide, a zinc oxide, an In—Ga oxide, a Ga—Sn oxide, a Ga—Zn oxide, an In—Sn oxide, an In—Zn oxide, a Sn—Zn oxide, an In—Ga—Zn oxide, an In—Sn—Zn oxide, and an In—Ga—Sn—Zn oxide.

In the case where the element Ma is Ga and Al and the element Mb is In and Zn, for example, the metal oxide of one embodiment of the present invention includes at least two oxides selected from a gallium oxide, an aluminum oxide, an indium oxide, a zinc oxide, a Ga—Al oxide, an In—Ga oxide, a Ga—Zn oxide, an In—Al oxide, an Al—Zn oxide, an In—Zn oxide, an In—Ga—Zn oxide, an In—Al—Zn oxide, and an In—Al—Ga—Zn oxide.

That is, the metal oxide of one embodiment of the present invention can be referred to as a composite material including a plurality of materials or a plurality of components.

Here, let a concept in FIG. 11 illustrate the Ma-Mb oxide with the CAC composition. In that case, it can be said that the region 001 is a region containing the oxide containing the element Ma as a main component and the region 002 is a region containing the oxide containing the element Mb as a main component. Surrounding portions of the region 001 and the region 002 are unclear (blurred), so that boundaries of the region 001 and the region 002 are not clearly observed in some cases. That is, the Ma-Mb oxide with the CAC composition is a metal oxide in which the region containing the oxide containing the element Ma as a main component and the region containing the oxide containing the element Mb as a main component are mixed. Accordingly, the metal oxide is referred to as a composite metal oxide in some cases.

The region 001 preferably further contains one of the elements that can be selected as the element Mb, and particularly preferably contains zinc. In that case, both the region 001 and the region 002 contain zinc. Furthermore, it is preferable that zinc be also contained in a region between the region 001 and the region 002 (e.g., such a region corresponds to a gray region in FIG. 11 and also includes the unclear region in the surrounding portions of the region 001 and the region 002). Zinc spreads in a cloud-like manner in the metal oxide, and the region 001 and the region 002 can be regarded as being connected to each other through a region containing zinc. Note that the atomic ratio of zinc contained in the region between the region 001 and the region 002 is sometimes higher than the atomic ratio of zinc contained in the region 001 or the region 002.

The sizes of the region 001 and the region 002 can be measured with energy dispersive X-ray spectroscopy (EDX) mapping images obtained by EDX. For example, the diameter of the region 001 is greater than or equal to 0.5 nm and less than or equal to 10 nm, or greater than or equal to 1 nm and less than or equal to 2 nm in the EDX mapping image of a cross-sectional photograph in some cases. The density of an element in a main component is gradually lowered from the central portion of the region toward the surrounding portion. For example, when the number (abundance) of atoms of an element countable in an EDX mapping image gradually changes from the central portion toward the surrounding portion, the surrounding portion of the region is unclear (blurred) in the EDX mapping image of the cross-sectional photograph.

In the CAC-OS, crystal structures of the region 001 and the region 002 are not particularly limited. The region 001 and the region 002 may have different crystal structures.

For example, the CAC-OS is preferably an oxide semiconductor having a non-single-crystal structure. Examples of an oxide semiconductor having a non-single-crystal structure include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the maximum diameter of the crystal region may be approximately several tens of nanometers.

When the CAAC-OS film is subjected to structural analysis by out-of-plane XRD measurement with an XRD apparatus using θ/2θ scanning, for example, a peak indicating c-axis alignment is detected at or around 2θ=31°. Note that the position of the peak indicating c-axis alignment (the value of 2θ) may change depending on the kind, composition, or the like of the metal element contained in the CAAC-OS. For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. There is no regularity of crystal orientation between different nanocrystals in the nc-OS. Hence, the orientation in the whole film is not observed. Accordingly, in some cases, the nc-OS cannot be distinguished from an a-like OS or an amorphous oxide semiconductor, depending on an analysis method.

For example, when an nc-OS film is subjected to structural analysis by out-of-plane XRD measurement with an XRD apparatus using θ/2θ scanning, a peak indicating crystallinity is not observed. Furthermore, a diffraction pattern like a halo pattern is shown in a selected-area electron diffraction pattern of the nc-OS film obtained using an electron beam having a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter substantially equal to or smaller than the diameter of a nanocrystal (e.g., 1 nm or larger and 30 nm or smaller).

The a-like OS is an oxide semiconductor having a structure between those of the nc-OS and the amorphous oxide semiconductor. The a-like OS has a void or a low-density region. That is, the a-like OS has an unstable structure, compared to the nc-OS and the CAAC-OS.

The crystallinity of the CAC-OS can be evaluated by electron diffraction. For example, in analysis of the CAC-OS by electron diffraction, a ring-like region with high luminance and a plurality of spots in the ring-like region are observed in some cases in an electron diffraction pattern image.

In analysis of the crystallinity of the CAC-OS, in some cases, different patterns are observed in accordance with the diameter of an electron beam, i.e., the area of a region observed. For example, NBED with an electron beam having a diameter of 1 nm (D to 100 nm (D inclusive is suitably employed in analysis of the crystallinity of the CAC-OS.

The conductivity of the region containing the oxide containing the element Mb as a main component (the region 002 in FIG. 11) is higher than that of the region containing the oxide containing the element Ma as a main component (the region 001 in FIG. 11). That is, when carriers flow through the region containing the oxide containing the element Mb as a main component, the conductivity of a metal oxide is exhibited. Accordingly, when the regions containing the oxide containing the element Mb as a main component are distributed in a metal oxide in a cloud-like manner, high field-effect mobility (μ) can be achieved. The region containing the oxide containing the element Mb or the like as a main component can be regarded as a semiconductor region whose properties are close to those of a conductor.

By contrast, the conductivity of the region containing the oxide containing the element Ma as a main component is lower than that of the region containing the oxide containing the element Mb as a main component. That is, when the regions containing the oxide containing the element Ma as a main component are distributed in a metal oxide, the off-state current can be reduced and excellent switching operation can be achieved. The region containing the oxide containing the element Ma as a main component can be regarded as a semiconductor region whose properties are close to those of an insulator.

Accordingly, when the Ma-Mb oxide including a CAC-OS is used for a semiconductor element, the property derived from the oxide containing the element Ma and the property derived from the oxide containing the element Mb complement each other, whereby a high on-state current, high field-effect mobility, and a low off-state current can be achieved.

As described above, the region 001, the region 002, and the region between the region 001 and the region 002 each contain zinc, whereby the region 001 and the region 002 can be electrically connected to each other using zinc as a conductive path. In this manner, carriers (electrons) flow through the metal oxide using zinc as a conductive path.

When the amount of the conductive material is larger than that of the insulating material in a metal oxide deposited using the sputtering target 10, the carrier mobility of the metal oxide can be increased. In order to deposit such a metal oxide, the proportion of the conductive material to the insulating material is preferably high in the sputtering target 10.

With the use of an element whose valence is greater than those of In, Ga, and Zn in the metal oxide, this element serves as a carrier supply source and can increase the carrier concentration of a region containing the element in the metal oxide deposited using the sputtering target 10. Examples of the element include Ti, Ge, Sn, V, Ni, Mo, W, and Ta. In particular, Sn is more strongly bonded to oxygen than In, Ga, and Zn. For this reason, when Sn is contained in the metal oxide, generation of oxygen vacancies can be inhibited. Thus, when the metal oxide deposited using the sputtering target 10 is used in a semiconductor layer of a transistor, the field-effect mobility of the transistor is improved and oxygen vacancies are reduced, whereby a semiconductor device with high reliability can be obtained.

The structures described in this embodiment can be used in appropriate combination with the structures described in any of the other embodiments.

### Embodiment 2

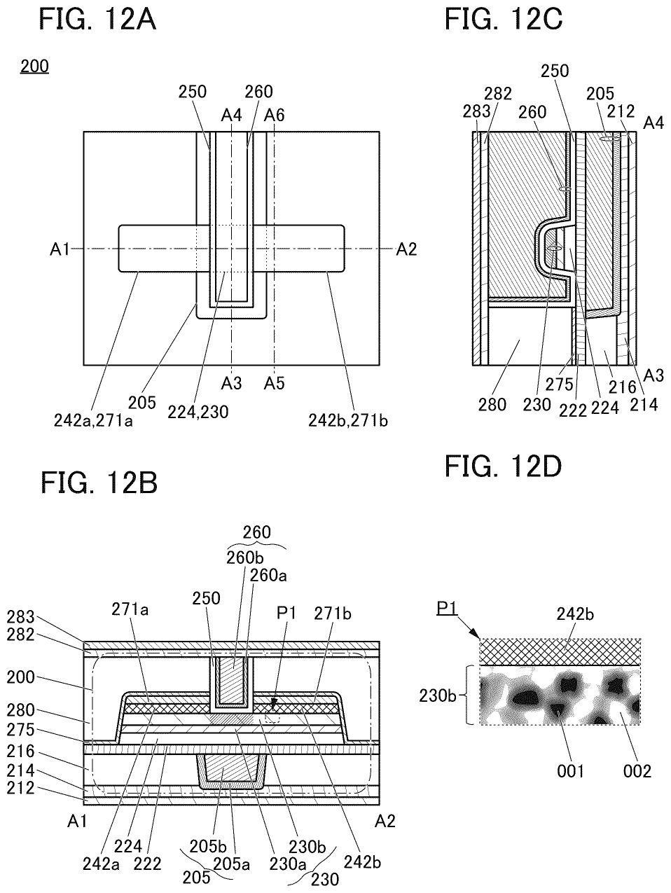

In this embodiment, a structure example of a semiconductor device of one embodiment of the present invention will be described with reference to FIGS. 12A to 12D, FIGS. 13A and 13B, FIGS. 14A and 14B, FIGS. 15A and 15B, FIGS. 16A to 16C, FIGS. 17A and 17B, FIG. 18, FIG. 19, FIGS. 20A and 20B, and FIGS. 21A and 21B.

The semiconductor device of one embodiment of the present invention includes a transistor.

### <Structure Example of Semiconductor Device>

A structure of a semiconductor device including a transistor 200 is described with reference to FIGS. 12A to 12D. FIGS. 12A to 12C are a top view and cross-sectional views of the semiconductor device. FIG. 12B is a cross-sectional view taken along the dashed-dotted line A1-A2 in FIG. 12A, which corresponds to a cross-sectional view of the transistor 200 in the channel length direction. FIG. 12C is a cross-sectional view taken along the dashed-dotted line A3-A4 in FIG. 12A, which corresponds to a cross-sectional view of the transistor 200 in the channel width direction. FIG. 12D is an enlarged cross-sectional conceptual view of a region P1 illustrated in FIG. 12B. Note that for simplification, some components are not illustrated in the top view of FIG. 12A.

The semiconductor device of one embodiment of the present invention includes an insulator 212 over a substrate (not illustrated), an insulator 214 over the insulator 212, the transistor 200 over the insulator 214, an insulator 280 over the transistor 200, an insulator 282 over the insulator 280, and an insulator 283 over the insulator 282. The insulators 212, 214, 280, 282, and 283 each function as an interlayer film.

As illustrated in FIGS. 12A to 12C, the transistor 200 includes an insulator 216 over the insulator 214, a conductor 205 (a conductor 205a and a conductor 205b) provided to be embedded in the insulator 216, an insulator 222 over the insulator 216 and the conductor 205, an insulator 224 over the insulator 222, an oxide 230 (an oxide 230a and an oxide 230b) over the insulator 224, a conductor 242a and a conductor 242b over the oxide 230, an insulator 271a over the conductor 242a, an insulator 271b over the conductor 242b, an insulator 250 over the oxide 230, and a conductor 260 (a conductor 260a and a conductor 260b) over the insulator 250. An insulator 275 is provided over the insulators 271a and 271b, and the insulator 280 is provided over the insulator 275.

Hereinafter, the conductors 242a and 242b are collectively referred to as a conductor 242 in some cases. The insulators 271a and 271b are collectively referred to as an insulator 271 in some cases.

An opening reaching the oxide 230 is formed in the insulators 280 and 275. The insulator 250 and the conductor 260 are provided in the opening. The conductor 260 and the insulator 250 are provided between the conductors 242a and 242b and between the insulators 271a and 271b in the channel length direction of the transistor 200.

The conductor 260 includes a region functioning as a first gate (also referred to as a top gate) electrode, and the conductor 205 includes a region functioning as a second gate (also referred to as a back gate) electrode. The insulator 250 includes a region functioning as a first gate insulator, and the insulators 222 and 224 include a region functioning as a second gate insulator. Note that the gate insulator is also referred to as a gate insulating layer or a gate insulating film in some cases. The conductor 242a includes a region functioning as one of a source electrode and a drain electrode, and the conductor 242b includes a region functioning as the other of the source electrode and the drain electrode. A region of the oxide 230 that overlaps with the conductor 260 at least partly functions as a channel formation region.

The oxide 230 preferably includes the oxide 230a provided over the insulator 224 and the oxide 230b provided over the oxide 230a. The oxide 230a under the oxide 230b can inhibit diffusion of impurities into the oxide 230b from the components formed below the oxide 230a.

Although the oxide 230 has a structure in which two layers, the oxides 230a and 230b, are stacked in FIGS. 12B and 12C, the present invention is not limited thereto. For example, the oxide 230 may have a single-layer structure or a stacked-layer structure of three or more layers.

In the transistor 200, the oxide 230 (the oxides 230a and 230b), which includes the channel formation region, is preferably formed using the metal oxide described in the above embodiment (hereinafter, also referred to as an oxide semiconductor). In the transistor 200, the oxide 230 is preferably formed using a metal oxide deposited using the sputtering target described in the above embodiment.

FIG. 12D is an enlarged cross-sectional conceptual view of the region P1 in the case where the metal oxide described in the above embodiment is used as the oxide 230b. As in the region P1 illustrated in FIG. 12D, the top surface of the oxide 230b is in contact with the conductor 242b; thus, contact resistance can be reduced. In addition, the oxide 230b has the CAC composition in FIG. 11 and the region 002 included in the CAC composition, i.e., a region with high conductivity, is in contact with the conductor 242b; thus, contact resistance can be further reduced. Although not illustrated, a connection between the oxide 230 and the conductor 242a is similar to that in the region P1.

The metal oxide of one embodiment of the present invention includes a highly conductive region and the contact resistance between the metal oxide and the conductor is reduced. Thus, the field-effect mobility of the transistor including the metal oxide can be increased.

The oxide 230 preferably has a stacked-layer structure of oxide layers with different chemical compositions. For example, the atomic ratio of the element M to a metal element that is the main component in the metal oxide used as the oxide 230a is preferably higher than that in the metal oxide used as the oxide 230b. The atomic ratio of the element M to In in the metal oxide used as the oxide 230a is preferably higher than that in the metal oxide used as the oxide 230b. With such a structure, impurities and oxygen can be inhibited from diffusing into the oxide 230b from the components formed below the oxide 230a.

The atomic ratio of In to the element M in the metal oxide used as the oxide 230b is preferably higher than that in the metal oxide used as the oxide 230a. With such a structure, the transistor 200 can have a high on-state current and excellent frequency characteristics.

When the oxides 230a and 230b contain a common element as a main component besides oxygen, the density of defect states at the interface between the oxides 230a and 230b can be made low. This reduces the influence of interface scattering on carrier conduction, and the transistor 200 can have a high on-state current and excellent frequency characteristics.

Specifically, as the oxide 230a, a metal oxide having an atomic ratio of In:M:Zn=1:3:4 or in the neighborhood thereof, or In:M:Zn=1:1:0.5 or in the neighborhood thereof is used. As the oxide 230b, the metal oxide described in the above embodiment is used. Gallium is preferably used as the element M. In the case where the oxide 230 has a single-layer structure, the metal oxide that can be used as the oxide 230a or the oxide 230b is preferably used as the oxide 230.

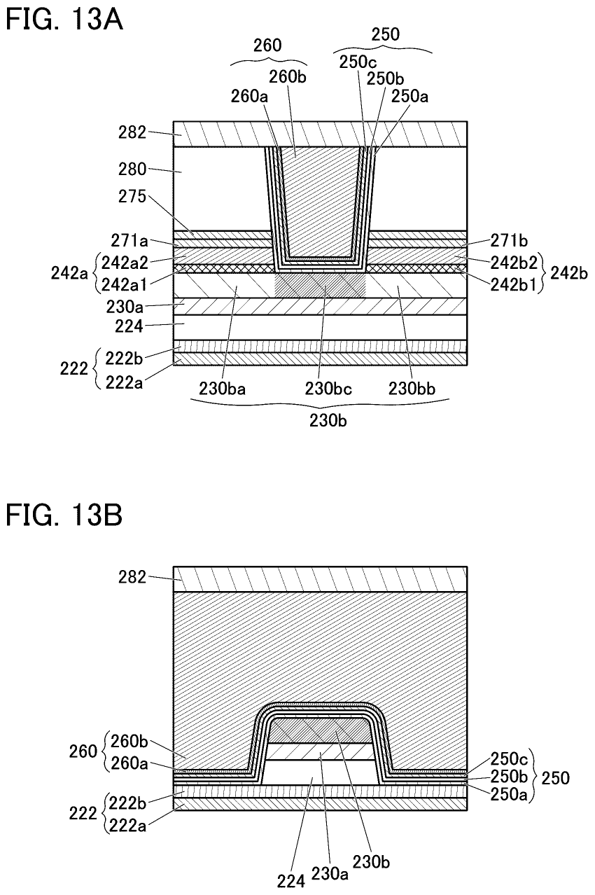

FIG. 13A is an enlarged view of the vicinity of the channel formation region in FIG. 12B, and FIG. 13B is an enlarged view of the vicinity of the channel formation region in FIG. 12C. As illustrated in FIG. 13A, the oxide 230b includes a region 230bc functioning as a channel formation region and a region 230ba and a region 230bb that are provided to sandwich the region 230bc and function as a source region and a drain region. At least part of the region 230bc overlaps with the conductor 260. In other words, the region 230bc is provided between the conductors 242a and 242b. The region 230ba is provided to overlap with the conductor 242a, and the region 230bb is provided to overlap with the conductor 242b.

A transistor including an oxide semiconductor in a channel formation region (hereinafter, sometimes referred to as an OS transistor) is likely to have its electrical characteristics changed by impurities and oxygen vacancies (Vo) in the channel formation region and thus the reliability is reduced in some cases. In an oxide semiconductor, a defect that is an oxygen vacancy into which hydrogen enters (hereinafter, sometimes referred to as VoH) generates an electron serving as a carrier in some cases. Formation of VoH in the channel formation region may increase the donor concentration in the channel formation region. An increase in the donor concentration in the channel formation region may lead to a variation in threshold voltage. Thus, when the channel formation region in the oxide semiconductor includes oxygen vacancies, the transistor tends to have normally-on characteristics. Therefore, the impurities, oxygen vacancies, and VoH are preferably reduced as much as possible in the channel formation region in the oxide semiconductor. In other words, the oxide semiconductor preferably includes an i-type (intrinsic) or substantially i-type channel formation region with a low carrier concentration.

By contrast, when an insulator containing oxygen that is released by heating (hereinafter, sometimes referred to as excess oxygen) is provided in the vicinity of the oxide semiconductor and heat treatment is performed, oxygen can be supplied from the insulator to the oxide semiconductor so as to reduce oxygen vacancies and VoH. Note that too much oxygen supplied to the source region or the drain region might cause a decrease in the on-state current or the field-effect mobility of the transistor 200. Furthermore, a variation in the amount of oxygen supplied to the source region or the drain region on the substrate plane leads to variable characteristics of the semiconductor device including the transistor.

Hence, the region 230bc functioning as the channel formation region in the oxide semiconductor is preferably an i-type or substantially i-type region with a low carrier concentration, whereas the regions 230ba and 230bb functioning as the source and drain regions are preferably n-type regions with a high carrier concentration. That is, it is preferable that in the oxide semiconductor, oxygen vacancies and VoH in the region 230bc be reduced and supply of too much oxygen to the regions 230ba and 230bb be prevented.

In other words, in the oxide semiconductor, the regions 230ba and 230bb are preferably n-type regions with a high carrier concentration, whereas the region 230bc is preferably an i-type or substantially i-type region with a low carrier concentration. That is, it is preferable that the n-type regions not extend to the channel formation region.

For example, the amount of oxygen vacancies in the region 230bc is set smaller or the concentration of an impurity such as hydrogen, nitrogen, or a metal element in the region 230bc is set lower than those in the regions 230ba and 230bb, so that the region 230bc can be a high-resistance region with a low carrier concentration. At this time, the region 230bc can be regarded as being i-type (intrinsic) or substantially i-type.

For another example, a reduction in the amount of oxygen vacancies or the impurity concentration in the regions 230ba and 230bb is inhibited, so that the regions 230ba and 230bb can each be a low-resistance region with a high carrier concentration. At this time, the regions 230ba and 230bb are each an n-type region having a higher carrier concentration and a lower resistance than the region 230bc.

The carrier concentration in the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration in the region 230bc is not particularly limited and can be, for example, 1×10⁻⁹ cm⁻³.

A region having a carrier concentration lower than or equal to that of the region 230ba and higher than or equal to that of the region 230bc may be formed between the regions 230bc and 230ba. That is, the region functions as a junction region between the regions 230bc and 230ba. The hydrogen concentration in the junction region is sometimes lower than or equal to that in the region 230ba and higher than or equal to that in the region 230bc. The amount of oxygen vacancies in the junction region is sometimes smaller than or equal to that in the region 230ba and larger than or equal to that in the region 230bc. The same applies to a region between the regions 230bc and 230bb.

Note that FIG. 13A illustrates an example in which the regions 230ba, 230bb, and 230bc are formed in the oxide 230b; however, the present invention is not limited thereto. For example, the above regions may be formed not only in the oxide 230b but also in the oxide 230a.

In the oxide 230, it is sometimes difficult to clearly observe the boundaries between the regions. The concentration of a metal element and an impurity such as hydrogen or nitrogen, which is detected in each region, may be gradually changed not only between the regions but also in each region. That is, the region closer to the channel formation region preferably has a lower concentration of an impurity such as hydrogen or nitrogen.

The oxide 230b is preferably formed using a crystalline oxide semiconductor. Examples of the crystalline oxide semiconductor include a CAAC-OS, an nc-OS, a polycrystalline oxide semiconductor, and a single crystal oxide semiconductor.

In the CAAC-OS, a reduction in electron mobility due to a crystal grain boundary is unlikely to occur because it is difficult to observe a clear crystal grain boundary. Thus, a metal oxide including the CAAC-OS is physically stable. Accordingly, the metal oxide including the CAAC-OS is resistant to heat and has high reliability.

There is no regularity of crystal orientation between different nanocrystals in the nc-OS; thus, the orientation of the whole film is not observed. That is, in the case where the nc-OS is used as the oxide 230b, the oxide 230b has uniform film characteristics regardless of the direction of carriers flowing in the oxide 230b; thus, the transistor has stable electrical characteristics.

An oxide semiconductor has any of various structures that show different properties. The oxide 230b may contain two or more of a CAAC-OS, an nc-OS, an a-like OS, an amorphous oxide semiconductor, a polycrystalline oxide semiconductor, and a CAC-OS.

As illustrated in FIG. 12C, the oxide 230 may have a curved surface between the side and top surfaces in a cross-sectional view in the channel width direction of the transistor 200. Such a shape can improve the coverage of the oxide 230 with the insulator 250 and the conductor 260.

At least one of the insulators 212, 214, 271, 275, 282, and 283 preferably functions as a barrier insulating film that inhibits diffusion of impurities from the substrate side or from above the transistor 200 into the transistor 200. Thus, at least one of the insulators 212, 214, 271, 275, 282, and 283 is preferably formed using an insulating material having a function of inhibiting diffusion of impurities. Alternatively, an insulating material having a function of inhibiting diffusion of oxygen is preferably used.

In this specification and the like, a barrier insulating film refers to an insulating film having a barrier property. A barrier property refers to a property of hardly diffusing a particular substance (also referred to as a property of hardly transmitting a particular substance, a low permeability of a particular substance, or a function of inhibiting diffusion of a particular substance). Alternatively, a barrier property refers to a function of capturing or fixing (also referred to as gettering) a particular substance. Hydrogen in the expression of “diffusion of hydrogen” or “entry of hydrogen” refers to, for example, at least one of a hydrogen atom, a hydrogen molecule, substances bonded to hydrogen, such as a water molecule and OH⁻, and the like. An impurity in the expression of “diffusion of an impurity” or “entry of an impurity” refers to, for example, at least one of a hydrogen atom, a hydrogen molecule, a water molecule, a nitrogen atom, a nitrogen molecule, a nitrogen oxide molecule (e.g., N₂O, NO, and NO₂), a copper atom, and the like. Oxygen in the expression of “diffusion of oxygen” refers to, for example, at least one of an oxygen atom, an oxygen molecule, and the like.

An insulator having a function of inhibiting diffusion of oxygen and impurities is preferably used as the insulators 212, 214, 271, 275, 282, and 283, and examples of the insulator include aluminum oxide, magnesium oxide, hafnium oxide, gallium oxide, indium gallium zinc oxide, silicon nitride, and silicon nitride oxide. For example, silicon nitride, which has a high hydrogen barrier property, is preferably used for the insulators 212, 275, and 283. For example, an insulator having a function of capturing or fixing hydrogen is preferably used as the insulators 214, 271, and 282. Accordingly, impurities can be inhibited from diffusing into the transistor 200 from the substrate side through the insulators 212 and 214. Furthermore, impurities can be inhibited from diffusing to the transistor 200 side from an interlayer insulating film and the like positioned outward from the insulator 283. In addition, oxygen contained in the insulator 224 and the like can be inhibited from diffusing to the substrate side through the insulators 212 and 214. Oxygen contained in the insulator 280 and the like can be inhibited from diffusing to above the transistor 200 through the insulator 282 and the like. In this manner, the transistor 200 is preferably surrounded by the insulators 212, 214, 271, 275, 282, and 283, which have a function of inhibiting diffusion of oxygen and impurities.

Examples of an insulator having a function of capturing or fixing hydrogen include a metal oxide having an amorphous structure. As the insulators 214, 271, and 282, a metal oxide such as magnesium oxide or an oxide containing one or both of aluminum and hafnium is preferably used, for example. In such a metal oxide having an amorphous structure, an oxygen atom has a dangling bond, and the metal oxide has a property of capturing or fixing hydrogen with the dangling bond in some cases. That is, the metal oxide having an amorphous structure is highly capable of capturing or fixing hydrogen. When such a metal oxide having an amorphous structure is used as the component of the transistor 200 or provided in the vicinity of the transistor 200, hydrogen contained in the transistor 200 or hydrogen in the vicinity of the transistor 200 can be captured or fixed. In particular, hydrogen contained in the channel formation region of the transistor 200 is preferably captured or fixed. With such a structure, the transistor 200 and the semiconductor device with excellent characteristics and high reliability can be fabricated.

Each of the insulators 214, 271, and 282 preferably has an amorphous structure but may partly have a crystal region. The insulators 214, 271, and 282 may each have a multilayer structure in which a layer having an amorphous structure and a layer having a crystal region are stacked. For example, a stacked-layer structure in which a layer having a crystal region, typically, a layer having a polycrystalline structure, is formed over a layer having an amorphous structure may be employed.

The insulators 212, 214, 271, 275, 282, and 283 can be formed by a sputtering method, for example. A deposition gas in a sputtering method need not include molecules containing hydrogen; thus, the hydrogen concentrations in the insulators 212, 214, 271, 275, 282, and 283 can be reduced. Note that the deposition method is not limited to a sputtering method, and a chemical vapor deposition (CVD) method, a molecular beam epitaxy (MBE) method, a pulsed laser deposition (PLD) method, an atomic layer deposition (ALD) method, or the like may be used as appropriate.

The insulators 216 and 280 are preferably formed using a material with a lower dielectric constant than the material for the insulator 214. In the case where a material with a low dielectric constant is used for an interlayer film, the parasitic capacitance between wirings can be reduced. For example, silicon oxide, silicon oxynitride, or silicon nitride oxide can be used for the insulators 216 and 280. For another example, silicon oxide to which fluorine is added, silicon oxide to which carbon is added, or silicon oxide to which carbon and nitrogen are added can be used. For another example, porous silicon oxide or the like can be used. These silicon oxides may contain nitrogen. Silicon oxide and silicon oxynitride are particularly preferable because of their thermal stability. Materials such as silicon oxide, silicon oxynitride, and porous silicon oxide are particularly preferable because a region containing excess oxygen can be easily formed in these materials.

The concentration of an impurity such as water or hydrogen in the insulator 280 is preferably reduced. For example, an oxide containing silicon, such as silicon oxide or silicon oxynitride, can be used for the insulator 280 as appropriate. The top surface of the insulator 280 may be planarized.

For the conductors 242a and 242b, a nitride containing tantalum, a nitride containing titanium, a nitride containing molybdenum, a nitride containing tungsten, a nitride containing tantalum and aluminum, or a nitride containing titanium and aluminum is preferably used, for example. In one embodiment of the present invention, a nitride containing tantalum is particularly preferable. For another example, ruthenium, ruthenium oxide, ruthenium nitride, an oxide containing strontium and ruthenium, or an oxide containing lanthanum and nickel may be used. These materials are preferable because they are conductive materials that are not easily oxidized or materials that maintain their conductivity even after absorbing oxygen.

Note that hydrogen contained in the oxide 230b or the like diffuses into the conductor 242a or the conductor 242b in some cases. In particular, when a nitride containing tantalum is used for the conductors 242a and 242b, hydrogen contained in the oxide 230b or the like is likely to diffuse into the conductor 242a or the conductor 242b, and the diffused hydrogen is bonded to nitrogen contained in the conductor 242a or the conductor 242b in some cases. That is, hydrogen contained in the oxide 230b or the like is sometimes absorbed by the conductor 242a or the conductor 242b.

In the case where heat treatment is performed with the conductor 242a and the oxide 230b being in contact with each other, the sheet resistance of the oxide 230b in a region overlapping with the conductor 242a is lowered and the carrier concentration thereof increases in some cases. Thus, the resistance of the oxide 230b in the region overlapping with the conductor 242a can be lowered in a self-aligned manner. The same applies to the oxide 230b in a region overlapping with the conductor 242b.

The conductor 242 is preferably formed using a conductive film having compressive stress. This can form distortion extended in the tensile direction (hereinafter, such distortion is sometimes referred to as tensile distortion) in the regions 230ba and 230bb. When VoH is stably formed by the tensile distortion, the regions 230ba and 230bb can be stable n-type regions. The compressive stress of the conductor 242 refers to stress for relaxing the compressive shape of the conductor 242 that has a vector in a direction from a center portion to an end portion of the conductor 242.

The level of the compressive stress of the conductor 242 is, for example, preferably higher than or equal to 500 MPa, further preferably higher than or equal to 1000 MPa, still further preferably higher than or equal to 1500 MPa, yet still further preferably higher than or equal to 2000 MPa. The level of the stress of the conductor 242 may be determined from the measured stress of a sample formed by depositing a conductive film to be used for the conductor 242 on a substrate.

Although the distortion formed in the oxide 230b is described above, the present invention is not limited thereto. In some cases, the distortion is formed similarly in the oxide 230a.

The conductors 242a and 242b may each have a single-layer structure or a stacked-layer structure. For example, as illustrated in FIG. 13A, the conductors 242a and 242b may each have a two-layer structure. In that case, the conductor 242a is a stack of a conductor 242al and a conductor 242a2 over the conductor 242al, and the conductor 242b is a stack of a conductor 242b1 and a conductor 242b2 over the conductor 242b1. At this time, the above-described conductive material that is unlikely to be oxidized or a conductive material having a function of inhibiting diffusion of oxygen is preferably used for layers (the conductors 242al and 242b1) in contact with the oxide 230b. This can inhibit excessive oxidation of the conductors 242a and 242b by oxygen contained in the oxide 230b. In addition, a reduction in the conductivity of the conductors 242a and 242b can be inhibited.

The conductors 242a2 and 242b2 preferably have higher conductivity than the conductors 242al and 242b1. For example, the thicknesses of the conductors 242a2 and 242b2 are preferably larger than those of the conductors 242a1 and 242b1. Any of the conductors that can be used as the conductor 205b is used as each of the conductors 242a2 and 242b2. Such a structure can lower the resistances of the conductors 242a2 and 242b2. Thus, the conductors 242a and 242b can function as wirings or electrodes with high conductivity. Moreover, the operation speed of the transistor 200 can be increased.

For example, it is possible to use tantalum nitride or titanium nitride for the conductors 242a1 and 242b1 and tungsten for the conductors 242a2 and 242b2.

As illustrated in FIGS. 13A and 13B, the insulator 250 preferably has a stacked-layer structure of an insulator 250a in contact with the oxide 230, an insulator 250b over the insulator 250a, and an insulator 250c over the insulator 250b.

As the insulator 250b, an insulator that easily transmits oxygen is preferably used. With such a structure, oxygen contained in the insulator 280 can be supplied to the region 230bc through the insulator 250b. Any of the insulators that can be used as the insulator 280 is preferably used as the insulator 250b. Silicon oxide and silicon oxynitride are particularly preferable because of their thermal stability. In that case, the insulator 250b contains at least oxygen and silicon. The concentration of an impurity such as water or hydrogen in the insulator 250b is preferably reduced.

The insulator 250a preferably has a barrier property against oxygen. The insulator 250a includes a region in contact with the side surface of the conductor 242a and a region in contact with the side surface of the conductor 242b. The insulator 250a having a barrier property against oxygen can inhibit oxidation of the side surfaces of the conductors 242a and 242b and resultant formation of an oxide film on the side surfaces. It is thus possible to inhibit a reduction in the on-state current or field-effect mobility of the transistor 200. Examples of the insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

The insulator 250a is provided in contact with the top and side surfaces of the oxide 230b and the side surface of the oxide 230a. That is, in the cross-sectional view in the channel width direction, the region 230bc is surrounded by the insulator 250a and the oxide 230a. The insulator 250a and the oxide 230a each of which has a barrier property against oxygen can inhibit release of oxygen from the region 230bc at the time of heat treatment or the like. This can inhibit formation of oxygen vacancies in the region 230bc. Accordingly, the electrical characteristics and reliability of the transistor 200 can be improved.

Even when an excessive amount of oxygen is contained in the insulator 280, providing the insulator 250a can inhibit excessive supply of the oxygen to the region 230bc, which enables a suitable amount of oxygen to be supplied to the region 230bc. This can inhibit excessive oxidation of the regions 230ba and 230bb, thereby inhibiting a reduction in the on-state current or field-effect mobility of the transistor 200.

An insulator containing an oxide containing one or both of aluminum and hafnium is preferably used as the insulator 250a. In this embodiment, aluminum oxide is used for the insulator 250a. In that case, the insulator 250a contains at least oxygen and aluminum.

The insulator 250c preferably has a barrier property against hydrogen. Thus, diffusion of impurities contained in the conductor 260 to the region 230bc can be inhibited. For the insulator 250c, for example, it is preferable to use aluminum oxide, magnesium oxide, hafnium oxide, gallium oxide, indium gallium zinc oxide, silicon nitride, or silicon nitride oxide. It is particularly suitable to use silicon nitride because of its high barrier property against hydrogen. In that case, the insulator 250c contains at least nitrogen and silicon.

The insulator 250c may also have a barrier property against oxygen. The insulator 250c is provided between the insulator 250b and the conductor 260. This can prevent diffusion of oxygen contained in the insulator 250b to the conductor 260, which can inhibit oxidation of the conductor 260 and a reduction in the amount of oxygen supplied to the region 230bc.

Silicon nitride has a barrier property against oxygen and thus can be suitably used for the insulator 250c.

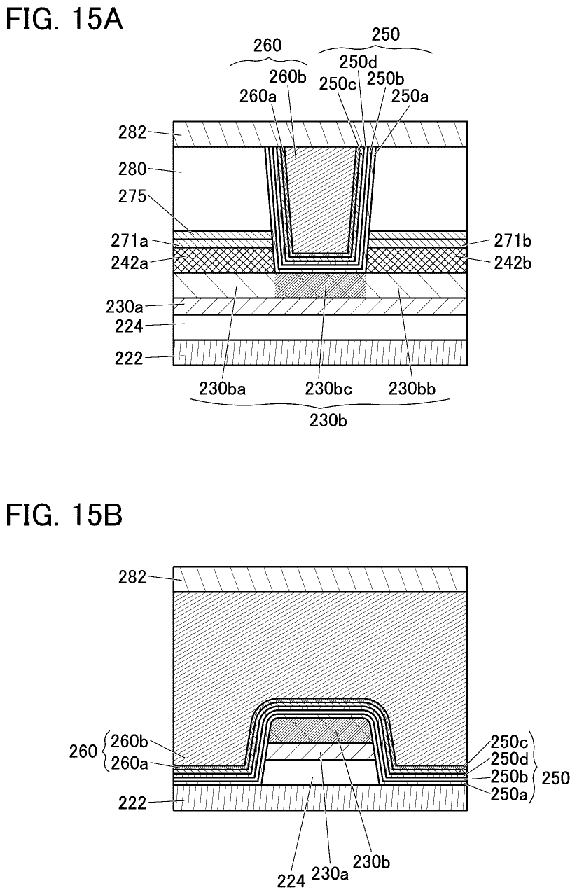

As illustrated in FIGS. 15A and 15B, an insulator 250d may be provided between the insulators 250b and 250c. The insulator 250d preferably has a function of capturing or fixing hydrogen. When an insulator having a function of capturing or fixing hydrogen is provided inside a region surrounded by the insulators 250c and 222, hydrogen inside the region can be captured or fixed more effectively. That is, hydrogen contained in the insulator 250b, the region 230bc of the oxide 230b, and the insulator 224 can be captured or fixed more effectively. Thus, the hydrogen concentration in the region 230bc can be reduced. Accordingly, VoH in the region 230bc can be reduced, so that the region 230bc can be an i-type or substantially i-type region.

For the insulator 250d, an oxide containing one or both of aluminum and hafnium is preferably used, and an oxide having an amorphous structure and containing one or both of aluminum and hafnium is further preferably used, for example. In this embodiment, hafnium oxide is used for the insulator 250d. In that case, the insulator 250d contains at least oxygen and hafnium. The insulator 250d may have an amorphous structure.

Any of insulators that can be used as the insulator 222 described later may be used as the insulator 250d. For example, since the insulator 250 includes the region functioning as the first gate insulator, an insulator containing a high-dielectric-constant (high-k) material described later may be used.

The insulators 250a to 250d are provided together with the conductor 260 in the opening formed in the insulator 280 and the like. The thicknesses of the insulators 250a to 250d are preferably small for scaling down of the transistor 200. The thicknesses of the insulators 250a to 250d are each greater than or equal to 0.1 nm and less than or equal to 10 nm, preferably greater than or equal to 0.1 nm and less than or equal to 5.0 nm, further preferably greater than or equal to 0.5 nm and less than or equal to 5.0 nm, still further preferably greater than or equal to 1.0 nm and less than or equal to 5.0 nm, yet still further preferably greater than or equal to 1.0 nm and less than or equal to 3.0 nm. In such a case, each of the insulators 250a to 250d at least partly has a region with the above thickness.

To reduce the thicknesses of the insulators 250a to 250d as described above, an ALD method is preferably used for deposition. As the ALD method, a thermal ALD method, in which a precursor and a reactant react with each other only by a thermal energy, a plasma-enhanced ALD (PEALD) method, in which a reactant excited by plasma is used, and the like can be used. The use of plasma is sometimes preferable because deposition at a lower temperature is possible in a PEALD method.

An ALD method enables a single atomic layer to be formed at a time, and has various advantages such as deposition of an extremely thin film, deposition on a component with a high aspect ratio, deposition of a film with a small number of defects such as pinholes, deposition with excellent coverage, and low-temperature deposition. Thus, the insulator 250 can be formed on the side surface of the opening formed in the insulator 280 and the like to have a small thickness as described above and to have excellent coverage.

Although the insulator 250 having the three-layer structure of the insulators 250a to 250c or the four-layer structure of the insulators 250a to 250d is described above, the present invention is not limited thereto. The insulator 250 can include at least one of the insulators 250a to 250d. When the insulator 250 includes one, two, or three of the insulators 250a to 250d, the fabrication process of a semiconductor device can be simplified and the productivity can be improved.

Although the insulator 250a is in contact with the side surfaces of the conductors 242a2 and 242b2 in FIG. 13A, the present invention is not limited thereto. For example, an insulator 255 may be provided between the insulator 250a and each of the conductors 242a2 and 242b2.

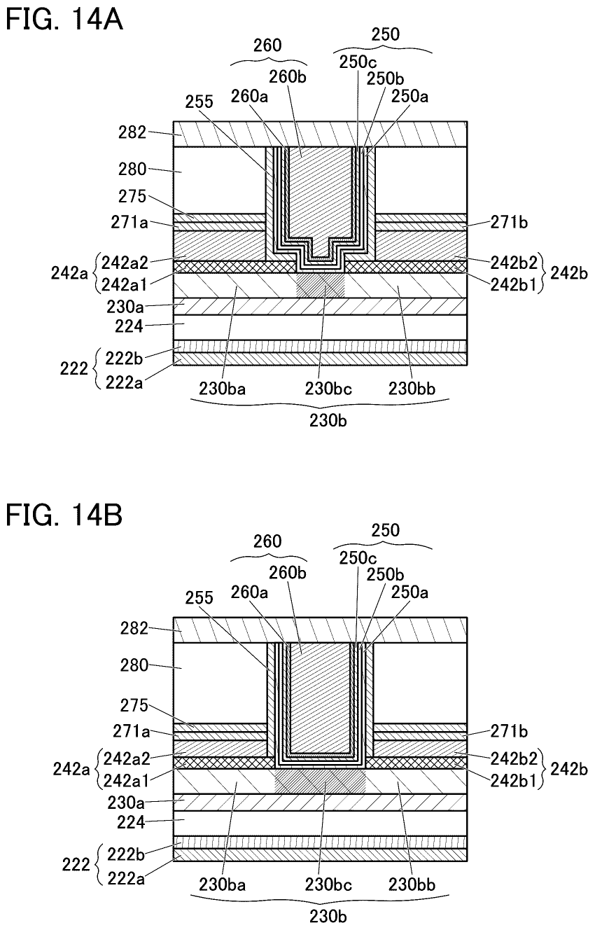

FIGS. 14A and 14B are enlarged cross-sectional views of the transistor 200 in the channel length direction. Semiconductor devices illustrated in FIGS. 14A and 14B are modification examples of the semiconductor device illustrated in FIG. 13A. Specifically, the semiconductor devices illustrated in FIGS. 14A and 14B are different from the semiconductor device illustrated in FIG. 13A in that the insulator 255 is provided between the insulator 250a and each of the conductors 242a2 and 242b2.

As illustrated in the cross-sectional view of the transistor 200 in the channel length direction in FIG. 14A, the distance between the conductors 242al and 242b1 is shorter than the distance between the conductors 242a2 and 242b2. With such a structure, the distance between the source and the drain can be shorter and accordingly the channel length can be shortened. Thus, the frequency characteristics of the transistor 200 can be improved. In this manner, scaling down of the semiconductor device enables the semiconductor device to have a higher operation speed.

The insulator 255 is preferably an insulator that is unlikely to be oxidized, such as a nitride, for example. The insulator 255 is formed in contact with the side surfaces of the conductors 242a2 and 242b2 and has a function of protecting the conductors 242a2 and 242b2. The insulator 255 is exposed to an oxidizing atmosphere and thus is preferably an inorganic insulator that is unlikely to be oxidized. Since the insulator 255 is in contact with the conductors 242a2 and 242b2, the insulator 255 is preferably an inorganic insulator that is unlikely to oxidize the conductors 242a2 and 242b2. Thus, the insulator 255 is preferably formed using an insulating material having a barrier property against oxygen. For example, silicon nitride can be used for the insulator 255.

The transistor 200 illustrated in FIG. 14A is formed in the following manner: an opening is formed in the insulators 280 and 275, the insulator 255 is formed in contact with a sidewall of the opening, and the conductors 242al and 242b1 are separated using a mask. Here, the opening overlaps with a region between the conductors 242a2 and 242b2. The conductors 242al and 242b1 are formed to partly extend in the opening. Thus, the insulator 255 is in contact with the top surfaces of the conductors 242al and 242b1 and the side surfaces of the conductors 242a2 and 242b2 in the opening. The insulator 250a is in contact with the top surface of the oxide 230 in a region between the conductors 242a1 and 242b1.

Although the insulator 250 includes the regions overlapping with the conductors 242a1 and 242b1 with the insulator 255 therebetween in FIG. 14A, the present invention is not limited thereto. For example, as illustrated in FIG. 14B, the side surface of the insulator 255 may be aligned with the side surfaces of the conductors 242al and 242b1 in the opening formed in the insulators 280 and 275. Such a structure can eliminate the above-described step of separating the conductors 242a1 and 242b1 using a mask, thereby simplifying the fabrication process of the semiconductor device and improving the productivity.

The conductor 260 preferably includes the conductor 260a and the conductor 260b over the conductor 260a. For example, the conductor 260a is preferably positioned to cover the bottom and side surfaces of the conductor 260b. Moreover, as illustrated in FIGS. 12B and 12C, the top surface of the conductor 260 is aligned with the top surface of the insulator 250. Although the conductor 260 has a two-layer structure of the conductors 260a and 260b in FIGS. 12B and 12C, the conductor 260 may have a single-layer structure or a stacked-layer structure of three or more layers.

The conductor 260a is preferably formed using a conductive material having a function of inhibiting diffusion of impurities. Alternatively, the conductor 260a is preferably formed using a conductive material having a function of inhibiting diffusion of oxygen. When the conductor 260a has a function of inhibiting diffusion of oxygen, the conductivity of the conductor 260b can be inhibited from being lowered because of oxidation due to oxygen contained in the insulator 250. As the conductive material having a function of inhibiting diffusion of oxygen, for example, titanium, titanium nitride, tantalum, tantalum nitride, ruthenium, or ruthenium oxide is preferably used. Thus, the conductor 260a may be a single layer or a stacked layer of the above conductive materials. For example, titanium nitride may be used for the conductor 260a.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure, for example, a stacked-layer structure of titanium or titanium nitride and the above conductive material.

In the transistor 200, the conductor 260 is formed in a self-aligned manner to fill the opening formed in the insulator 280 and the like. In this manner, the conductor 260 can surely be provided in a region between the conductors 242a and 242b without alignment.

In the channel width direction of the transistor 200 as illustrated in FIG. 12C, with the level of the insulator 222 as a reference, the level of a region of the bottom surface of the conductor 260 that does not overlap with the oxide 230b is preferably lower than the level of the bottom surface of the oxide 230b. When the conductor 260 functioning as the gate electrode covers the side and top surfaces of the channel formation region of the oxide 230b, the electric field of the conductor 260 is likely to affect the entire channel formation region of the oxide 230b. Hence, the transistor 200 can have a higher on-state current and higher frequency characteristics.

The conductor 205 is provided to overlap with the oxide 230 and the conductor 260. Here, the conductor 205 is preferably provided to fill an opening formed in the insulator 216. Part of the conductor 205 is embedded in the insulator 214 in some cases.

The conductor 205 includes the conductors 205a and 205b. The conductor 205a is provided in contact with the bottom surface and sidewall of the opening formed in the insulator 216. The conductor 205b is provided to fill a recessed portion formed in the conductor 205a. Here, the top surface of the conductor 205b is level with the top surfaces of the conductor 205a and the insulator 216.

Note that the conductor 205a is preferably formed using a conductive material having a function of inhibiting diffusion of impurities. Alternatively, the conductor 205a is preferably formed using a conductive material having a function of inhibiting diffusion of oxygen.

When the conductor 205a is formed using a conductive material having a function of inhibiting diffusion of impurities, impurities contained in the conductor 205b can be inhibited from diffusing into the oxide 230 through the insulator 216 and the like. When the conductor 205a is formed using a conductive material having a function of inhibiting diffusion of oxygen, the conductivity of the conductor 205b can be inhibited from being lowered because of oxidation.

As the conductor 205a, any of the conductors that can be used as the conductor 260a is used. A conductive material containing tungsten, copper, or aluminum as its main component is preferably used for the conductor 205b. For example, tungsten may be used for the conductor 205b.

Although the conductors 205a and 205b are stacked in FIGS. 12B and 12C, the present invention is not limited thereto. For example, the conductor 205 may have a single-layer structure or a stacked-layer structure of three or more layers.

The conductor 205 functions as a second gate electrode in some cases. In that case, by changing a potential applied to the conductor 205 independently of a potential applied to the conductor 260, the threshold voltage (Vth) of the transistor 200 can be controlled. In particular, by applying a negative potential to the conductor 205, Vth of the transistor 200 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

As illustrated in FIG. 12A, the size of the conductor 205 is preferably larger than the size of a region of the oxide 230 that does not overlap with the conductors 242a and 242b. As illustrated in FIG. 12C, it is particularly preferable that the conductor 205 extend beyond the end portions of the oxides 230a and 230b in the channel width direction. That is, the conductors 205 and 260 preferably overlap with each other with the insulator positioned therebetween, in a region beyond the side surface of the oxide 230 in the channel width direction. With this structure, the channel formation region in the oxide 230 can be electrically surrounded by the electric field of the conductor 260 functioning as a first gate electrode and the electric field of the conductor 205 functioning as a second gate electrode. In this specification, a transistor structure in which the channel formation region is electrically surrounded by at least the electric field of the first gate electrode is referred to as a surrounded channel (S-channel) structure.

In this specification and the like, the S-channel structure refers to a transistor structure in which a channel formation region is electrically surrounded by the electric fields of a pair of gate electrodes. The S-channel structure disclosed in this specification and the like is different from a Fin structure or a planar structure. The S-channel structure disclosed in this specification and the like can be regarded as a kind of the Fin structure. In this specification and the like, the Fin structure refers to a structure in which at least two surfaces (specifically, two surfaces, three surfaces, four surfaces, or the like) of a channel are covered with a gate electrode. With the use of the Fin structure or the S-channel structure, a transistor with high resistance to a short-channel effect, i.e., a transistor in which a short-channel effect is unlikely to occur, can be obtained.

When the transistor 200 has the above-described S-channel structure, the channel formation region can be electrically surrounded. Since the S-channel structure is a structure with the electrically surrounded channel formation region, the S-channel structure is, in a sense, equivalent to a gate all around (GAA) structure or a lateral gate all around (LGAA) structure. When the transistor 200 has any of the S-channel structure, the GAA structure, and the LGAA structure, the channel formation region formed at the interface between the oxide 230 and the gate insulator or in the vicinity thereof can correspond to the whole of bulk in the oxide 230. Consequently, the density of current flowing through the transistor can be improved, so that the on-state current or the field-effect mobility of the transistor can be increased.

As illustrated in FIG. 12C, the conductor 205 is extended to have a function of a wiring. However, without limitation to this structure, a structure in which a conductor functioning as a wiring is provided below the conductor 205 may be employed. In addition, the conductor 205 is not necessarily provided in each transistor. For example, the conductor 205 may be shared by a plurality of transistors.

The insulator 222 preferably has a function of inhibiting diffusion of hydrogen. Moreover, the insulator 222 preferably has a function of inhibiting diffusion of oxygen. For example, the insulator 222 preferably has a function of inhibiting diffusion of much hydrogen and/or oxygen compared to the insulator 224.

As the insulator 222, an insulator containing an oxide of one or both of aluminum and hafnium, which is an insulating material, is preferably used. Alternatively, an oxide containing hafnium and zirconium, e.g., a hafnium zirconium oxide, is preferably used. The insulator 222 formed of such a material functions as a layer that inhibits release of oxygen from the oxide 230 to the substrate side or diffusion of impurities from the periphery of the transistor 200 into the oxide 230. Thus, providing the insulator 222 can inhibit diffusion of impurities into the transistor 200 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. The insulator 222 may have a stacked-layer structure including silicon oxide, silicon oxynitride, or silicon nitride over any of these insulators.

The insulator 222 includes the region functioning as the second gate insulator and thus may be formed to have a single-layer structure or a stacked-layer structure including an insulator containing a high-k material described later. The insulator 222 can sometimes be formed using a high-dielectric-constant substance such as lead zirconate titanate (PZT), strontium titanate (SrTiO₃), or (Ba,Sr)TiO₃ (BST).

As illustrated in FIGS. 13A and 13B, the insulator 222 may have a stacked-layer structure of an insulator 222a over the insulator 216 and the conductor 205 and an insulator 222b over the insulator 222a.

Any of the insulators that can be used as the insulator 222 is used as the insulator 222b.

The insulator 222a is provided between the insulator 222b and each of the insulator 216 and the conductor 205. The insulator 222a preferably has a function of inhibiting diffusion of hydrogen. This can inhibit diffusion of hydrogen into the transistor 200 from below the insulator 222a.

For the insulator 222a, for example, silicon nitride deposited by an ALD method (especially, a PEALD method) is preferably used. The insulator 222a deposited by an ALD method can have excellent coverage even when unevenness is formed by the insulator 216 and the conductor 205. Thus, formation of a pinhole, step disconnection, or the like on the insulator 222b formed over the insulator 222a can be inhibited.

Silicon oxide, silicon oxynitride, or the like can be used as appropriate for the insulator 224 in contact with the oxide 230, for example.

Note that the insulator 222 and/or the insulator 224 may have a stacked-layer structure of two or more layers. In those cases, without limitation to a stacked-layer structure formed of the same material, a stacked-layer structure formed of different materials may be employed. The insulator 224 may be formed into an island shape overlapping with the oxide 230a. In that case, the insulator 275 is in contact with the side surface of the insulator 224 and the top surface of the insulator 222. In this specification and the like, the term “island shape” refers to a state where two or more layers formed using the same material in the same step are physically separated from each other.

The insulator 271a is provided in contact with the top surface of the conductor 242a, and the insulator 271b is provided in contact with the top surface of the conductor 242b. The insulator 271 preferably functions as at least a barrier insulating film against oxygen. For example, the insulator 271 preferably has a function of inhibiting oxygen diffusion more than the insulator 280.

Since the insulators 271a and 271b are respectively in contact with the conductors 242a and 242b, the insulators 271a and 271b are each preferably an inorganic insulator that is unlikely to oxidize the conductors 242a and 242b. For example, the insulators 271a and 271b are each preferably formed using a nitride insulator that can be used for the insulator 250c. For example, silicon nitride can be used for the insulators 271a and 271b.

An insulating layer to be the insulators 271a and 271b functions as a mask for a conductive layer to be the conductors 242a and 242b; thus, the conductors 242a and 242b do not have curved surfaces between the side surfaces and the top surfaces. Thus, an end portion at the intersection of the side surface and the top surface of the conductor 242a is angular. The cross-sectional area of the conductor 242a is larger in the case where the end portion at the intersection of the side surface and the top surface of the conductor 242a is angular than in the case where the end portion is rounded. The same applies to the conductor 242b. The use of a nitride insulator that is unlikely to oxidize a metal as the insulators 271a and 271b can inhibit excessive oxidation of the conductors 242a and 242b. Accordingly, the resistances of the conductors 242a and 242b are reduced, so that the on-state current of the transistor 200 can be increased.

The insulator 275 is provided to cover the insulator 224, the oxide 230, the conductor 242, and the insulator 271. The insulator 275 preferably has a function of capturing or fixing hydrogen. In that case, the insulator 275 preferably includes silicon nitride or a metal oxide having an amorphous structure, for example, an insulator such as aluminum oxide or magnesium oxide. Alternatively, for example, a stacked-layer film of aluminum oxide and silicon nitride over the aluminum oxide may be used as the insulator 275.

When the above insulators 271 and 275 are provided, the conductor 242 can be covered with the barrier insulating films against oxygen. With such a structure, the conductor 242 can be inhibited from being directly oxidized by oxygen contained in the insulator 280, so that an increase in the resistivity and a reduction in the on-state current can be inhibited.

The insulator 282 is provided over the insulator 280, the conductor 260, and the insulator 250. The insulator 282 preferably has a function of inhibiting diffusion of impurities into the insulator 280 from above and a function of capturing or fixing impurities such as hydrogen. The insulator 282 preferably functions also as a barrier insulating film against oxygen. As the insulator 282, a metal oxide having an amorphous structure, e.g., an insulator such as aluminum oxide, is used. In that case, the insulator 282 contains at least oxygen and aluminum. The insulator 282, which has a function of capturing or fixing impurities such as hydrogen, is provided in contact with the insulator 280 in a region sandwiched between the insulators 212 and 283, whereby impurities such as hydrogen contained in the insulator 280 and the like can be captured or fixed and the amount of hydrogen in the region can be kept constant. Accordingly, the transistor 200 and the semiconductor device with excellent characteristics and high reliability can be fabricated.

As the insulator 282, aluminum oxide is further preferably deposited by a sputtering method using an aluminum target in an atmosphere containing an oxygen gas. In the sputtering method, the amount of oxygen implanted into the layers below the insulator 282 can be controlled by the amount of radio frequency (RF) power applied to the substrate. For example, the amount of oxygen implanted into the layers below the insulator 282 is smaller as the RF power is lower, and the amount of oxygen is easily saturated even when the insulator 282 has a small thickness. Moreover, the amount of oxygen implanted into the layers below the insulator 282 is larger as the RF power is higher.

The insulator 283 functions as a barrier insulating film that inhibits diffusion of impurities into the insulator 280 from above. The insulator 283 is preferably formed using a nitride containing silicon, such as silicon nitride or silicon nitride oxide. For example, silicon nitride deposited by a sputtering method may be used for the insulator 283. When the insulator 283 is formed by a sputtering method, a high-density silicon nitride film can be obtained.

Although the insulators 282 and 283 each have a single-layer structure in FIGS. 12B and 12C, the present invention is not limited thereto, and a stacked-layer structure of two or more layers may be employed.

### <Material for Semiconductor Device>

Materials that can be used for the semiconductor device will be described below.

### <<Substrate>>

As a substrate where the transistor 200 is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example includes a semiconductor substrate in which an insulator region is provided in the above semiconductor substrate, such as a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. An insulator substrate provided with a conductor or a semiconductor, a semiconductor substrate provided with a conductor or an insulator, a conductor substrate provided with a semiconductor or an insulator, or the like may be used. Alternatively, these substrates provided with elements may be used. Examples of the element provided over the substrate include a capacitor, a resistor, a switching element, a light-emitting element, and a memory element.

### <<Insulator>>

Examples of an insulator include an insulating oxide, an insulating nitride, an insulating oxynitride, an insulating nitride oxide, an insulating metal oxide, an insulating metal oxynitride, and an insulating metal nitride oxide.

With scaling down and higher integration of transistors, for example, a problem such as generation of leakage current may arise because of a thinner gate insulator. When a high-k material is used for the insulator functioning as a gate insulator, the voltage at the time of operation of the transistor can be reduced while the physical thickness is maintained. Furthermore, the equivalent oxide thickness (EOT) of the insulator functioning as the gate insulator can be reduced. By contrast, when a low-dielectric-constant material is used for the insulator functioning as an interlayer film, parasitic capacitance generated between wirings can be reduced. Thus, a material is preferably selected depending on the function of an insulator.

Examples of a high-dielectric-constant (high-k) material include gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a low-dielectric-constant material include inorganic insulating materials such as silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide and resins such as polyester, polyolefin, polyamide (e.g., nylon and aramid), polyimide, polycarbonate, and acrylic. A low-dielectric-constant material has high dielectric strength.

A transistor including a metal oxide can have stable electrical characteristics when surrounded by an insulator having a function of inhibiting transmission of oxygen and impurities. The insulator having a function of inhibiting transmission of oxygen and impurities can have, for example, a single-layer structure or a stacked-layer structure of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting transmission of oxygen and impurities, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

The insulator functioning as a gate insulator preferably includes a region containing excess oxygen. For example, silicon oxide or silicon oxynitride that includes a region containing excess oxygen is provided in contact with or in the vicinity of the oxide 230 to reduce the oxygen vacancies in the oxide 230.

### <<Conductor>>

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high electric conductivity, typified by polycrystalline silicon containing an impurity element such as phosphorus, or silicide such as nickel silicide may be used.

Conductive layers formed using any of the above materials may be stacked. For example, a stacked-layer structure combining a material containing the above metal element and a conductive material containing oxygen may be employed. Alternatively, a stacked-layer structure combining a material containing the above metal element and a conductive material containing nitrogen may be employed. Further alternatively, a stacked-layer structure combining a material containing the above metal element, a conductive material containing oxygen, and a conductive material containing nitrogen may be employed.

When a metal oxide is used for the channel formation region of the transistor, the conductor functioning as the gate electrode preferably has a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide in which the channel is formed. A conductive material containing any of the above metal elements and nitrogen may also be used. For example, a conductive material containing nitrogen, such as titanium nitride or tantalum nitride, may be used. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With the use of such a material, hydrogen contained in the metal oxide in which the channel is formed can be captured in some cases. Hydrogen entering from a surrounding insulator or the like can also be captured in some cases.

The semiconductor device of this embodiment includes an OS transistor. The OS transistor has a low off-state current and thus can achieve a semiconductor device with low power consumption. The OS transistor also has excellent frequency characteristics and thus can achieve a semiconductor device with a high operation speed. With the use of the OS transistor, a semiconductor device with excellent electrical characteristics, a semiconductor device with a small variation in the electrical characteristics of transistors, a semiconductor device with a high on-state current, and a semiconductor device with high reliability can be achieved.

### <Application Example of Semiconductor Device>

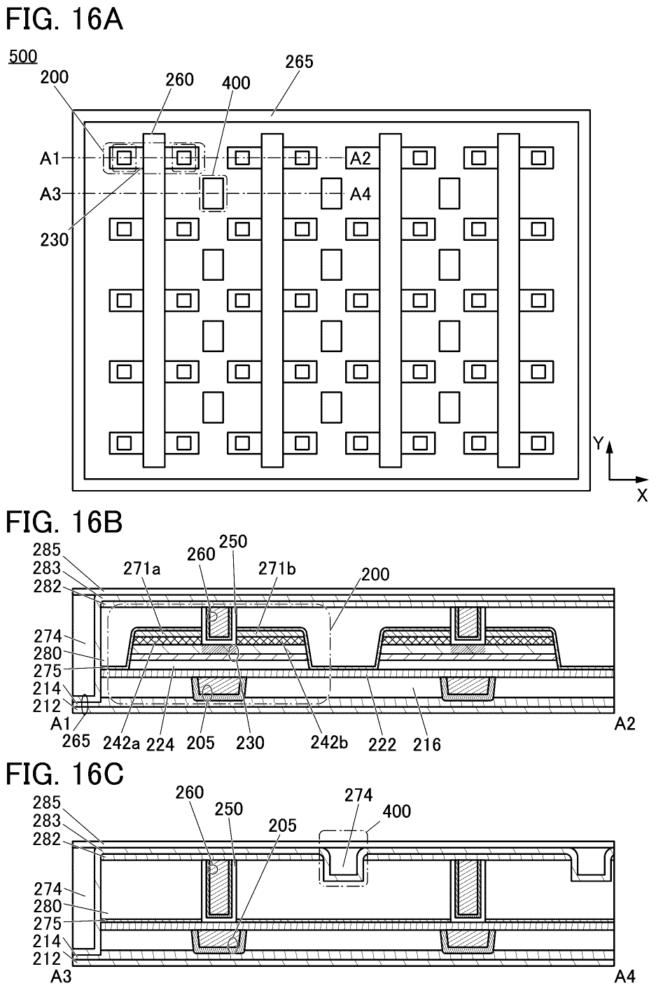

An example of the semiconductor device of one embodiment of the present invention will be described below with reference to FIGS. 16A to 16C.

FIG. 16A is a top view of a semiconductor device 500. In FIG. 16A, the X direction is parallel to the channel length direction of the transistor 200, and the Y direction is perpendicular to the X direction. FIG. 16B is a cross-sectional view taken along the dashed-dotted line A1-A2 in FIG. 16A, which corresponds to a cross-sectional view of the transistor 200 in the channel length direction. FIG. 16C is a cross-sectional view taken along the dashed-dotted line A3-A4 in FIG. 16A, which corresponds to a cross-sectional view of an opening region 400 and in the vicinity thereof. Note that for simplification, some components are not illustrated in the top view of FIG. 16A.

Note that in the semiconductor device illustrated in FIGS. 16A to 16C, components having the same functions as those in the semiconductor device described in <Structure example of semiconductor device> are denoted by the same reference numerals. Note that also in this section, the materials described in detail in <Structure example of semiconductor device> can be used as materials of the semiconductor device.

The semiconductor device 500 is a modification example of the semiconductor device illustrated in FIGS. 12A to 12D. The semiconductor device 500 is different from the semiconductor device illustrated in FIGS. 12A to 12D in that the opening region 400 is formed in the insulators 282 and 280. Moreover, a sealing portion 265 is formed to surround a plurality of the transistors 200, which is a different point from the semiconductor device illustrated in FIGS. 12A to 12D.

The semiconductor device 500 includes a plurality of the transistors 200 and a plurality of the opening regions 400 arranged in a matrix. In addition, the plurality of conductors 260 are provided to extend in the Y direction. The opening regions 400 are formed in regions not overlapping with the oxide 230 or the conductor 260. The sealing portion 265 is formed to surround the plurality of transistors 200, the plurality of conductors 260, and the plurality of opening regions 400. Note that the numbers, the positions, and the sizes of the transistors 200, the conductors 260, and the opening regions 400 are not limited to those illustrated in FIG. 16A and may be set as appropriate in accordance with the design of the semiconductor device 500.

The insulator 285 is provided over the insulator 283. As the insulator 285, an insulator similar to the insulator 280 can be used.

As illustrated in FIGS. 16B and 16C, the sealing portion 265 is provided to surround the plurality of transistors 200 and the insulators 216, 222, 275, 280, and 282. In other words, the insulator 283 is provided to cover the plurality of transistors 200 and the insulators 216, 222, 275, 280, and 282. In the sealing portion 265, the insulator 283 is in contact with the top surface of the insulator 214. An insulator 274 is provided between the insulators 283 and 285 above the sealing portion 265. The top surface of the insulator 274 is level with the uppermost surface of the insulator 283. As the insulator 274, an insulator similar to the insulator 280 can be used.

Such a structure enables the plurality of transistors 200 to be surrounded by the insulators 283, 214, and 212. One or more of the insulators 283, 214, and 212 preferably function as a barrier insulating film against hydrogen. Accordingly, entry of hydrogen contained in the region outside the sealing portion 265 into the sealing portion 265 can be inhibited.

As illustrated in FIG. 16C, the insulator 282 in the opening region 400 has an opening. In the opening region 400, the insulator 280 may have a groove overlapping with the opening in the insulator 282. The depth of the groove is less than or equal to the depth at which the top surface of the insulator 275 is exposed and is, for example, approximately greater than or equal to ¼ and less than or equal to ½ of the maximum thickness of the insulator 280.

As illustrated in FIG. 16C, the insulator 283 in the opening region 400 is in contact with the side surface of the insulator 282 and the side and top surfaces of the insulator 280. Part of the insulator 274 is formed in the opening region 400 to fill the recessed portion formed in the insulator 283, in some cases. At this time, the top surface of the insulator 274 formed in the opening region 400 is level with the uppermost surface of the insulator 283, in some cases.

When heat treatment is performed in such a state that the opening region 400 is formed and the insulator 280 is exposed in the opening of the insulator 282, part of oxygen contained in the insulator 280 can be made to diffuse outwardly from the opening region 400 while oxygen is supplied to the oxide 230. This enables oxygen released from the insulator 280 by heating to be sufficiently supplied into a region serving as a channel formation region and its vicinity and also prevents an excess amount of oxygen from being supplied thereto.

At this time, hydrogen in the insulator 280 can be bonded to oxygen and released to the outside through the opening region 400. The hydrogen bonded to oxygen is released as water. Through the treatment, the amount of hydrogen in the insulator 280 can be reduced, and the hydrogen in the insulator 280 can be inhibited from entering the oxide 230.

In FIG. 16A, the shape of the opening region 400 in the top view is substantially rectangular; however, the present invention is not limited thereto. For example, the shape of the opening region 400 in the top view can be a rectangular shape, an elliptical shape, a circular shape, a rhombus shape, or a shape obtained by combining any of the above shapes. The area and arrangement interval of the opening regions 400 can be set as appropriate in accordance with the design of the semiconductor device including the transistor 200. For example, in the region where the density of the transistors 200 is low, the area of the opening region 400 may be increased or the arrangement interval of the opening regions 400 may be narrowed. For example, in the region where the density of the transistors 200 is high, the area of the opening region 400 may be decreased or the arrangement interval of the opening regions 400 may be increased.

According to one embodiment of the present invention, a novel transistor can be provided. A semiconductor device with excellent electrical characteristics can be provided. A semiconductor device with high reliability can be provided. A semiconductor device with a small variation in transistor characteristics can be provided. A semiconductor device with a high on-state current can be provided. A semiconductor device with high field-effect mobility can be provided. A semiconductor device with excellent frequency characteristics can be provided. A semiconductor device that can be scaled down or highly integrated can be provided. A semiconductor device with low power consumption can be provided.

### <Structure Example of Semiconductor Device Including Transistor 200 and Capacitor 100>

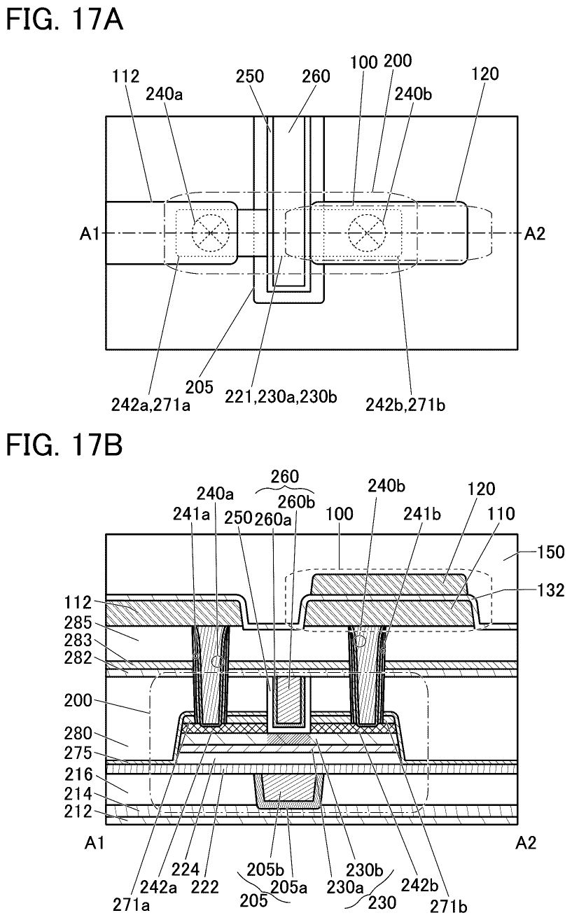

FIGS. 17A and 17B illustrate a semiconductor device including the above transistor 200 and a capacitor 100. FIG. 17A is a top view of the semiconductor device. FIG. 17B is a cross-sectional view taken along the dashed-dotted line A1-A2 in FIG. 17A, which corresponds to a cross-sectional view of the transistor 200 in the channel length direction. Note that for simplification, some components are not illustrated in the top view of FIG. 17A.

In the semiconductor device illustrated in FIGS. 17A and 17B, the capacitor 100 and a conductor 112 are provided over the transistor 200. Here, the area where the capacitor 100 and the transistor 200 overlap with each other is preferably large in the top view. Such a structure can reduce the area occupied by the semiconductor device including the capacitor 100 and the transistor 200. Accordingly, scaling down or high integration of the semiconductor device can be achieved.

The semiconductor device includes a conductor 240a and a conductor 240b that function as plugs. The conductor 240a is provided in an opening formed in the insulators 285, 283, 282, 280, 275, and 271a, and the conductor 240b is provided in an opening formed in the insulators 285, 283, 282, 280, 275, and 271b.

As illustrated in FIG. 17B, the conductor 240a includes a region in contact with the conductor 242a and a region in contact with at least part of the bottom surface of the conductor 112. The conductor 240b includes a region in contact with the conductor 242b and a region in contact with at least part of the bottom surface of a conductor 110 included in the capacitor 100. That is, the conductor 240a is electrically connected to one of the source electrode and the drain electrode of the transistor 200, and the conductor 240b is electrically connected to the other of the source electrode and the drain electrode of the transistor 200.

The conductors 240a and 240b are preferably formed using a conductive material containing tungsten, copper, or aluminum as its main component, for example. The conductors 240a and 240b may each have a stacked-layer structure of a first conductor provided along the side and bottom surfaces of the opening and a second conductor over the first conductor.

In the case where the conductors 240a and 240b each have a stacked-layer structure, a conductive material having a function of inhibiting transmission of impurities is preferably used for the first conductor provided in the vicinity of the insulators 285 and 280. For example, tantalum, tantalum nitride, titanium, titanium nitride, ruthenium, or ruthenium oxide is preferably used. The conductive material having a function of inhibiting transmission of impurities can be used as a single layer or stacked layers. With such a structure, impurities contained in the components above the insulator 283 can be inhibited from entering the oxide 230 through the conductors 240a and 240b. The second conductor also functions as a wiring and thus is preferably formed using a conductor having high conductivity. For the second conductor, for example, a conductive material containing tungsten, copper, or aluminum as its main component is used.

Although the conductors 240a and 240b illustrated in FIG. 17B each have a stacked-layer structure of the first conductor and the second conductor, the present invention is not limited thereto. For example, the conductor 240 may have a single-layer structure or a stacked-layer structure of three or more layers.

An insulator 241a is provided in contact with an inner wall of the opening formed in the insulators 285, 283, 282, 280, 275, and 271a and the side surface of the conductor 240a. An insulator 241b is provided in contact with an inner wall of the opening formed in the insulators 285, 283, 282, 280, 275, and 271b and the side surface of the conductor 240b. Each of the insulators 241a and 241b has a structure in which a first insulator is provided in contact with the inner wall of the opening and a second insulator is provided on the inner side.

Each of the insulators 241a and 241b preferably functions as a barrier insulating film against hydrogen and/or oxygen. For example, silicon nitride, silicon nitride oxide, aluminum oxide, hafnium oxide, or the like is preferably used for the insulators 241a and 241b. Alternatively, for example, a metal oxide such as magnesium oxide, gallium oxide, germanium oxide, yttrium oxide, zirconium oxide, lanthanum oxide, neodymium oxide, or tantalum oxide can be used. Since the insulators 241a and 241b are provided in contact with the insulators 283, 282, and 275, impurities contained in the insulator 280 and the like can be inhibited from entering the oxide 230 through the conductors 240a and 240b. Silicon nitride is particularly preferable because of its high barrier property against hydrogen.

The insulator 241a is provided between the insulator 280 and the conductor 240a, and the insulator 241b is provided between the insulator 280 and the conductor 240b. The insulator 280 contains excess oxygen and is provided in the vicinity of an oxide semiconductor. The insulators 241a and 241b having a barrier property against oxygen can inhibit oxygen contained in the insulator 280 from being absorbed by the conductors 240a and 240b.

When the insulators 241a and 241b each have a stacked-layer structure as illustrated in FIG. 17B, a first insulator in contact with an inner wall of the opening formed in the insulator 280 and the like and a second insulator located inward from the first insulator are preferably formed using a combination of a barrier insulating film against oxygen and a barrier insulating film against hydrogen. For example, aluminum oxide deposited by an ALD method can be used as the first insulator and silicon nitride deposited by a PEALD method can be used as the second insulator. Such a structure can inhibit oxidation of the conductors 240a and 240b and inhibit entry of hydrogen into the conductors 240a and 240b.

### <Capacitor 100>

The capacitor 100 is provided above the transistor 200. The capacitor 100 includes the conductor 110 functioning as a first electrode (also referred to as a lower electrode), a conductor 120 functioning as a second electrode (also referred to as an upper electrode), and an insulator 132 functioning as a dielectric. The first electrode and the second electrode serve as a pair of electrodes of the capacitor 100.

For the conductors 110 and 120, any of the materials described above in <<Conductor>> can be used in a single-layer structure or a stacked-layer structure.

For example, the conductor 112 provided over the conductor 240a and the conductor 110 provided over the conductor 240b can be formed at the same time. In that case, the conductors 112 and 110 are formed using the same conductive material. Note that the conductor 112 functions as a plug or a wiring that is electrically connected to the capacitor 100 or the transistor 200.

The conductors 112 and 110 each have a single-layer structure in FIG. 17B; however, the present invention is not limited thereto. For example, the conductors 112 and 110 may each have a stacked-layer structure of two or more layers. For example, between a conductor having a barrier property and a conductor having high conductivity, a conductor that is highly adhesive to the conductor having a barrier property and the conductor having high conductivity may be formed.

The insulator 132 can be formed to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like. For example, as the insulator 132, an insulator in which zirconium oxide, aluminum oxide, and zirconium oxide are stacked in this order can be used.

For example, the insulator 132 preferably has a stacked-layer structure of an insulator containing a material with high dielectric strength (a low-dielectric-constant material) and an insulator containing a high-dielectric-constant (high-k) material. In the capacitor 100 having such a structure, a sufficient capacitance can be provided owing to the insulator containing a high-k material, and the dielectric strength can be increased owing to the insulator containing a material with high dielectric strength, so that the electrostatic breakdown of the capacitor 100 can be inhibited.

An insulator 150 is provided over the conductor 120 and the insulator 132. The insulator 150 functions as an interlayer film.

For example, the insulator 150 preferably contains the low-dielectric-constant material. Alternatively, the insulator 150 preferably has a stacked-layer structure of an insulator containing a low-dielectric-constant inorganic insulating material and an insulator containing a low-dielectric-constant resin. Since silicon oxide and silicon oxynitride have thermal stability, a combination of silicon oxide or silicon oxynitride with a resin allows the stacked-layer structure to be thermally stable and have a low dielectric constant. The use of the low-dielectric-constant material for the insulator 150 can reduce the parasitic capacitance between wirings.

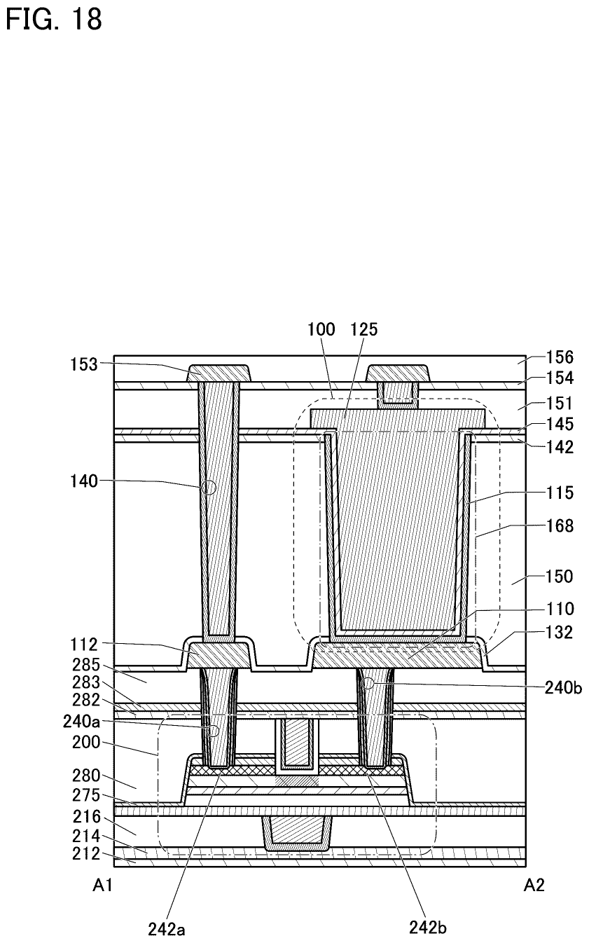

Although the capacitor 100 of the semiconductor device illustrated in FIGS. 17A and 17B has a planar shape, the present invention is not limited thereto. For example, the capacitor 100 may have a cylindrical shape as illustrated in FIG. 18. Note that the structure below and including the insulator 150 of the semiconductor device illustrated in FIG. 18 is similar to that of the semiconductor device illustrated in FIGS. 17A and 17B.

In the semiconductor device illustrated in FIG. 18, the insulator 150 is provided over the insulator 132, and an insulator 142 is provided over the insulator 150. An opening 168 reaching the conductor 110 is formed in the insulators 132, 150, and 142.

The capacitor 100 illustrated in FIG. 18 includes a conductor 115, an insulator 145 over the conductor 115 and the insulator 142, and a conductor 125 over the insulator 145. Note that at least parts of the conductor 115, the insulator 145, and the conductor 125 are positioned inside the opening 168.

An insulator 151 is provided over the conductor 125 and the insulator 145, an insulator 154 is provided over the insulator 151, and a conductor 153 and an insulator 156 are provided over the insulator 154. A conductor 140 is provided in an opening formed in the insulators 132, 150, 142, 145, 151, and 154.

The conductor 115 functions as a first electrode, the conductor 125 functions as a second electrode, and the insulator 145 functions as a dielectric. The first electrode and the second electrode of the capacitor 100 face each other with the dielectric positioned therebetween, along the side surface of the opening 168 as well as the bottom surface thereof; thus, the capacitance per unit area can be larger. Accordingly, the deeper the opening is, the larger the capacitance of the capacitor 100 can be. Increasing the capacitance per unit area of the capacitor 100 in this manner enhances scaling down and integration of the semiconductor device.

Any of the insulators that can be used as the insulator 150 is used as the insulator 151. Any of the insulators that can be used as the insulator 282 is used as the insulator 142.

The shape of the opening 168 when seen from above may be a quadrangular shape, a polygonal shape other than a quadrangular shape, a polygonal shape with rounded corners, or a circular shape such as an elliptical shape. Here, the area where the opening 168 and the transistor 200 overlap with each other is preferably larger in the top view. Such a structure can reduce the area occupied by the semiconductor device including the capacitor 100 and the transistor 200.

The conductor 115 is provided in contact with the side surfaces of the insulators 150 and 142 in the opening 168. The top surface of the conductor 115 is preferably level with the top surface of the insulator 142. The bottom surface of the conductor 115 is in contact with the conductor 110 through the opening 168. The conductor 115 is preferably formed by an ALD method, a CVD method, or the like and is formed using any of the conductors that can be used as the conductor 205, for example.

The insulator 145 is provided to cover the conductor 115 and the insulator 142. The insulator 145 is preferably formed by an ALD method, a CVD method, or the like. Any of the insulators that can be used as the insulator 132 can be used as the insulator 145.

The conductor 125 is provided to fill the opening 168. The conductor 125 is preferably formed by an ALD method, a CVD method, or the like, and any of the conductors that can be used as the conductor 205 is used, for example.

The conductor 153 is provided over the insulator 154 and covered with the insulator 156. As the conductor 153, any of the conductors that can be used as the conductor 112 is used. As the insulator 156, any of the insulators that can be used as the insulator 150 is used. Here, the conductor 153 is in contact with the top surface of the conductor 140 and functions as a terminal of the capacitor 100 or the transistor 200.

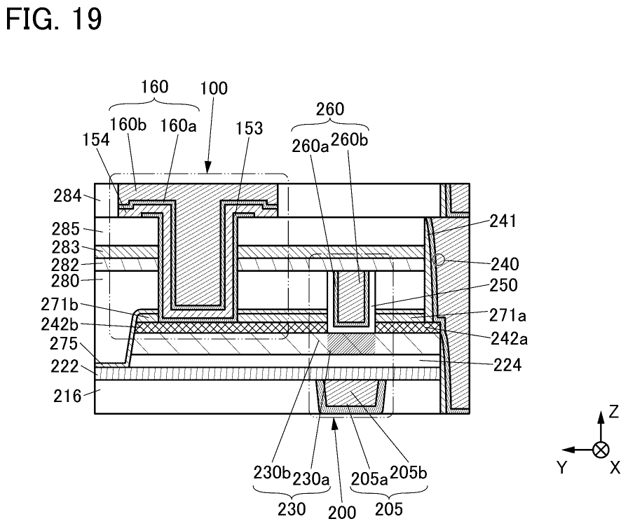

Although the lower electrode of the cylindrical capacitor 100 is electrically connected to the other of the source electrode and the drain electrode of the transistor 200 through the conductor 240b in FIG. 18, the present invention is not limited thereto. For example, as illustrated in FIG. 19, the lower electrode of the cylindrical capacitor may be in contact with the other of the source electrode and the drain electrode of the transistor 200.

FIG. 19 illustrates a semiconductor device including the transistor 200 and the cylindrical capacitor 100. In FIG. 19, the X direction is parallel to the channel length direction of the transistor 200, the Y direction is perpendicular to the X direction, and the Z direction is perpendicular to the X direction and the Y direction. Differences from the semiconductor device illustrated in FIG. 18 will be mainly described below, and the description of portions similar to those in FIG. 18 is omitted.

An insulator 284 is provided over the insulator 285. Any of the insulators that can be used as the insulator 216 is used as the insulator 284.

The capacitor 100 includes the conductor 153 over the conductor 242b, the insulator 154 over the conductor 153, and a conductor 160 (a conductor 160a and a conductor 160b) over the insulator 154.

The conductor 153, the insulator 154, and the conductor 160 are at least partly provided in an opening formed in the insulators 271b, 275, 280, 282, 283, and 285. End portions of the conductor 153, the insulator 154, and the conductor 160 are positioned at least over the insulator 282, preferably over the insulator 285. The insulator 154 is provided to cover the end portion of the conductor 153. This enables the conductors 153 and 160 to be electrically insulated from each other.

The conductor 153 includes a region functioning as a first electrode (a lower electrode). The insulator 154 includes a region functioning as a dielectric. The conductor 160 includes a region functioning as a second electrode (an upper electrode). The capacitor 100 is a metal-insulator-metal (MIM) capacitor.

The conductor 242b provided over the oxide 230 to overlap with the oxide 230 functions as a wiring that is electrically connected to the conductor 153 of the capacitor 100.

Any of the conductors that can be used as the conductors 205, 242a, 242b, and 260 can be used as the conductors 153 and 160 of the capacitor 100. The conductors 153 and 160 are preferably deposited by a deposition method that offers excellent coverage, such as an ALD method or a CVD method. For example, titanium nitride or tantalum nitride deposited by an ALD method or a CVD method can be used for the conductor 153.

The top surface of the conductor 242b is in contact with the bottom surface of the conductor 153. The use of a conductive material having high conductivity for the conductor 242b can reduce the contact resistance between the conductors 153 and 242b.

Titanium nitride deposited by an ALD method or a CVD method can be used for the conductor 160a, and tungsten deposited by a CVD method can be used for the conductor 160b. In the case where the adhesion of tungsten to the insulator 154 is sufficiently high, the conductor 160 may have a single-layer structure of tungsten deposited by a CVD method.

The insulator 154 of the capacitor 100 is preferably formed using a high-dielectric-constant material. The insulator 154 is preferably deposited by a deposition method that offers excellent coverage, such as an ALD method or a CVD method.

The insulator 154 preferably has a stacked-layer structure of a high-dielectric-constant material and a material with high dielectric strength. For example, as the insulator 154, an insulator in which zirconium oxide, aluminum oxide, and zirconium oxide are stacked in this order can be used. For another example, an insulator in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor 100.

Alternatively, a material that can show ferroelectricity described later may be used for the insulator 154.

The deeper the opening formed in the insulators 271b, 275, 280, 282, 283, and 285 is (i.e., the larger the thickness of one or more of the insulators 271b, 275, 280, 282, 283, and 285 is), the larger the capacitance of the capacitor 100 can be. Increasing the capacitance per unit area of the capacitor 100 enhances scaling down or integration of the semiconductor device.

Since the insulators 271b, 275, 282, and 283 function as the barrier insulating films, their thicknesses are preferably set in accordance with a barrier property required for the semiconductor device. The thickness of the conductor 260 functioning as a gate electrode depends on the thickness of the insulator 280; thus, the thickness of the insulator 280 is preferably set in accordance with the thickness of the conductor 260 required for the semiconductor device.

Hence, the capacitance of the capacitor 100 is preferably set by adjusting the thickness of the insulator 285. For example, the thickness of the insulator 285 is set within the range from 50 nm to 250 nm, and the depth of the opening is approximately greater than or equal to 150 nm and less than or equal to 350 nm. When the capacitor 100 is formed within the above ranges, the capacitor 100 can have sufficient capacitance, and in a semiconductor device including a stack of layers each including the capacitor 100, the height of one layer can be inhibited from being excessively increased. Note that a structure may be employed in which the capacitance of the capacitor differs between the layers. In this structure, the thickness of the insulator 285 differs between the layers, for example.

Note that a sidewall of the opening in which the capacitor 100 is provided and which is formed in the insulator 285 and the like may be substantially perpendicular to the top surface of the insulator 222 or may be tapered. The tapered sidewall can increase the coverage with the conductor 153 and the like provided in the opening and thus can reduce the number of defects such as a void.

The conductor 240 is provided inside an opening formed in the insulators 216, 222, 275, 280, 282, 283, 285, and 284. The conductor 240 is provided in contact with one of the source electrode and the drain electrode (the conductor 242a) of the transistor 200. The conductor 240 extends in the Z direction.

The conductor 242a provided over the oxide 230 includes a region functioning as a wiring electrically connected to the conductor 240. In FIG. 19, for example, the top surface and side end portion of the conductor 242a are electrically connected to the conductor 240 extending in the Z direction. When the conductor 240 is in direct contact with at least one of the top surface and side end portion of the conductor 242a, a connection electrode to be additionally provided becomes unnecessary; thus, the area occupied by the semiconductor device can be reduced. Note that the conductor 240 is preferably in contact with the side end portion and part of the top surface of the conductor 242a. When the conductor 240 is in contact with a plurality of surfaces of the conductor 242a, the contact resistance between the conductors 240 and 242a can be reduced.

The conductor 240 preferably has a stacked-layer structure of a first conductor and a second conductor. For example, as illustrated in FIG. 19, a structure can be employed in which the first conductor of the conductor 240 is provided in contact with an inner wall of the opening and the second conductor is provided on the inner side. That is, the first conductor is closer to the insulators 216, 222, 275, 280, 282, 283, 285, and 284 than the second conductor is. The first conductor is in contact with the top surface and side end portion of the conductor 242a.

The first conductor of the conductor 240 is formed using any of the conductive materials that can be used for the first conductor of the conductor 240a or the conductor 240b, and the second conductor of the conductor 240 is formed using any of the conductive materials that can be used for the second conductor of the conductor 240a or the conductor 240b.

For example, it is preferable to use titanium nitride for the first conductor of the conductor 240 and tungsten for the second conductor of the conductor 240. In that case, the first conductor of the conductor 240 contains titanium and nitrogen, and the second conductor of the conductor 240 contains tungsten.

The conductor 240 may have a single-layer structure or a stacked-layer structure of three or more layers.

As illustrated in FIG. 19, an insulator 241 is preferably provided in contact with the side surface of the conductor 240. Specifically, the insulator 241 is provided in contact with the inner wall of the opening formed in the insulators 216, 222, 275, 280, 282, 283, 285, and 284. The insulator 241 is formed also on the side surfaces of the insulator 224, the oxide 230, and the conductor 242a that extend in the opening. Note that at least part of the conductor 242a is exposed from the insulator 241 and is in contact with the conductor 240. That is, the conductor 240 is provided to fill the opening through the insulator 241.

As illustrated in FIG. 19, the uppermost portion of the insulator 241 formed below the conductor 242a is preferably positioned below the top surface of the conductor 242a. With such a structure, the conductor 240 can be in contact with at least part of the side end portion of the conductor 242a. The insulator 241 formed below the conductor 242a preferably includes a region in contact with the side surface of the oxide 230. Such a structure can inhibit entry of impurities contained in the insulator 280 and the like into the oxide 230 through the conductor 240.

As the insulator 241, any of the insulators that can be used as the insulators 241a and 241b is used.

Although the insulator 241 has a single-layer structure in FIG. 19, the present invention is not limited thereto. The insulator 241 may have a stacked-layer structure of two or more layers.

In the case where the insulator 241 has a two-layer stacked structure, a barrier insulating film against oxygen is used for a first layer in contact with the inner wall of the opening in the insulator 280 and the like, and a barrier insulating film against hydrogen is used for a second layer positioned inward from the first layer. For example, aluminum oxide deposited by an ALD method is used for the first layer and silicon nitride deposited by a PEALD method is used for the second layer. Such a structure can inhibit oxidation of the conductor 240 and entry of hydrogen into the oxide 230 and the like from the conductor 240. Thus, the reliability and electrical characteristics of the transistor 200 can be improved.

A sidewall of the opening in which the conductor 240 and the insulator 241 are provided may be substantially perpendicular to the top surface of the insulator 222 or may be tapered. The tapered sidewall can improve the coverage with the insulator 241 and the like provided in the opening.

The semiconductor device which includes the transistor 200 and the capacitor 100 and in which one of the source and the drain of the transistor 200 is electrically connected to one of the pair of electrodes of the capacitor 100 can function as a memory cell of a memory device, for example.

### <Structure Example of Semiconductor Device Including Transistor 200 and Capacitor 100A>

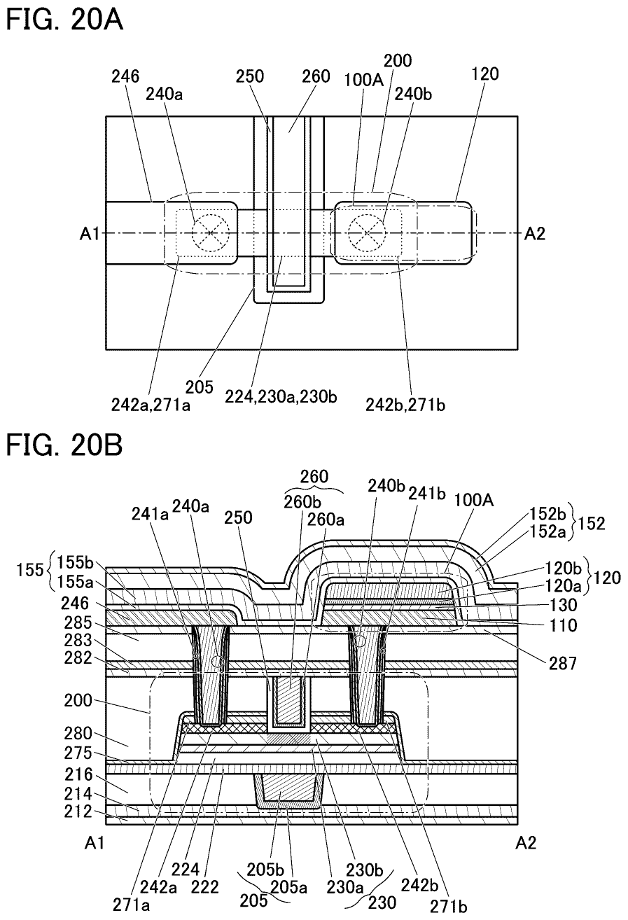

FIGS. 20A and 20B illustrate a semiconductor device including the above transistor 200 and a capacitor 100A. FIG. 20A is atop view of the semiconductor device. FIG. 20B is a cross-sectional view taken along the dashed-dotted line A1-A2 in FIG. 20A, which corresponds to a cross-sectional view of the transistor 200 in the channel length direction. Note that for simplification, some components are not illustrated in the top view of FIG. 20A.

In the semiconductor device illustrated in FIGS. 20A and 20B, the capacitor 100A and a conductor 246 are provided over the transistor 200. The conductor 246 functions as a wiring. Here, the area where the capacitor 100A and the transistor 200 overlap with each other is preferably large in the top view. Such a structure can reduce the area occupied by the semiconductor device including the capacitor 100A and the transistor 200. Accordingly, scaling down or high integration of the semiconductor device can be achieved.

Note that the structure below and including the insulator 285 of the semiconductor device illustrated in FIGS. 20A and 20B is similar to that of the semiconductor device illustrated in FIGS. 17A and 17B. Differences from the semiconductor device illustrated in FIGS. 17A and 17B will be mainly described below, and the description of portions similar to those in FIGS. 17A and 17B is omitted.

The semiconductor device illustrated in FIGS. 20A and 20B includes an insulator 287 over the insulator 285.

The conductor 240a is provided in an opening formed in the insulators 287, 285, 283, 282, 280, 275, and 271a, and the conductor 240b is provided in an opening formed in the insulators 287, 285, 283, 282, 280, 275, and 271b. As illustrated in FIG. 20B, the conductor 240a includes a region in contact with the conductor 242a and a region in contact with at least part of the bottom surface of the conductor 246. The conductor 240b includes a region in contact with the conductor 242b and a region in contact with at least part of the bottom surface of the conductor 110 included in the capacitor 100A.

The conductor 246 is provided in contact with the top surface of the conductor 240a. The conductor 246 is preferably formed using a conductive material containing tungsten, copper, or aluminum as its main component. The conductor 246 may have a stacked-layer structure, such as a stacked layer of any of the above conductive materials and titanium or titanium nitride. The conductor 246 is preferably formed using the same material in the same layer as that for/in the conductor 110.

### <Capacitor 100A>

The capacitor 100A includes the conductor 110, the conductor 120, and the insulator 130 sandwiched between the conductors 110 and 120. For example, the conductor 110 is provided over the insulator 287 and the conductor 240b, the insulator 130 is provided over the conductor 110, and the conductor 120 is provided over the insulator 130. Here, the conductor 110 functions as a first electrode of the capacitor 100A, the conductor 120 functions as a second electrode of the capacitor 100A, and the insulator 130 functions as a dielectric of the capacitor 100A.

The insulator 130 is preferably formed using a material that can show ferroelectricity. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element MX1, an element MX2, and nitrogen. Here, the element MX1 is one or more of aluminum, gallium, indium, and the like. The element MX2 is one or more of boron, scandium, yttrium, lanthanum, cerium, neodymium, europium, titanium, zirconium, hafnium, vanadium, niobium, tantalum, chromium, and the like. Note that the atomic ratio of the element MX1 to the element MX2 can be set as appropriate. A metal oxide containing the element MX1 and nitrogen shows ferroelectricity in some cases even though the metal oxide does not contain the element MX2. Examples of the material that can show ferroelectricity also include the above metal nitride to which an element MX3 is added. Note that the element MX3 is one or more of magnesium, calcium, strontium, zinc, cadmium, and the like. Here, the atomic ratio between the element MX1, the element MX2, and the element MX3 can be set as appropriate.

Examples of the material that can show ferroelectricity also include perovskite-type oxynitrides such as SrTaO₂N and BaTaO₂N, and GaFeO₃ with a κ-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can show ferroelectricity, a mixture or compound containing a plurality of materials selected from the above-listed materials can be used, for example. Alternatively, the insulator 130 can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

A metal oxide containing one or both of hafnium and zirconium is preferable because the metal oxide can show ferroelectricity even when being processed into a thin film of several nanometers. Here, the thickness of the insulator 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). For example, the thickness of the insulator 130 is preferably greater than or equal to 8 nm and less than or equal to 12 nm. With the use of the ferroelectric layer that can have a small thickness, the capacitor 100A can be combined with a scaled-down semiconductor element such as a transistor to fabricate a semiconductor device. Note that in this specification and the like, the material that can show ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can show ferroelectricity even with a minute area. For example, a ferroelectric layer can show ferroelectricity even with an area (occupied area) less than or equal to 10000 μm², less than or equal to 1000 μm², less than or equal to 100 μm², less than or equal to 10 μm², less than or equal to 1 μm², or less than or equal to 0.1 μm² in a top view. With a small-area ferroelectric layer, the area occupied by the capacitor 100A can be reduced.

The material that can show ferroelectricity refers to an insulator having a property of causing internal polarization by application of an electric field from the outside and maintaining the polarization even after the electric field is made zero. Thus, with the use of a capacitor that includes this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, the capacitor 100A described in this embodiment is a ferroelectric capacitor, and the semiconductor device including the capacitor 100A and the transistor 200 can function as a ferroelectric memory.

Note that ferroelectricity is exhibited by displacement of oxygen of a crystal included in a ferroelectric layer due to an external electric field. Ferroelectricity is presumably exhibited depending on a crystal structure of a crystal included in a ferroelectric layer. Thus, in order that the insulator 130 can exhibit ferroelectricity, the insulator 130 needs to include a crystal. It is particularly preferable that the insulator 130 include a crystal having an orthorhombic crystal structure to exhibit ferroelectricity. A crystal included in the insulator 130 may have one or more of crystal structures selected from tetragonal, orthorhombic, and monoclinic crystal structures. Alternatively, the insulator 130 may have an amorphous structure. In that case, the insulator 130 may have a composite structure including an amorphous structure and a crystal structure.

In order to form the insulator 130 including a crystal, the concentration of an impurity such as hydrogen or chlorine in the insulator 130 is preferably reduced. Such an impurity forms oxygen vacancies in a crystal in the insulator 130 in some cases. Furthermore, an impurity such as hydrogen is bonded to the oxygen vacancy part to reduce the crystallinity of the insulator 130 in some cases. Accordingly, when such an impurity is contained in the insulator 130, the crystallization of the insulator 130 is inhibited in some cases. Thus, in order to improve the ferroelectricity of the insulator 130, the concentration of an impurity such as hydrogen or chlorine is preferably reduced.

Thus, as illustrated in FIG. 20B, it is preferable that the insulator 152 be provided to cover the capacitor 100A and the insulator 155 be provided between the insulators 152 and 130. In that case, the insulator 155 in a region not overlapping with the conductor 110 is preferably in contact with the insulator 287.

The insulator 152 preferably has a function of inhibiting diffusion of hydrogen. Thus, the insulator 152 preferably has a higher capability of inhibiting diffusion of hydrogen than the insulator 130. Any of the insulators that can be used as the insulator 212 can be used as the insulator 152, for example. For the insulator 152, silicon nitride is preferably used, for example. In that case, the insulator 152 contains at least nitrogen and silicon.

The insulator 155 preferably has a function of capturing or fixing hydrogen. Thus, the insulator 155 preferably has a higher capability of capturing or fixing hydrogen than the insulator 130. Any of the insulators that can be used as the insulator 214 can be used as the insulator 155. As the insulator 155, for example, aluminum oxide is preferably used. In that case, the insulator 155 contains at least oxygen and aluminum.

The insulator 152 can inhibit diffusion of impurities into the insulator 130 from the outside of the insulator 152. Furthermore, impurities such as hydrogen existing inside a region surrounded by the insulator 152 can be captured or fixed with the insulator 155, whereby the concentration of impurities such as hydrogen contained in the insulator 130 can be reduced. When the insulator 130 does not contain impurities such as hydrogen or the amount of impurities such as hydrogen contained in the insulator 130 is made extremely small as described above, the insulator 130 can have higher crystallinity and thus can have higher ferroelectricity.

In FIG. 20B, the insulator 155 has a stacked-layer structure of an insulator 155a and an insulator 155b over and in contact with the insulator 155a. The insulator 152 has a stacked-layer structure of an insulator 152a and an insulator 152b over and in contact with the insulator 152a. Without being limited to the above, one or both of the insulators 155 and 152 may have a single-layer structure or a stacked-layer structure of three or more layers.

As the insulator 155a, any of the insulators that can be used as the insulator 155 is preferably deposited by an ALD method, particularly preferably by a thermal ALD method. For example, aluminum oxide deposited by an ALD method can be used for the insulator 155a. The insulator 155a can thus be formed to have excellent coverage; hence, even when a pinhole, step disconnection, or the like is generated in the insulator 155b formed by a sputtering method, diffusion of impurities from the outside of the insulator 155b into the insulator 130 through the pinhole, the step disconnection, or the like can be inhibited.

As the insulator 155b, any of the insulators that can be used as the insulator 155 is deposited by a sputtering method. For example, aluminum oxide deposited by a sputtering method can be used for the insulator 155b. A deposition gas in a sputtering method need not include molecules containing hydrogen; thus, the hydrogen concentration in the insulator 155b can be reduced. As a result, more impurities such as hydrogen contained in the insulator 130 can be captured or fixed.

As the insulator 152a, any of the insulators that can be used as the insulator 152 is deposited by a sputtering method. For example, silicon nitride deposited by a sputtering method can be used for the insulator 152a. A deposition gas in a sputtering method need not include molecules containing hydrogen; thus, the hydrogen concentration in the insulator 152a can be reduced.

As the insulator 152b, any of the insulators that can be used as the insulator 152 is preferably deposited by an ALD method, particularly preferably by a PEALD method. For example, silicon nitride deposited by a PEALD method can be used for the insulator 152b. Thus, even when a pinhole, step disconnection, or the like is generated in the insulator 152a formed by a sputtering method, a portion overlapping with such a defect can be filled with ALD-deposited silicon nitride with excellent coverage. Covering the pinhole, the step disconnection, or the like with the insulator 152b can inhibit diffusion of impurities from the outside of the insulator 152b into the insulator 130.

As illustrated in FIG. 20B, the insulators 155 and 152 are provided to cover not only the capacitor 100A but also the conductor 246. Accordingly, in the heat treatment, impurities such as hydrogen can be inhibited from diffusing into the oxide 230 through the capacitor 100A, the conductor 246, and the conductor 240. The highly purified intrinsic capacitor with ferroelectricity in which the amount of impurities such as hydrogen is reduced and a highly purified intrinsic oxide semiconductor in which the amount of impurities such as hydrogen is reduced are highly compatible with each other in the manufacturing process. Thus, a method for fabricating a semiconductor device with high productivity can be provided.

The insulator 287 is preferably formed using an insulator that is highly capable of inhibiting diffusion of impurities, like the insulator 152. When the insulators 155 and 287 are in contact with each other in a region not overlapping with the capacitor 100A, the capacitor 100A is sealed by the insulators 287, 155, and 152. Thus, diffusion of hydrogen from the outside of the insulators 152 and 287 into the capacitor 100A is inhibited and hydrogen in the region surrounded by the insulators 152 and 287 is captured or fixed, so that the hydrogen concentration in the insulator 130 of the capacitor 100A can be reduced. As a result, the ferroelectricity of the insulator 130 can be enhanced.

Although the insulator 287 in a region not overlapping with the conductor 110 is in contact with the insulator 155 in FIG. 20B, the present invention is not limited thereto. A structure may be employed in which the insulator 287 is omitted and the top surface of the insulator 285 is in contact with the bottom surfaces of the conductor 246, the insulator 155a, and the conductor 110.

A layer increasing the crystallinity of the insulator 130 may be provided between the insulator 130 and the conductor 110 and/or between the insulator 130 and the conductor 120. As the layer increasing the crystallinity, a layer containing at least one of the elements contained in the insulator 130 is preferably used, for example. The composition of the layer increasing the crystallinity and the composition of the insulator 130 are preferably different from each other. When HfZrO_{X} is used for the insulator 130, specifically, a metal oxide such as hafnium oxide or zirconium oxide or a metal such as hafnium or zirconium is preferably used for the layer increasing the crystallinity.

The composition of the layer increasing the crystallinity does not necessarily contain an element contained in the insulator 130. In that case, silicon, yttrium, aluminum, scandium, or the like can be used as the element. Providing the layer increasing the crystallinity can increase the crystallinity of the insulator 130 and enhance the ferroelectricity of the insulator 130. Since the increase in the crystallinity of the insulator 130 is followed by the enhancement of the ferroelectricity of the insulator 130, the layer increasing the crystallinity can also be referred to as a layer increasing the remanent polarization of the insulator 130.

The conductor 110 may have a single-layer structure or a stacked-layer structure. Any of the conductors that can be used as the conductor 110 of the capacitor 100 is used as the conductor 110.

In FIG. 20B, the conductor 120 has a stacked-layer structure of a conductor 120a and a conductor 120b over and in contact with the conductor 120a.

As the conductor 120a, any of the conductors that can be used as the conductor 120 of the capacitor 100 is formed by a sputtering method, an ALD method, a CVD method, or the like. For example, titanium nitride is deposited for the conductor 120a by a sputtering method.

For another example, titanium nitride may be deposited for the conductor 120a by a thermal ALD method. In that case, the substrate temperature during the deposition of the conductor 120a is, for example, preferably higher than or equal to room temperature, higher than or equal to 300° C., higher than or equal to 325° C., or higher than or equal to 350° C., and lower than or equal to 500° C. or lower than or equal to 450° C. For example, the substrate temperature is approximately 400° C.

The deposition of the conductor 120a within the above temperature range enables the insulator 130 to have ferroelectricity even without high-temperature baking treatment (e.g., baking treatment at a heat treatment temperature of 400° C. or higher or 500° C. or higher) after the deposition of the conductor 120a. When the conductor 120a is deposited by an ALD method, which causes relatively little damage to a base, as described above, the crystal structure of the insulator 130 can be inhibited from being broken excessively, which leads to higher ferroelectricity of the insulator 130. Note that increasing the crystallinity or ferroelectricity of the insulator 130 by utilizing the temperature during the deposition of the conductor 120 without performing annealing after the deposition of the conductor 120a is sometimes referred to as self-annealing.

As the conductor 120b, any of the conductors that can be used as the conductor 120 of the capacitor 100 is deposited by a sputtering method, an ALD method, a CVD method, or the like. For example, tungsten is deposited by a sputtering method.

Without being limited to the above, the conductor 120 may have a single-layer structure or a stacked-layer structure of three or more layers.

### <Modification Example of Capacitor 100A>

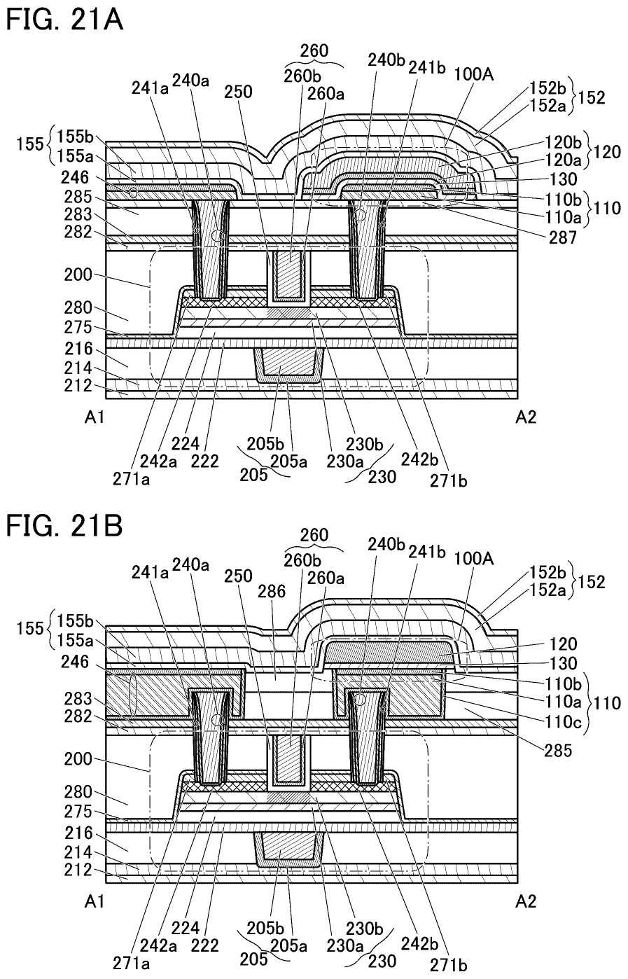

Although the side surfaces of the conductor 110, the insulator 130, and the conductor 120 are aligned with each other in the capacitor 100A illustrated in FIGS. 20A and 20B, the present invention is not limited thereto. Modification examples of the capacitor 100A illustrated in FIGS. 20A and 20B will be described below with reference to FIGS. 21A and 21B. Differences from the semiconductor device illustrated in FIGS. 20A and 20B will be mainly described below, and the description of portions similar to those in FIGS. 20A and 20B is omitted.

FIG. 21A is a cross-sectional view of a semiconductor device, which corresponds to a cross-sectional view of the transistor 200 in the channel length direction.

As illustrated in FIG. 21A, the side surface of the conductor 110 may be located inward from the side surfaces of the insulator 130 and the conductor 120. The insulator 130 is formed to cover the top and side surfaces of the conductor 110, and a region of the insulator 130 that does not overlap with the conductor 110 is in contact with the insulator 287. In that case, the periphery of the conductor 110 is located inward from the peripheries of the insulator 130 and the conductor 120 when seen from above. In such a structure, the conductors 110 and 120 can be adequately apart from each other with the insulator 130.

Increasing the area of the conductor 120 in a top view enables an adequate design margin to be provided in the case where a conductor (not illustrated) that is connected to the conductor 120 and functions as a plug or a wiring is provided.

Although the conductor 110 has a single-layer structure in FIG. 20B, the present invention is not limited thereto, and the conductor 110 may have a stacked-layer structure of two or more layers. For example, as illustrated in FIG. 21A, the conductor 110 may have a stacked-layer structure of a conductor 110a and a conductor 110b over the conductor 110a.

As the conductor 110a, any of the conductors that can be used as the conductor 110 is deposited by a sputtering method, an ALD method, a CVD method, or the like. For example, tungsten is deposited by a sputtering method or a CVD method.

As the conductor 110b in contact with at least part of the bottom surface of the insulator 130, any of the conductors that can be used as the conductor 110 is deposited by an ALD method, a CVD method, or the like. For example, titanium nitride is deposited by a thermal ALD method. The top surface of the conductor 110b preferably has high planarity. High planarity of the top surface of the conductor 110b can improve the crystallinity of the insulator 130 and enhance the ferroelectricity of the insulator 130.

FIG. 21B is a cross-sectional view of a semiconductor device, which corresponds to a cross-sectional view of the transistor 200 in the channel length direction.

As illustrated in FIG. 21B, an insulator 286 may be provided instead of the insulator 287 illustrated in FIG. 20B and the conductor 110 may be provided to fill an opening formed in the insulators 286 and 285.

The insulator 286 is formed using any of the insulating materials that can be used for the insulator 285.

The conductor 110 fills the opening formed in the insulators 286 and 285. In the opening formed in the insulators 286 and 285, the conductor 110 includes a region in contact with the conductor 240b. When the conductor 110 fills the opening formed in the insulators 286 and 285, the conductors 110 and 120 can be adequately apart from each other. This can reduce the leakage current of the capacitor 100A.

The conductor 110 illustrated in FIG. 21B can be formed in the following manner: an opening is formed in the insulators 286 and 285, a conductive film to be the conductor 110 is formed, and planarization treatment is performed until the insulator 286 is exposed. That is, the conductor 110 illustrated in FIG. 21B can be formed by single damascene. Such a step of forming the conductor 110 doubles as a step of enhancing the planarity of the top surface of the conductor 110. Thus, the insulator 130 is provided over the conductor 110 with high planarity, so that the planarity of the insulator 130 can also be high. Accordingly, the leakage current of the capacitor 100A can be reduced even when the insulator 130 is formed using a thin ferroelectric layer. Such a step of forming the conductor 110 is suitable also in the case where part of the insulator 130 is provided over the insulator 286 because the planarity of the top surface of the insulator 286 is also high.

As illustrated in FIG. 21B, the conductor 110 may have a stacked-layer structure of a conductor 110c, the conductor 110a over the conductor 110c, and the conductor 110b over the conductor 110a. In the opening formed in the insulators 286 and 285, the conductor 110c is provided in contact with the side surfaces of the insulators 286, 285, and 241b and the top surfaces of the insulator 283 and the conductor 240b. The conductor 110a is provided to fill part of a recessed portion of the conductor 110c. Note that the level of the top surface of the conductor 110a is lower than the levels of the top surfaces of the conductor 110c and the insulator 286. The conductor 110b is provided in contact with the top surface of the conductor 110a and the side surface of the conductor 110c. Note that the top surface of the conductor 110b is level with the top surfaces of the conductor 110c and the insulator 286. That is, the conductor 110a is surrounded by the conductors 110c and 110b.

As the conductor 110c, any of the conductors that can be used as the conductor 205a is deposited by a sputtering method, an ALD method, a CVD method, or the like. When the conductor 110c is formed using a conductive material having a function of inhibiting diffusion of oxygen, the conductivity of the conductor 110a can be inhibited from being lowered because of oxidation. For example, titanium nitride is deposited as the conductor 110c by a CVD method.

As the conductor 110b, any of the conductors that can be used as the conductor 110 is deposited by an ALD method, a CVD method, or the like. In the case where the conductor 110c is formed through the planarization treatment as described above, the conductor 110c may be formed by a sputtering method, a CVD method, or a PECVD method that provides a high deposition rate. Thus, a semiconductor device can be fabricated with high productivity. For example, titanium nitride is deposited as the conductor 110b by a CVD method.

In FIG. 21B, the side surface of the conductor 110 is positioned inward from the side surface of the insulator 130. In that case, as illustrated in FIG. 21B, part of the insulator 286 in a region not overlapping with the conductor 120 is sometimes removed.

Although the side surface of the conductor 110 is positioned inward from the side surface of the insulator 130 in FIG. 21B, the present invention is not limited thereto. For example, the side surface of the conductor 110 may be positioned outward from the side surface of the insulator 130. With this structure, the insulator 130 is surrounded by the conductor 110c, the insulator 155, and the insulator 152. With the use of a conductive material having a function of inhibiting diffusion of hydrogen for the conductor 110c, diffusion of hydrogen from the outside of the insulator 152 and the conductor 110c into the insulator 130 is inhibited and hydrogen in the insulator 130 is captured or fixed, so that the hydrogen concentration in the insulator 130 can be reduced. As a result, the ferroelectricity of the insulator 130 can be enhanced. Note that the side surface of the conductor 110 may be aligned with the side surface of the insulator 130.

In the opening formed in the insulators 286 and 285, the conductor 246 includes a region in contact with the conductor 240a. The conductor 246 functions as a wiring or a terminal. The conductor 246 is preferably formed using the same material in the same layer as that for/in the conductor 110. In the case where the conductor 110 has the above-described three-layer stacked structure as illustrated in FIG. 21B, the conductors 246 and 110 are formed using the same material in the same layer so that the conductor 246 can have a three-layer stacked structure.

The conductor 120 in FIG. 21B has a single-layer structure. Note that the conductor 120 may have a stacked-layer structure of two or more layers. In the case where the conductor 120 has a single-layer structure, any of the conductors that can be used as the conductor 120a or the conductor 120b is used as the conductor 120. The conductor 120 is formed by any of the methods that can be used for forming the conductor 120a or the conductor 120b.

This embodiment can be combined with any of the other embodiments as appropriate. In this specification, in the case where a plurality of structure examples are shown in one embodiment, the structure examples can be combined as appropriate.

### Embodiment 3

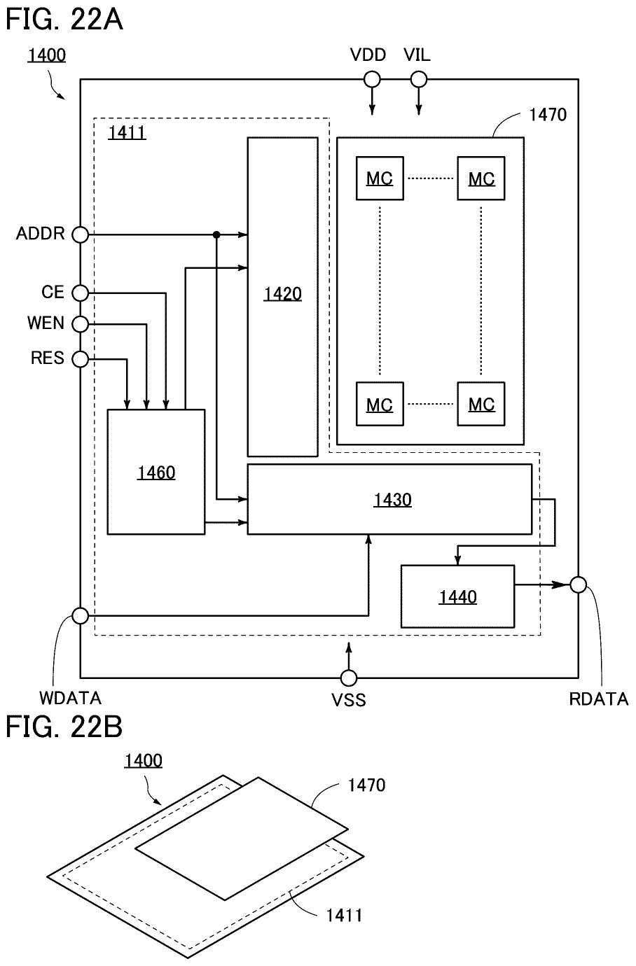

In this embodiment, a memory device of one embodiment of the present invention that includes an OS transistor and a capacitor (hereinafter, such a memory device is sometimes referred to as an OS memory device) will be described with reference to FIGS. 22A and 22B, FIGS. 23A to 23I, FIG. 24, FIG. 25, FIG. 26, and FIG. 27. The OS memory device includes at least a capacitor and an OS transistor that controls the charging and discharging of the capacitor. Since the OS transistor has an extremely low off-state current, the OS memory device has excellent retention characteristics and can function as a nonvolatile memory.

### <Structure Example of Memory Device>

FIG. 22A illustrates a structure example of an OS memory device. A memory device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes a column decoder, a precharge circuit, a sense amplifier, and a write circuit, for example. The precharge circuit has a function of precharging wirings. The sense amplifier has a function of amplifying a data signal read from a memory cell. The wirings mentioned above are connected to memory cells included in the memory cell array 1470, which will be described later in detail. The amplified data signal is output as a data signal RDATA to the outside of the memory device 1400 through the output circuit 1440. The row circuit 1420 includes a row decoder and a word line driver circuit, for example, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the memory device 1400. Control signals (CE, WEN, and RES), an address signal ADDR, and a data signal WDATA are also input to the memory device 1400 from the outside. The address signal ADDR is input to the row decoder and the column decoder, and the data signal WDATA is input to the write circuit.

The control logic circuit 1460 processes the control signals (CE, WEN, and RES) input from the outside, and generates control signals for the row decoder and the column decoder. The control signal CE is a chip enable signal, the control signal WEN is a write enable signal, and the control signal RES is a read enable signal. Signals processed by the control logic circuit 1460 are not limited thereto and other control signals may be input as necessary.

The memory cell array 1470 includes a plurality of memory cells MC arranged in a matrix and a plurality of wirings. The number of wirings that connect the memory cell array 1470 and the row circuit 1420 depends on the configuration of the memory cell MC, the number of memory cells MC in one column, and the like. The number of wirings that connect the memory cell array 1470 and the column circuit 1430 depends on the configuration of the memory cell MC, the number of memory cells MC in one row, and the like.

FIG. 22A illustrates an example in which the peripheral circuit 1411 and the memory cell array 1470 are formed on the same plane; however, this embodiment is not limited thereto. For example, as illustrated in FIG. 22B, the memory cell array 1470 may be provided over the peripheral circuit 1411 to partly overlap with the peripheral circuit 1411. For example, the sense amplifier may be provided below the memory cell array 1470 so that they overlap with each other. The OS transistor can be formed in a back end of line (BEOL) process for forming a wiring of a memory device. Thus, in the case where the OS transistor is used in the memory cell array 1470 and a transistor containing silicon in its channel formation region (hereinafter, sometimes referred to as a Si transistor) is used in the peripheral circuit 1411, a technique by which the OS transistor is formed directly above the Si transistor (such a technique is referred to as a BEOL-Tr technique) can be employed.

A plurality of the memory cell arrays 1470 may be stacked. By stacking the plurality of memory cell arrays 1470, the memory cells can be integrated without an increase in the area occupied by the memory cell arrays 1470. That is, a 3D cell array can be structured. A high integration of memory cells is thus possible and a semiconductor device with high storage capacity can be provided. Note that layers including the OS transistors can be monolithically stacked and are thus suitable.

Note that the configurations of the peripheral circuit 1411, the memory cell array 1470, and the like described in this embodiment are not limited to those described above. The arrangement and functions of these circuits and the wirings, circuit components, and the like connected to the circuits can be changed, removed, or added as needed. The memory device of one embodiment of the present invention operates fast and can retain data for a long time.

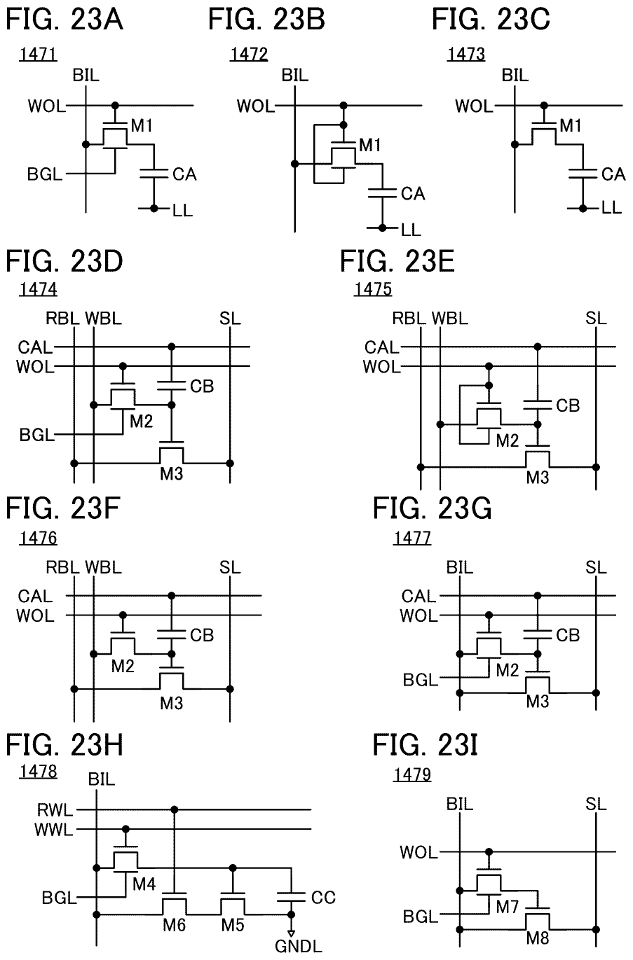

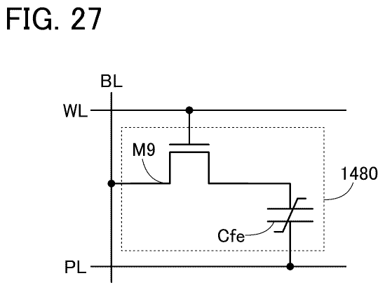

FIGS. 23A to 23I and FIG. 27 illustrate configuration examples of memory cells that can be used as the memory cell MC.

### [DOSRAM]

FIGS. 23A to 23C each illustrate a circuit configuration example of a memory cell of a DRAM. In this specification and the like, a DRAM using a memory cell including one OS transistor and one capacitor is sometimes referred to as a dynamic oxide semiconductor random access memory (DOSRAM). A memory cell 1471 illustrated in FIG. 23A includes a transistor M1 and a capacitor CA. The transistor M1 includes a gate (sometimes referred to as a top gate) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. In data writing and data reading, the wiring LL may be set at a ground potential or a low-level potential. The wiring BGL functions as a wiring for applying a potential to the back gate of the transistor M1. The threshold voltage of the transistor M1 can be increased or decreased by applying a given potential to the wiring BGL.

The memory cell MC is not limited to the memory cell 1471 and can have a different circuit configuration. For example, in the memory cell MC, the back gate of the transistor M1 may be connected to the wiring WOL instead of the wiring BGL as in a memory cell 1472 illustrated in FIG. 23B. As another example of the memory cell MC, the transistor M1 may be a single-gate transistor, that is, a transistor without a back gate as in a memory cell 1473 illustrated in FIG. 23C.

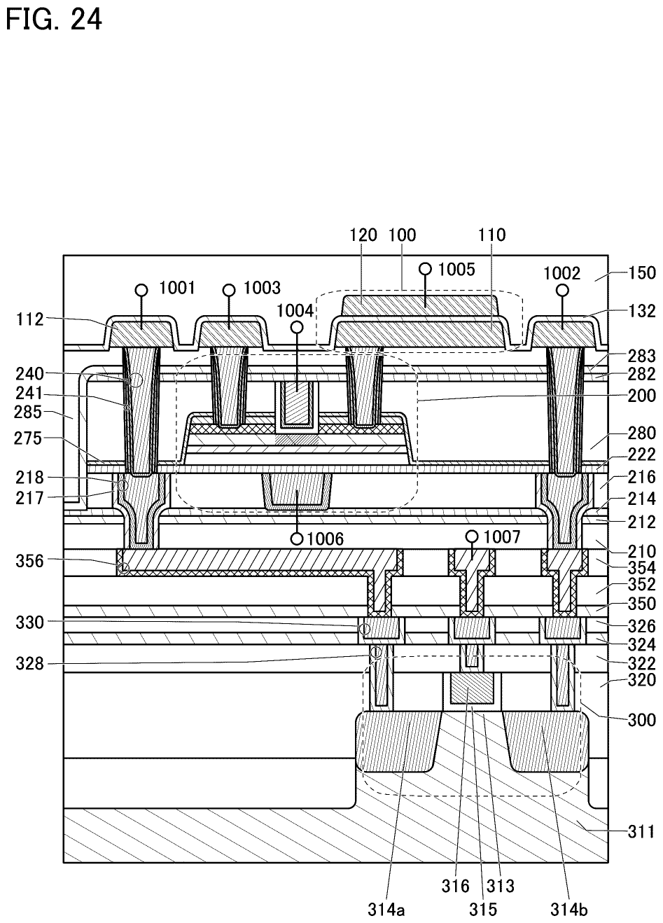

FIG. 24 illustrates a structure example of a memory device including a DOSRAM. In the memory device illustrated in FIG. 24, the transistor 200 is provided above a transistor 300, and the capacitor 100 is provided above the transistors 300 and 200. The transistor 200 and the capacitor 100 described in the above embodiment can be respectively used as the transistor 200 and the capacitor 100.

When the memory device illustrated in FIG. 24 is used in the memory cell 1471, the transistor 200 can be used as the transistor M1 and the capacitor 100 can be used as the capacitor CA. When an OS transistor is used as the transistor M1, the off-state current of the transistor M1 can be extremely low. That is, with the use of the transistor M1, written data can be retained for a long time, and thus the frequency of refresh operation for the memory cell can be decreased. Alternatively, refresh operation for the memory cell can be omitted. In addition, since the transistor M1 has an extremely low off-state current, multi-level data or analog data can be retained in the memory cell 1471. The same applies to the memory cells 1472 and 1473.

In the DOSRAM, when the sense amplifier is provided below the memory cell array 1470 such that they overlap with each other as described above, the bit line can be shortened. This reduces bit line capacity, which reduces the storage capacitance of the memory cell.

In the memory device illustrated in FIG. 24, a wiring 1001 is electrically connected to a source of the transistor 300. A wiring 1002 is electrically connected to a drain of the transistor 300. A wiring 1007 is electrically connected to a gate of the transistor 300. A wiring 1003 is electrically connected to one of the source and the drain of the transistor 200. A wiring 1004 is electrically connected to the first gate of the transistor 200. A wiring 1006 is electrically connected to the second gate of the transistor 200. The other of the source and the drain of the transistor 200 is electrically connected to one electrode of the capacitor 100. A wiring 1005 is electrically connected to the other electrode of the capacitor 100.

### <Transistor 300>

The transistor 300 is provided in and on a substrate 311 and includes a conductor 316 functioning as a gate, an insulator 315 functioning as a gate insulator, a semiconductor region 313 that is a part of the substrate 311, and a low-resistance region 314a and a low-resistance region 314b functioning as a source region and a drain region. The transistor 300 may be either a p-channel transistor or an n-channel transistor.

In the transistor 300 illustrated in FIG. 24, the semiconductor region 313 (part of the substrate 311) in which a channel is formed has a projecting portion. The conductor 316 is provided to cover the top and side surfaces of the semiconductor region 313 with the insulator 315 positioned therebetween. Note that the conductor 316 may be formed using a material for adjusting the work function. The transistor 300 having such a structure is also referred to as a FIN transistor because the projecting portion of the semiconductor substrate is utilized. An insulator functioning as a mask for forming the projecting portion may be provided in contact with the top surface of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 24 is just an example and is not limited to the structure illustrated therein; an appropriate transistor may be used in accordance with a circuit configuration or a driving method.

### <Wiring Layer>

Wiring layers provided with an interlayer film, a wiring, a plug, and the like may be provided between the components. A plurality of wiring layers can be provided in accordance with the design. Here, a plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases, and part of a conductor functions as a plug in other cases.

For example, an insulator 320, an insulator 322, an insulator 324, and an insulator 326 are stacked over the transistor 300 in this order as interlayer films. A conductor 328 is embedded in the insulators 320 and 322, and a conductor 330 is embedded in the insulators 324 and 326. Note that the conductors 328 and 330 each function as a plug or a wiring.

The insulator functioning as an interlayer film may function as a planarization film that covers a roughness thereunder. For example, the top surface of the insulator 322 may be planarized by planarization treatment using a CMP method or the like to increase the level of planarity.

A wiring layer may be provided over the insulator 326 and the conductor 330. For example, in FIG. 24, an insulator 350, an insulator 352, and an insulator 354 are stacked in this order. Furthermore, a conductor 356 is formed in the insulators 350, 352, and 354. The conductor 356 functions as a plug or a wiring.

Similarly, a conductor 218, a conductor forming the transistor 200, and the like are embedded in the insulators 210, 212, 214, and 216. The conductor 218 functions as a plug or a wiring that is electrically connected to the transistor 300.

Here, like the insulators 241a and 241b described in the above embodiment, an insulator 217 is provided in contact with the side surface of the conductor 218. The insulator 217 is provided in contact with the inner wall of the opening formed in the insulators 210, 212, 214, and 216. That is, the insulator 217 is provided between the conductor 218 and the insulators 210, 212, 214, and 216. Note that the conductors 205 and 218 can be formed in parallel; thus, the insulator 217 is sometimes formed in contact with the side surface of the conductor 205.

As the insulator 217, any of the insulators that can be used as the insulators 241a and 241b is used, for example. The insulator 217 is provided in contact with the insulators 210, 212, 214, and 222; thus, impurities contained in the insulator 210, the insulator 216, or the like can be inhibited from entering the oxide 230 through the conductor 218. Silicon nitride is particularly preferable because of its high barrier property against hydrogen. Furthermore, oxygen contained in the insulator 210 or the insulator 216 can be inhibited from being absorbed by the conductor 218.

The insulator 217 can be formed by a method similar to the method for forming the insulators 241a and 241b. For example, silicon nitride is deposited by a PEALD method and an opening reaching the conductor 356 is formed by anisotropic etching.

Any of the insulators that can be used as the insulator 150 is used as the insulators 210, 352, and 354 that function as interlayer films, for example.

When an OS transistor is surrounded by an insulator having a function of inhibiting transmission of oxygen and impurities, the transistor can have stable electrical characteristics. Thus, the insulator having a function of inhibiting transmission of oxygen and impurities that is described above in <<Insulator>> is preferably used as each of the insulators 214, 212, 350, and the like.

Any of the conductors described above in <<Conductor>> can be used as the conductors 328, 330, 356, 218, and 112 that function as plugs or wirings, for example. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

### <Wiring or Plug in Layer Including Oxide Semiconductor>

As described in the above embodiment, the transistor 200 may be sealed with the insulators 212, 214, and 283. Such a structure can inhibit entry of hydrogen contained in the insulators 274, 150, and the like into the insulator 280 or the like.

The conductor 240 penetrates the insulator 283 and the conductor 218 penetrates the insulators 214 and 212; however, as illustrated in FIG. 24, the insulator 241 is provided in contact with the conductor 240 and the insulator 217 is provided in contact with the conductor 218. The use of a barrier insulating film against hydrogen for each of the insulators 241 and 217 can inhibit entry of hydrogen into the insulators 212, 214, and 283 through the conductors 240 and 218. In this manner, the transistor 200 is sealed with the insulators 212, 214, 283, 241, and 217, so that entry of impurities contained in the insulator 274 or the like from the outside can be inhibited.

### [NOSRAM]

FIGS. 23D to 23G each illustrate a circuit configuration example of a gain-cell memory cell including two transistors and one capacitor. A memory cell 1474 illustrated in FIG. 23D includes a transistor M2, a transistor M3, and a capacitor CB. The transistor M2 includes a gate and a back gate. In this specification and the like, a memory device including a gain-cell memory cell using an OS transistor as the transistor M2 is referred to as a nonvolatile oxide semiconductor RAM (NOSRAM) in some cases.

A first terminal of the transistor M2 is connected to a first terminal of the capacitor CB. A second terminal of the transistor M2 is connected to a wiring WBL. The gate of the transistor M2 is connected to the wiring WOL. The back gate of the transistor M2 is connected to the wiring BGL. A second terminal of the capacitor CB is connected to a wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. A high-level potential is preferably applied to the wiring CAL at the time of data writing and data reading. In the data retention, a low-level potential is preferably applied to the wiring CAL. The wiring BGL functions as a wiring for applying a predetermined potential to the back gate of the transistor M2. The threshold voltage of the transistor M2 can be increased or decreased by applying a given potential to the wiring BGL.

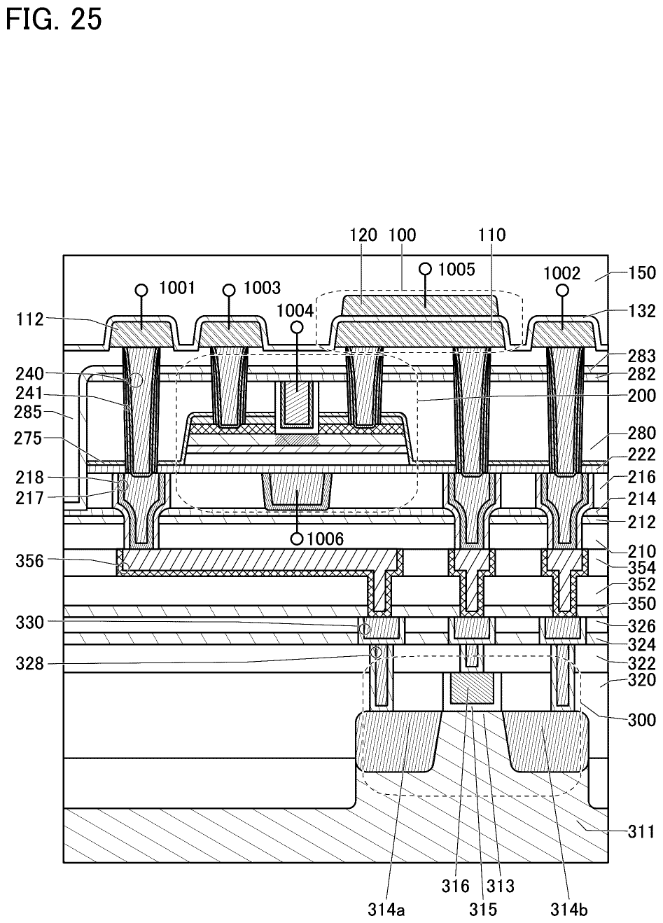

FIG. 25 illustrates an example of a memory device including a NOSRAM. Note that in the memory device described below, components having the same functions as those in the memory device illustrated in FIG. 24 are denoted by the same reference numerals. Differences from the above-described memory device will be mainly described below, and the description of portions similar to those described above is omitted.

FIG. 25 is a cross-sectional view of a memory device. The memory device illustrated in FIG. 25 is different from the memory device illustrated in FIG. 24 in that the wiring 1007 is not provided and the gate of the transistor 300 is electrically connected to the other of the source and the drain of the transistor 200 and the one electrode of the capacitor 100.

In the memory device illustrated in FIG. 25, the gate of the transistor 300 and the other of the source and the drain of the transistor 200 are electrically connected to the one electrode of the capacitor 100. The conductor 316 is electrically connected to the capacitor 100 or the transistor 200 through the conductors 328, 330, 356, 218, and 240.

In the case where the memory device illustrated in FIG. 25 is used in the memory cell 1474 and the like, the transistor 200 can be used as the transistor M2, the transistor 300 can be used as the transistor M3, and the capacitor 100 can be used as the capacitor CB. The wiring 1003, the wiring 1004, the wiring 1006, the wiring 1005, the wiring 1002, and the wiring 1001 can be used as the wiring WBL, the wiring WOL, the wiring BGL, the wiring CAL, the wiring RBL, and the wiring SL, respectively.

The memory cell MC is not limited to the memory cell 1474, and the circuit configuration can be changed as appropriate. For example, as in a memory cell 1475 illustrated in FIG. 23E, the back gate of the transistor M2 may be connected not to the wiring BGL but to the wiring WOL in the memory cell MC. Alternatively, for example, the transistor M2 may be a single-gate transistor, that is, a transistor without a back gate in the memory cell MC as in a memory cell 1476 illustrated in FIG. 23F. For example, the memory cell MC may have a structure in which the wirings WBL and RBL are combined into one wiring BIL as in a memory cell 1477 illustrated in FIG. 23G.

When an OS transistor is used as the transistor M2, the off-state current of the transistor M2 can be extremely low. Thus, with the use of the transistor M2, written data can be retained for a long time, and thus the frequency of refresh operation for the memory cell can be decreased. Alternatively, refresh operation for the memory cell can be omitted. In addition, since the transistor M2 has an extremely low off-state current, multi-level data or analog data can be retained in the memory cell 1474. The same applies to the memory cells 1475 to 1477.

Note that the transistor M3 may be a Si transistor. The Si transistor may be either an n-channel transistor or a p-channel transistor. The Si transistor has higher field-effect mobility than the OS transistor in some cases. Thus, the Si transistor may be used as the transistor M3 functioning as a read transistor. Furthermore, the transistor M2 can be formed over the transistor M3 when the Si transistor is used as the transistor M3, in which case the area of the memory cell can be reduced, leading to high integration of the memory device.

Alternatively, the transistor M3 may be an OS transistor. When an OS transistor is used as each of the transistors M2 and M3, the memory cell array 1470 can be formed using only n-channel transistors.

FIG. 23H illustrates an example of a gain-cell memory cell including three transistors and one capacitor. A memory cell 1478 illustrated in FIG. 23H includes transistors M4 to M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wirings RBL and WBL instead of the wiring BIL.

The transistor M4 is an OS transistor with a back gate that is electrically connected to the wiring BGL. Note that the back gate and the gate of the transistor M4 may be electrically connected to each other. Alternatively, the transistor M4 does not necessarily include the back gate.

Note that each of the transistors M5 and M6 may be either an n-channel Si transistor or a p-channel Si transistor. Alternatively, the transistors M4 to M6 may be OS transistors. In that case, the circuit of the memory cell array 1470 can be formed using only n-channel transistors.

When the semiconductor device described in any of the foregoing embodiments is used in the memory cell 1478, the transistor 200 can be used as the transistor M4, the transistor 300 can be used as each of the transistors M5 and M6, and the capacitor 100 can be used as the capacitor CC. When an OS transistor is used as the transistor M4, the off-state current of the transistor M4 can be extremely low.

FIG. 23I illustrates an example of a gain-cell memory cell including two transistors. A memory cell 1479 illustrated in FIG. 23I includes a transistor M7 and a transistor M8. The memory cell 1479 is electrically connected to the wirings BIL, WWL, BGL, and SL.

The transistor M7 is an OS transistor with a back gate that is electrically connected to the wiring BGL. Note that the back gate and the gate of the transistor M7 may be electrically connected to each other. Alternatively, the transistor M7 does not necessarily include the back gate.

In the memory cell 1479 illustrated in FIG. 23I, the gate capacitance of the transistor M8 is used as storage capacitance. That is, the memory cell 1479 can be regarded as a capacitor-less memory cell. The memory cell 1479 corresponds to the memory cell 1477 illustrated in FIG. 23G from which the capacitor CB is omitted, and can be regarded as a gain-cell memory cell with two transistors and no capacitor.

When the OS transistor is used as the transistor M7 and the transistor M7 is turned off, charge at a node where one of a source electrode and a drain electrode of the transistor M7 is electrically connected to a gate electrode of the transistor M8 can be retained for an extremely long time. Thus, a nonvolatile memory cell can be obtained.

The transistor M8 may be either an n-channel Si transistor or a p-channel Si transistor.

In the case where the semiconductor device described in any of the foregoing embodiments is used in the memory cell 1479, the transistor 200 can be used as the transistor M7 and the transistor 300 can be used as the transistor M8.

Alternatively, the transistor M8 may be an OS transistor. In that case, the circuit of the memory cell array 1470 can be formed using only n-channel transistors.

When the semiconductor device described in the above embodiment is used in the memory cell 1479, the transistor 200 can be used as each of the transistors M7 and M8. With this structure, the transistors M7 and M8 can be formed in the same layer. This structure can simplify a step of stacking layers each including the memory cell 1479 and improve the productivity as compared with a structure in which the transistors M7 and M8 are formed in different layers.

In the case where the transistor 200 is used as each of the transistors M7 and M8, the design matters (including a channel length, a channel width, a cross-sectional shape, and the like) of the transistor can be determined as appropriate in accordance with the characteristics required for the transistors M7 and M8.

There is no particular limitation on the structures of the transistors M1 to M8, regardless of the semiconductor materials used for the transistors M1 to M8. For example, a planar transistor, a staggered transistor, an inverted staggered transistor, or a vertical-channel transistor can be used. Either a top-gate transistor or a bottom-gate transistor may be used. Gates may be provided above and below a semiconductor layer where a channel is formed.

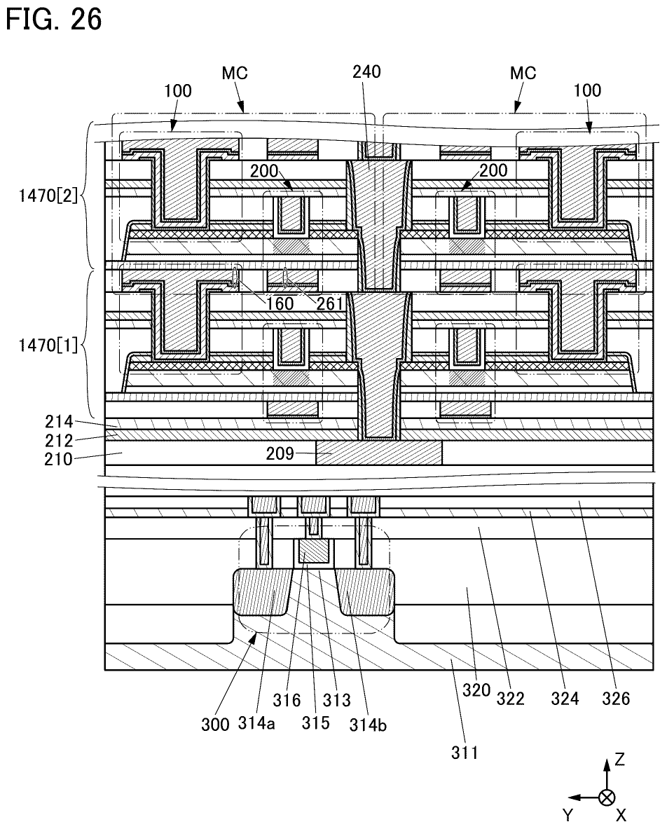

As described above, the plurality of memory cell arrays 1470 may be stacked. By stacking the plurality of memory cell arrays 1470, the memory cells can be integrated without an increase in the area occupied by the memory cell arrays 1470. That is, a 3D cell array can be structured. FIG. 26 illustrates an example of a memory device having a structure in which the plurality of memory cell arrays 1470 are stacked.

The memory device illustrated in FIG. 26 includes a first layer including the transistor 300 and memory cell arrays 1470[1] to 1470[m] (only the memory cell arrays 1470[1] and 1470[2] are illustrated in FIG. 26) over the first layer. Note that m is an integer greater than or equal to 1. The structure below and including the insulator 326 of the memory device illustrated in FIG. 26 is similar to that of the memory device illustrated in FIG. 24.

The memory cell arrays 1470[1] to 1470[m] each include a plurality of memory cells MC. The plurality of memory cells MC each include the transistor 200 and the capacitor 100. Note that the transistor 200 corresponds to the transistor 200 described in the above embodiment, and the capacitor 100 corresponds to the capacitor 100 or the capacitor 100A described in the above embodiment. FIG. 26 illustrates an example in which the transistor 200 and the capacitor 100 illustrated in FIG. 19 are used as the transistor 200 and the capacitor 100.

A wiring layer provided with an interlayer film, a wiring, a plug, and the like may be provided between the first layer and the memory cell array 1470 or between the two memory cell arrays 1470. A plurality of wiring layers can be provided in accordance with the design. In this specification and the like, a wiring and a plug electrically connected to the wiring may be a single component. That is, part of a conductor functions as a wiring in some cases and part of a conductor functions as a plug in other cases.

The insulator 210 is provided above the insulator 326, and a conductor 209 is provided in an opening formed in the insulator 210. The insulators 212 and 214 are provided over the insulator 210. Part of the conductor 240 provided in the memory cell array 1470[1] fills an opening formed in the insulators 212 and 214. Note that any of the insulators that can be used as the insulator 216 can be used as the insulator 210.

A conductor (not illustrated) is provided in contact with the bottom surface of the conductor 209. The top surface of the conductor 209 is in contact with the bottom surface of the conductor 240 provided in the memory cell array 1470[1]. With such a structure, the conductor 240 functioning as the wiring BL can be electrically connected to a circuit element such as a switch, a transistor, a capacitor, an inductor, a resistor, or a diode, a wiring, an electrode, or a terminal, which is provided below the memory cell array 1470.

The memory cell arrays 1470[1] to 1470[m] each include the plurality of memory cells MC. The conductor 240 of each of the memory cells MC is electrically connected to the conductor 240 in the upper layer and the conductor 240 in the lower layer.

As illustrated in FIG. 26, the conductor 240 is shared by the adjacent memory cells MC. The structures of the adjacent memory cells MC are symmetrical with respect to the conductor 240.

Note that the conductor 160 functioning as the upper electrode of the capacitor 100 in the lower layer (e.g., the layer of the memory cell array 1470[1]) can be formed in the same layer as a conductor 261 functioning as a second gate electrode of the transistor 200 in the upper layer (e.g., the layer of the memory cell array 1470[2]). In other words, both the conductor 160 of the capacitor 100 in the lower layer and the conductor 261 of the transistor 200 in the upper layer can be formed to fill the opening formed in the insulator 216. This structure can be obtained by forming the conductor 160 of the capacitor 100 in the lower layer and the conductor 261 of the transistor 200 in the upper layer by processing one conductive film. At this time, the conductor 160 of the capacitor 100 in the lower layer and the conductor 261 of the transistor 200 in the upper layer contain the same material.

The conductor 160 of the capacitor 100 in the lower layer and the conductor 261 of the transistor 200 in the upper layer are formed concurrently in this manner, so that the number of fabrication steps of the memory device of this embodiment can be reduced and the productivity of the memory device can be improved.

In the memory cell array 1470, the plurality of memory cell arrays (the memory cell arrays 1470[1] to 1470[m]) can be stacked. When the memory cell arrays 1470[1] to 1470[m] in the memory cell array 1470 are arranged in a direction perpendicular to the substrate surface, the memory density of the memory cells can be increased. The memory cell array 1470 can be formed by repeating the same formation step in the vertical direction. The formation cost of the memory cell array 1470 of the memory device illustrated in FIG. 26 can be reduced.

### [Ferroelectric Memory]

FIG. 27 illustrates a circuit configuration example of a memory cell including a ferroelectric capacitor. A memory cell 1480 includes a transistor M9 and a capacitor Cfe. As the memory cell 1480, the memory device illustrated in FIG. 24 that includes the capacitor 100A instead of the capacitor 100 can be used. In that case, the transistor 200 can be used as the transistor M9 and the capacitor 100A described in the above embodiment can be used as the capacitor Cfe. The transistor M9 does not necessarily include a back gate.

The transistor 200 described in the above embodiment is preferably used as the transistor M9. The OS transistor has a feature of a high breakdown voltage between its source and drain. That is, the OS transistor can be referred to as a minute device with a high breakdown voltage. Thus, with the use of the OS transistor as the transistor M9, a high voltage can be applied to the transistor M9 even when the transistor M9 is scaled down. The scaling down of the transistor M9 can reduce the area occupied by the semiconductor device. Accordingly, the semiconductor devices can be arranged at high density. This enables a memory device to have high memory capacity.

One of a source and a drain of the transistor M9 is electrically connected to the wiring BL, the other of the source and the drain of the transistor M9 is electrically connected to one electrode of the capacitor Cfe, and a gate of the transistor M9 is electrically connected to a wiring WL. The other electrode of the capacitor Cfe is electrically connected to a wiring PL.

The wiring WL functions as a word line, and the potential of the wiring WL is controlled so that the on/off states of the transistor M9 can be controlled. For example, the potential of the wiring WL is set to a high potential so that the transistor M9 can be turned on, while the potential of the wiring WL is set to a low potential so that the transistor M9 can be turned off. The wiring WL is electrically connected to the word line driver circuit included in the row circuit 1420, and the potential of the wiring WL can be controlled by the word line driver circuit.

The wiring BL functions as a bit line, and a potential corresponding to the potential of the wiring BL is supplied to one electrode of the capacitor Cfe when the transistor M9 is on. The wiring BL is electrically connected to a bit line driver circuit of the column circuit 1430. The bit line driver circuit has a function of generating data to be written to the memory cell MC. In addition, the bit line driver circuit has a function of reading data output from the memory cell MC. Specifically, a sense amplifier is provided in the bit line driver circuit, and data output from the memory cell MC can be read using the sense amplifier.

The wiring PL functions as a plate line. A potential is supplied to the other electrode of the capacitor Cfe through the wiring PL.

The capacitor Cfe includes a material that can show ferroelectricity as a dielectric layer between the two electrodes. As the material that can show ferroelectricity, any of the above-described materials that can be used for the insulator 130 is used. With a ferroelectric layer that can be thin, a memory device combined with a scaled-down transistor can be obtained. The dielectric layer included in the capacitor Cfe is referred to as a ferroelectric layer in the following description.

The semiconductor device including the ferroelectric layer in the capacitor Cfe functions as a nonvolatile memory element that can retain written data even when power supply is stopped.

A DRAM requires regular refresh operation and thus increases power consumption. A semiconductor device that includes the capacitor Cfe including a ferroelectric layer does not require refresh operation and thus can have low power consumption.

In this specification and the like, a memory element or memory circuit including a ferroelectric layer is sometimes referred to as a “ferroelectric memory” or an “FE memory”. Thus, the semiconductor device of one embodiment of the present invention is a ferroelectric memory and is also an FE memory. The FE memory can achieve the number of times of data rewriting of 1×10¹⁰ or more, preferably 1×10¹′ or more, further preferably 1×10¹⁵ or more. In addition, the FE memory can have an operation frequency greater than or equal to 10 MHz, preferably greater than or equal to 1 GHz.

In the FE memory, the remanent polarization 2Pr and data retention capability have a correlation; as the remanent polarization 2Pr becomes smaller, the data retention capability decreases. In this specification and the like, a period over which the remanent polarization 2Pr is reduced by 5% (the data retention capability is decreased by 5%) is referred to as a “memory retention period”. The FE memory can have a memory retention period of ten days or longer, preferably one year or longer, further preferably ten years or longer at a temperature of 150° C. or 200° C.

The FE memory can also be used for a cache memory, a register, and the like in a central processing unit (CPU), a graphics processing unit (GPU), and the like. A normally-off CPU (NoffCPU (registered trademark)) can be obtained by a combination of the FE memory with a cache memory, a register, and the like in a CPU. A normally-off GPU (NoffGPU (registered trademark)) can be obtained by a combination of the FE memory with a cache memory, a register, and the like in a GPU.

The structures, methods, and the like described in this embodiment can be combined as appropriate with any of the other structures, methods, and the like described in this embodiment or any of the structures, methods, and the like described in the other embodiments.

### Embodiment 4

In this embodiment, an OS transistor will be described. In the description of the OS transistor, comparison with the Si transistor will also be briefly described.

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

In order to obtain stable electrical characteristics of the transistor, reducing the impurity concentration in the oxide semiconductor is effective. In order to reduce the impurity concentration in the oxide semiconductor, the impurity concentration in a film that is adjacent to the oxide semiconductor is preferably reduced. Examples of the impurity include hydrogen and nitrogen. Note that an impurity in an oxide semiconductor refers to, for example, elements other than the main components of the oxide semiconductor. For example, an element with a concentration lower than 0.1 atomic % is regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In a Si transistor, a short-channel effect (also referred to as SCE) appears as scaling down of the transistor proceeds. Thus, it is difficult to scale down the Si transistor. One factor in causing the short-channel effect is a small band gap of silicon. By contrast, the OS transistor includes an oxide semiconductor that is a semiconductor material having a large band gap, and thus can suppress the short-channel effect. In other words, the OS transistor does not cause or hardly causes the short-channel effect.

The short-channel effect refers to degradation of electrical characteristics that becomes obvious along with scaling down (a decrease in channel length) of a transistor. Specific examples of the short-channel effect include a decrease in threshold voltage, an increase in subthreshold swing (sometimes referred to as S value), and an increase in leakage current. Here, the S value refers to the amount of change in a gate voltage in a subthreshold region, which is required for changing drain current by one digit at a constant drain voltage.

The characteristic length is widely used as an indicator of resistance to a short-channel effect. The characteristic length is an indicator of curving of potential in a channel formation region. As the characteristic length is shorter, the potential rises more sharply, which means that the resistance to a short-channel effect is high.

The OS transistor is an accumulation-type transistor and the Si transistor is an inversion-type transistor. Thus, the OS transistor has a shorter characteristic length between the channel formation region and each of the source region and the drain region than the Si transistor has. Accordingly, the OS transistor has higher resistance to a short-channel effect than the Si transistor has. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of a short-channel effect. Thus, the OS transistor can be more suitably used as a short-channel transistor than the Si transistor. Note that the gate length refers to a length of a gate electrode in the direction in which carriers flow through a channel formation region when a transistor operates.

Scaling down of the OS transistor can improve the frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

The above comparison of the OS transistor with the Si transistor demonstrates that the OS transistor is advantageous over the Si transistor in that the off-state current is low and a short-channel transistor can be formed.

The configurations, structures, methods, and the like described in this embodiment can be used in an appropriate combination with any of the configurations, structures, methods, and the like described in the other embodiments and the like.

### Embodiment 5

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

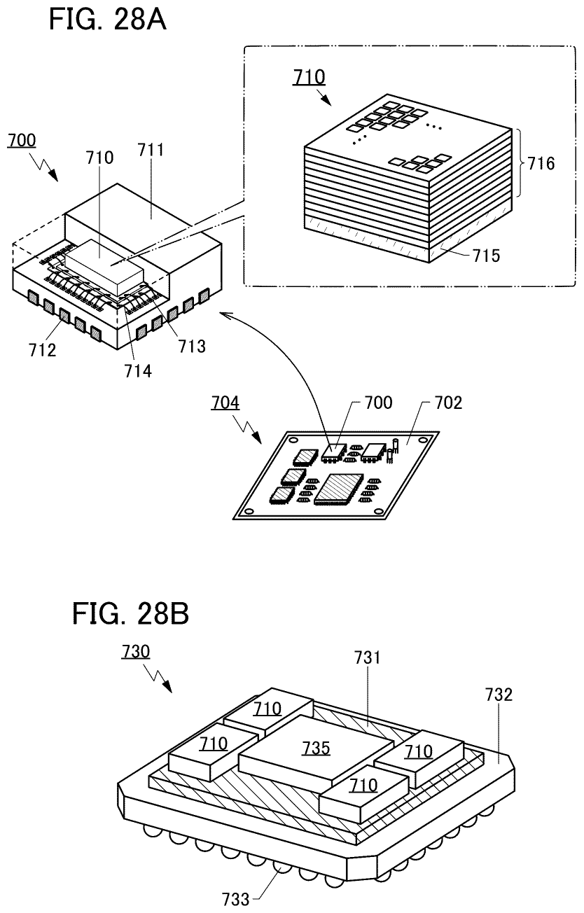

FIG. 28A is a perspective view of a substrate (a circuit board 704) on which an electronic component 700 is mounted. The electronic component 700 illustrated in FIG. 28A includes a semiconductor device 710 in a mold 711. Some components are omitted in FIG. 28A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. Note that the memory layer 716 may include one layer including one or more memory cell arrays. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. When the driver circuit layer 715 and the memory layer 716 are monolithically stacked, for example, a structure in which a memory is directly formed on a processor, what is called an on-chip memory structure, can be obtained. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase a memory bandwidth.

It is preferable that the plurality of memory cell arrays included in the memory layer 716 be formed using the OS transistors and be monolithically stacked.

Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using the Si transistors, it is difficult to obtain the monolithic stacked-layer structure as compared with the case where the memory layer 716 is formed using the OS transistors. Thus, the OS transistor is superior to the Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the formation process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 28B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of the semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the monolithic stacked-layer structure using the OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 28B illustrates an example in which the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include a staggered pin grid array (SPGA), a land grid array (LGA), a quad flat package (QFP), quad flat J-leaded package (QFJ), and a quad flat non-leaded package (QFN).

### [Electronic Device]

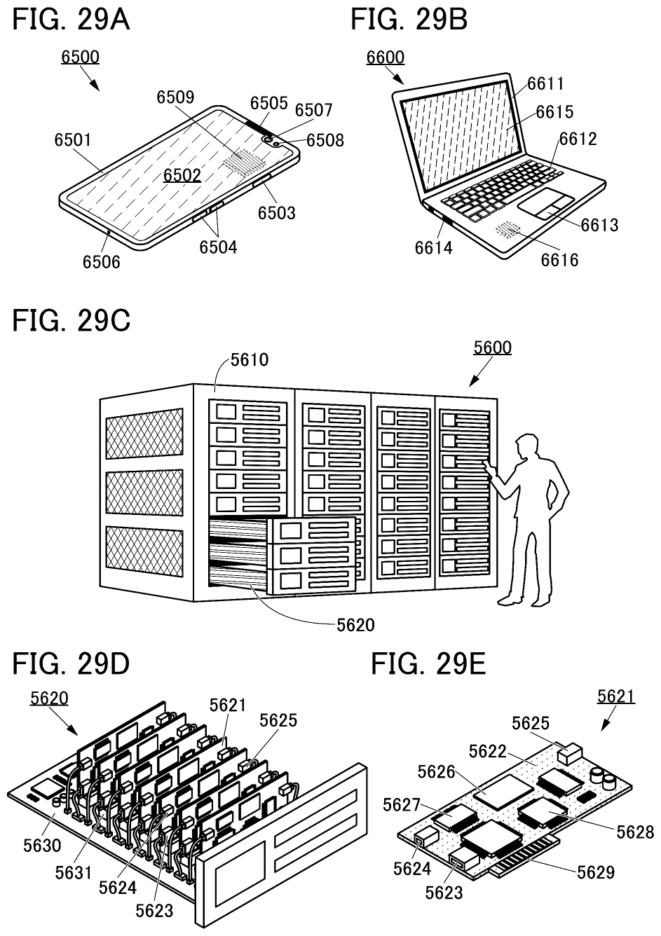

FIG. 29A is a perspective view of an electronic device 6500. The electronic device 6500 illustrated in FIG. 29A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are used as the control device 6509, for example. The semiconductor device of one embodiment of the present invention can be used for the display portion 6502, the control device 6509, and the like.

An electronic device 6600 illustrated in FIG. 29B is an information terminal that can be used as a laptop computer. The electronic device 6600 includes a housing 6611, a keyboard 6612, a pointing device 6613, an external connection port 6614, a display portion 6615, a control device 6616, and the like. One or more selected from a CPU, a GPU, and a memory device are used as the control device 6616, for example. The semiconductor device of one embodiment of the present invention can be used for the display portion 6615, the control device 6616, and the like. Note that the semiconductor device of one embodiment of the present invention is preferably used for the control devices 6509 and 6616, in which case power consumption can be reduced.

### [Large Computer]

FIG. 29C is a perspective view of a large computer 5600. In the large computer 5600 illustrated in FIG. 29C, a plurality of rack mount computers 5620 are stored in a rack 5610. Note that the large computer 5600 may be referred to as a supercomputer.

The computer 5620 can have a structure in a perspective view of FIG. 29D, for example. In FIG. 29D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 29E is an example of a processing board provided with a CPU, a GPU, a memory device, and the like. The PC card 5621 includes a board 5622. The board 5622 includes the connection terminals 5623, 5624, and 5625, a semiconductor device 5626, a semiconductor device 5627, a semiconductor device 5628, and a connection terminal 5629. Although FIG. 29E also illustrates semiconductor devices other than the semiconductor devices 5626, 5627, and 5628, the following description of the semiconductor devices 5626, 5627, and 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can serve as, for example, an interface for performing power supply, signal input, or the like to the PC card 5621. For another example, they can serve as an interface for outputting a signal calculated by the PC card 5621. Examples of the standard for each of the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used even in an environment where radiation can enter. For example, the OS transistor can be suitably used in outer space.

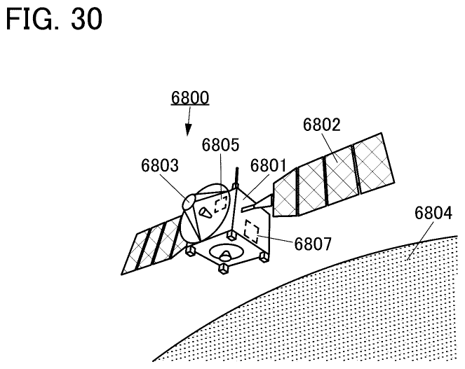

FIG. 30 illustrates an artificial satellite 6800 as an example of space equipment. The artificial satellite 6800 includes a body 6801, a solar panel 6802, an antenna 6803, a secondary battery 6805, and a control device 6807. FIG. 30 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 30, a battery management system (also referred to as BMS) or a battery control circuit may be provided in the secondary battery 6805. The OS transistor is preferably used in the battery management system or the battery control circuit because of its low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. One or more selected from a CPU, a GPU, and a memory device are used as the control device 6807, for example. Note that the semiconductor device including the OS transistor of one embodiment of the present invention is preferably used for the control device 6807. A change in electrical characteristics of the OS transistor due to radiation irradiation is smaller than a change in electrical characteristics of a Si transistor. That is, the OS transistor has high reliability even in an environment where radiation can enter; thus, the OS transistor can be suitably used in such an environment.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, the OS transistor has advantageous effects over the Si transistor, such as a wide memory bandwidth and high radiation resistance.

### [Data Center]

The semiconductor device of one embodiment of the present invention can be suitably used for a storage system in a data center, for example. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, and the like.

With the use of the semiconductor device of one embodiment of the present invention for the storage system in the data center, electric power required for data retention and the size of a semiconductor device retaining data can be reduced. Thus, the size of the storage system, the amount of electric power for data retention, the size of the cooling equipment, and the like can be reduced. This can reduce the scale of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

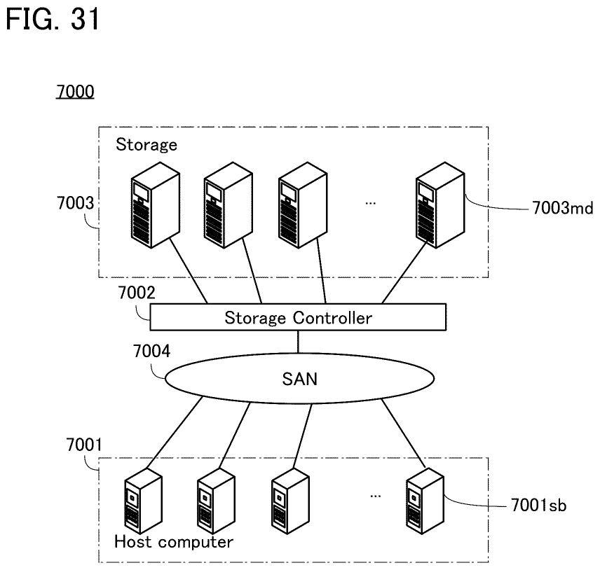

FIG. 31 illustrates a storage system that can be used in a data center. A storage system 7000 illustrated in FIG. 31 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in a storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

The configurations, structures, methods, and the like described in this embodiment can be used in an appropriate combination with any of the configurations, structures, methods, and the like described in the other embodiments and the like.

This application is based on Japanese Patent Application Serial No. 2022-105047 filed with Japan Patent Office on Jun. 29, 2022, the entire contents of which are hereby incorporated by reference.

What is claimed is:

1. A sputtering target comprising:
a first region; and
a second region,
wherein the first region comprises a first metal oxide comprising an element M1,
wherein the element M1 is one or more elements selected from Al, Ga, Si, Mg, Zr, and B,
wherein the second region comprises a second metal oxide comprising indium and an element M2,
wherein the element M2 is one or more elements selected from Zn, Ti, Ge, Sn, V, Ni, Mo, W, and Ta,
wherein the first region and the second region are separated from each other,
wherein each of the first region and the second region is a crystal grain,
wherein a crystal grain boundary is observed between the first region and the second region, and
wherein a diameter of each of the first region and the second region is greater than or equal to 5 nm and less than or equal to 10 μm.

2. The sputtering target according to claim 1, wherein the first metal oxide further comprises indium and zinc.

3. The sputtering target according to claim 2,
wherein the element M1 is Ga, and
wherein the element M2 is Sn.

4. The sputtering target according to claim 1, wherein a crystal structure of the first region is different from a crystal structure of the second region.

5. A sputtering target comprising:
a first region; and
a second region,
wherein the first region comprises a first metal oxide comprising an element M1,
wherein the element M1 is one or more elements selected from Al, Ga, Si, Mg, Zr, and B,
wherein the second region comprises a second metal oxide comprising indium and zinc,
wherein the first region and the second region are separated from each other,
wherein each of the first region and the second region is a crystal grain,
wherein a crystal grain boundary is observed between the first region and the second region, and
wherein a diameter of each of the first region and the second region is greater than or equal to 5 nm and less than or equal to 10 μm.

6. The sputtering target according to claim 5, wherein the first metal oxide further comprises indium and zinc.

7. The sputtering target according to claim 6, wherein the element M1 is Ga.

8. The sputtering target according to claim 5, wherein a crystal structure of the first region is different from a crystal structure of the second region.

9. A method for forming a sputtering target, the method comprising the steps of:
weighing a first indium oxide, an oxide of an element M1, and a first zinc oxide, which are raw materials of a first fired body, and a second indium oxide and a second zinc oxide, which are raw materials of a second fired body, wherein the element M1 is one or more elements selected from Al, Ga, Si, Mg, Zr, and B;
forming a first mixture by mixing the first indium oxide, the oxide of the element M1, and the first zinc oxide;
forming a first molded body by molding the first mixture with pressure;
forming the first fired body by firing the first molded body;
forming a first powder by pulverizing the first fired body;
forming a second mixture by mixing the second indium oxide and the second zinc oxide;
forming a second molded body by molding the second mixture with pressure;
forming the second fired body by firing the second molded body;
forming a second powder by pulverizing the second fired body;
forming a third mixture by mixing the first powder and the second powder; and
forming a third molded body by molding the third mixture with pressure,
wherein a step of firing the third molded body is not performed after the step of forming the third molded body.

10. A method for forming a sputtering target, the method comprising the steps of:
weighing a first indium oxide, an oxide of an element M1, and a first zinc oxide, which are raw materials of a first fired body, and a second indium oxide and a second zinc oxide, which are raw materials of a second fired body, wherein the element M1 is one or more elements selected from Al, Ga, Si, Mg, Zr, and B;
forming a first mixture by mixing the first indium oxide, the oxide of the element M1, and the first zinc oxide;
forming a first molded body by molding the first mixture with pressure;
forming the first fired body by firing the first molded body;
forming a first powder by pulverizing the first fired body;
forming a second mixture by mixing the second indium oxide and the second zinc oxide;
forming a second molded body by molding the second mixture with pressure;
forming the second fired body by firing the second molded body;
forming a second powder by pulverizing the second fired body;
forming a third mixture by mixing the first powder and the second powder;
forming a third molded body by molding the third mixture with pressure; and
forming a third fired body by firing the third molded body,
wherein a firing temperature of the third molded body is a temperature at which part of the first powder and part of the second powder are not combined with each other.

11. The method for forming a sputtering target, according to claim 10, wherein the firing temperature of the third molded body is lower than each of a firing temperature of the first molded body and a firing temperature of the second molded body.
